(19) United States
(12) Patent Application Publication
(10) Pub. No.: US 2014/0252279 A1
(43) Pub. Date: Sep. 11, 2014

(54) ORGANIC SEMICONDUCTORS

(71) Applicant: Merck Patent GmbH, Darmstadt (DE)

(72) Inventors: Changsheng Wang, Durham (GB); Steven Tierney, Southampton (GB); Mansoor D'Lavari, Bude (GB); Lana Nanson, Southampton (GB)

(73) Assignee: MERCK PATENT GMBH, Darmstadt (DE)

(21) Appl. No.: 14/352,828

(22) PCT Filed: Sep. 24, 2012
(86) PCT No.: PCT/EP2012/003980

§ 371 Date: Apr. 18, 2014

(30) Foreign Application Priority Data
Oct. 20, 2011 (EP) 11008425.8

(51) Int. Cl. H01L 51/00

(52) U.S. Cl. CPC H01L 51/0043
USPC 252/511; 549/41; 526/240; 252/500

(57) ABSTRACT

The invention relates to novel organic semiconducting compounds containing one or more dithieno[2,3-b:7,8-b′]-s-indaceno[1,2-b:5,6-b′]dithiophene (IDTT) units that are functionalised at the 6,12-positions with electron withdrawing groups and are optionally substituted at the 3,9-positions with solubilising groups, to methods for their preparation and educts or intermediates used therein, to polymers, blends, mixtures and formulations containing them, to the use of the compounds, polymers, polymer blends, mixtures and formulations as semiconductors in organic electronic (OE) devices, especially in organic photovoltaic (OPV) devices and organic photodetectors (OPD), and to OE, OPV and OPD devices comprising these compounds, polymers, polymer blends, mixtures or formulations.

### FIELD OF THE INVENTION

The invention relates to novel organic semiconducting compounds containing one or more dithieno[2,3-b:7,8-b′]-s-indaceno[1,2-b:5,6-b′]dithiophene (IDTT) units that are functionalised at the 6,12-positions with electron withdrawing groups and are optionally substituted at the 3,9-positions with solubilising groups, to methods for their preparation and educts or intermediates used therein, to polymers, blends, mixtures and formulations containing them, to the use of the compounds, polymers, polymer blends, mixtures and formulations as semiconductors in organic electronic (OE) devices, especially in organic photovoltaic (OPV) devices and organic photodetectors (OPD), and to OE, OPV and OPD devices comprising these compounds, polymers, polymer blends, mixtures or formulations.

### BACKGROUND OF THE INVENTION

Organic semiconducting (OSC) materials are receiving growing interest mostly due to their rapid development in the recent years and the lucrative commercial prospects of organic electronics.

One particular area of importance is organic photovoltaics (OPV). Conjugated polymers have found use in OPVs as they allow devices to be manufactured by solution-processing techniques such as spin casting, dip coating or ink jet printing. Solution processing can be carried out cheaper and on a larger scale compared to the evaporative techniques used to make inorganic thin film devices. Currently, polymer based photovoltaic devices are achieving efficiencies above 8%.

In order to obtain ideal solution-processible OSC molecules two basic features are essential, firstly a rigid π-conjugated core or backbone, and secondly suitable functionality of the aromatic cores in the OSC backbone. The former extends π-π overlaps, defines the primary energy levels of the highest occupied and lowest unoccupied molecular orbitals (HOMO and LUMO), enables both charge injection and transport, and facilitates optical absorption. The latter further fine-tunes the energy levels and enables solubility and hence processability of the materials as well as π-πinteractions of the molecular backbones in the solid state.

An efficient way of lowering bandgaps of conjugated polymers for OPV applications is to co-polymerise electron-rich monomers (donors) with electron-deficient monomers (acceptors) to afford the so called donor-acceptor polymers. Interestingly, it has been found that donor-acceptor co-polymers form the main type of OSC materials with high charge carrier mobilities in OFETs, but the exact mechanism is yet to be proven.

However, compared to the large number of electron donor monomers that have been reported in the literature, the number of electron acceptor monomers that are currently available is still relatively small. Therefore, there is a growing need to expand the pool of electron-accepting monomers leading to both highly efficient donor-acceptor copolymers and high electron mobility OSC polymers.

Recently, indacenodithophene (IDT)-4,9-dione (I) and 4,9-bis(dicyano-methylidene) IDT (TCNM-IDT, II) of the structures shown below have been reported as n-type molecular materials, and the latter have been reported to show electron mobility up to 0.33 cm²/Vs in bottom gate top contact OFETs (see CN101798310 A; H. Tian, Y. Deng, F. Pan, L. Huang, D. Yan, Y. Geng and F. Wang, J. Mater. Chem., 2010, 20(17), 7998).

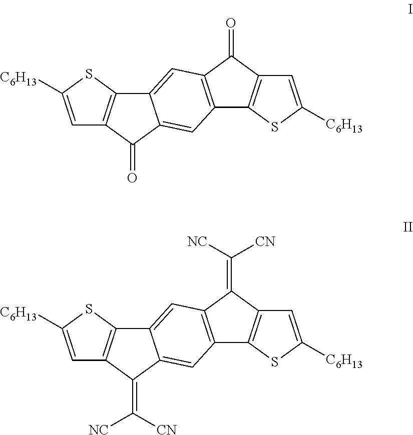

A co-polymeric form of compound I was reported earlier by Zhao et al, however, the FET properties were not studied (see C. Zhao, Y. Zhang and M.-K. Ng, J. Org. Chem., 2007, 72 (17), 6364; C. Zhao, X. Chen, Y. Zhang and M.-K. Ng, J. polym. Sci.: Part A: Polym. Chem., 2008, 46, 2680.).

Thus there is still a need for organic semiconducting (OSC) materials, especially electron acceptor materials, which are easy to synthesize, especially by methods suitable for mass production, show good structural organization and film-forming properties, exhibit good electronic properties, especially a high charge carrier mobility, good processability, especially a high solubility in organic solvents, and high stability in air. Especially for use in OPV cells, there is a need for OSC materials having a low bandgap, which enable improved light harvesting by the photoactive layer and can lead to higher cell efficiencies, compared to the polymers from prior art.

It was an aim of the present invention to provide compounds for use as organic semiconducting materials that are easy to synthesize, especially by methods suitable for mass production, and do especially show good processability, high stability, good solubility in organic solvents, high charge carrier mobility, and a low bandgap. Another aim of the invention was to extend the pool of OSC materials available to the expert. Other aims of the present invention are immediately evident to the expert from the following detailed description.

The inventors of the present invention have found that one or more of the above aims can be achieved by providing compounds, including small molecules, oligomers and conjugated polymers, containing one or more dithieno[2,3-b:7,8-b′]-s-indaceno[1,2-b:5,6-b′]dithiophene (IDTT) units, which are functionalised at the 6,12-positions with electron withdrawing groups, and are optionally substituted at the 3,9-positions with solubilising groups, and which have for example the following structure

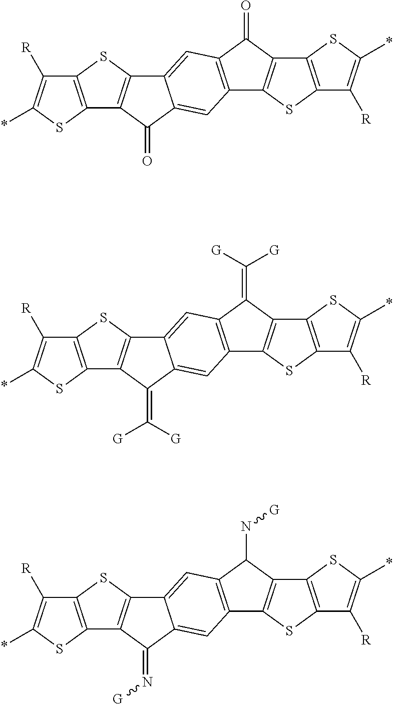

wherein R is for example an alkyl or fluoroalkyl group, G is an electron withdrawing group like for example cyano, ester or ketone, and wherein the S atoms in the thiophene rings may also be replaced by other chalcogen atoms like O, Se or Te.

It was found that the IDTT units according to the present invention have improved planarity, leading to improved the charge mobilities and OPV efficiencies of the resultant polymers. The planar electron-accepting quinoid carbonyls or in-plane methylidene groups with electron drawing substitutents G, which are located at the 6- and 12-positions of IDTT, lead to electron accepting properties. The solubility of the IDTT units is improved by the addition of alkyl chains at the 3- and 9-positions.

It was also found that compounds comprising IDTT units as claimed in the present invention are attractive candidates both for transistor applications and photovoltaic applications, specifically in bulk heterojunction (BHJ) photovoltaic devices. By the incorporation of the electron-accepting IDTT unit and an electron-donating unit into a co-polymer i.e. a “donor-acceptor” polymer, a reduction of the bandgap can be achieved, which enables improved light harvesting properties in BHJ photovoltaic devices. Also, by varying the substituents at the 3,9-positions the solubility and electronic properties of the compounds can be further optimised.

In prior art the IDTT compounds as claimed in the present invention have so far not been reported.

### SUMMARY OF THE INVENTION

The invention relates to compounds comprising one or more divalent units of formula I

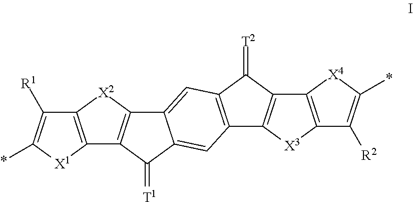

wherein
X¹, X², X³, X⁴ are independently of each other O, S, Se or Te,
T¹ and T² are independently of each other O, C(G¹G²) or N-G¹,
G¹ and G² are independently of each other an electron withdrawing group,
R¹ and R² independently of each other denote H, straight-chain, branched or cyclic alkyl, with 1 to 30 C atoms, in which one or more non-adjacent C atoms are optionally replaced by —O—, —S—, —NR⁰—, —SiR⁰R⁰⁰—, —CY¹═CY²— or —C≡C— in such a manner that 0 and/or S atoms are not linked directly to one another, and in which one or more H atoms are optionally replaced by F, Cl, Br, I or CN, or denote aryl, heteroaryl, aryloxy or heteroaryloxy with 4 to 20 ring atoms which is optionally substituted,
Y¹ and Y² are independently of each other H, F, Cl or CN,
R⁰ and R⁰⁰ are independently of each other H or optionally substituted C₁₋₄₀ carbyl or hydrocarbyl, and preferably denote H or alkyl with 1 to 12 C-atoms.

The invention further relates to a formulation comprising one or more compounds comprising a unit of formula I and one or more solvents, preferably selected from organic solvents.

The invention further relates to an organic semiconducting formulation comprising one or more compounds comprising a unit of formula I, one or more organic binders, or precursors thereof, preferably having a permittivity ∈ at 1,000 Hz and 20° C. of 3.3 or less, and optionally one or more solvents.

The invention further relates to the use of units of formula I as electron donor units in semiconducting polymers.

The invention further relates to a conjugated polymer comprising one or more repeating units, wherein said repeating units contain a unit of formula I and/or one or more groups selected from aryl and heteroaryl groups that are optionally substituted, and wherein at least one repeating unit in the polymer contains at least one unit of formula I.

The invention further relates to monomers containing a unit of formula I and further containing one or more reactive groups which can be reacted to form a conjugated polymer as described above and below.

The invention further relates to a semiconducting polymer comprising one or more units of formula I as electron acceptor units, and preferably further comprising one or more units having electron donor properties.

The invention further relates to the use of the compounds according to the present invention as electron acceptor or n-type semiconductor.

The invention further relates to the use of the compounds according to the present invention as electron acceptor component in a semiconducting material, formulation, polymer blend, device or component of a device.

The invention further relates to a semiconducting material, formulation, polymer blend, device or component of a device comprising a polymer according to the present invention as electron acceptor component, and preferably further comprising one or more compounds or polymers having electron donor properties.

The invention further relates to a mixture or polymer blend comprising one or more compounds according to the present invention and one or more additional compounds which are preferably selected from compounds having one or more of semiconducting, charge transport, hole or electron transport, hole or electron blocking, electrically conducting, photoconducting or light emitting properties.

The invention further relates to a mixture or polymer blend as described above and below, which comprises one or more compounds of the present invention and one or more n-type organic semiconductor compounds, preferably selected from fullerenes or substituted fullerenes. yes.

The invention further relates to a formulation comprising one or more compounds, polymers, formulations, mixtures or polymer blends according to the present invention and optionally one or more solvents, preferably selected from organic solvents.

The invention further relates to the use of a compound, polymer, formulation, mixture or polymer blend of the present invention as charge transport, semiconducting, electrically conducting, photoconducting or light emitting material, or in an optical, electrooptical, electronic, electroluminescent or photoluminescent device, or in a component of such a device or in an assembly comprising such a device or component.

The invention further relates to a charge transport, semiconducting, electrically conducting, photoconducting or light emitting material comprising a compound, polymer, formulation, mixture or polymer blend according to the present invention.

The invention further relates to an optical, electrooptical, electronic, electroluminescent or photoluminescent device, or a component thereof, or an assembly comprising it, which comprises a compound, polymer, formulation, mixture or polymer blend, or comprises a charge transport, semiconducting, electrically conducting, photoconducting or light emitting material, according to the present invention.

The optical, electrooptical, electronic, electroluminescent and photoluminescent devices include, without limitation, organic field effect transistors (OFET), thin film transistors (TFT), organic light emitting diodes (OLED), organic light emitting transistors (OLET), organic photovoltaic devices (OPV), organic photodetectors (OPD), organic solar cells, laser diodes, Schottky diodes, and photoconductors.

The components of the above devices include, without limitation, charge injection layers, charge transport layers, interlayers, planarising layers, antistatic films, polymer electrolyte membranes (PEM), conducting substrates and conducting patterns.

The assemblies comprising such devices or components include, without limitation, integrated circuits (IC), radio frequency identification (RFID) tags or security markings or security devices containing them, flat panel displays or backlights thereof, electrophotographic devices, electrophotographic recording devices, organic memory devices, sensor devices, biosensors and biochips.

In addition the compounds, polymers, formulations, mixtures or polymer blends of the present invention can be used as electrode materials in batteries and in components or devices for detecting and discriminating DNA sequences.

### DETAILED DESCRIPTION OF THE INVENTION

The compounds, monomers and polymers of the present invention are easy to synthesize and exhibit advantageous properties. The conjugated polymers of the present invention show good processability for the device manufacture process, high solubility in organic solvents, and are especially suitable for large scale production using solution processing methods. At the same time, the co-polymers derived from monomers of the present invention and electron donor monomers show low bandgaps, high charge carrier mobilities, high external quantum efficiencies in BHJ solar cells, good morphology when used in p/n-type blends e.g. with fullerenes, high oxidative stability, and a long lifetime in electronic devices, and are promising materials for organic electronic OE devices, especially for OPV devices with high power conversion efficiency.

The unit of formula I is especially suitable as (electron) acceptor unit in both n-type and p-type semiconducting compounds, polymers or copolymers, in particular copolymers containing both donor and acceptor units, and for the preparation of blends of p-type and n-type semiconductors which are useful for application in bulk heterojunction photovoltaic devices.

In addition, the compounds show the following advantageous properties:
i) The IDTT core can be easily brominated with N-bromosuccinimide or elemental bromine. These dibromides can be used to prepare a wide range of new semiconducting/molecular materials as well as new homopolymers and copolymers through transition metal catalysed coupling methods such as Yamamoto reaction (see Yamamoto et al., Bull. Chem. Soc. Jpn., 1978, 51(7), 2091; Yamamoto et al., Macromolecules, 1992, 25(4), 1214), Suzuki-Miyaura reaction (see Miyaura et al., Chem. Rev., 1995, 95, 2457) and Stille reaction (see Bao et al., J. Am., Chem., Soc., 1995, 117(50), 12426).
ii) The IDTT units represent highly conjugated new electron-withdrawing structures, which are potential building-blocks and monomers for constructing n-type and ambipolar OSC small molecules and polymers used as components of OFETs. When coupled or polymerised with electron-donating co-monomer units, the IDTT units of the present invention can be used to prepare low band-gap OSC polymers used for polymeric photovoltaic cells, or photosensitizers used for dye-sensitized solar cells, as well as donor-acceptor OSC polymers used for OFETs.
iii) The solubility of the IDTT units can be improved by adding solubilising groups like alkyl chains at the 3- and 9-positions. This type of substitution allows the solublising groups to stay within the π-molecular plain, which reduces the inter-planar separation of the π-πpolymer backbones, and improves the degree of inter-molecular π-πinteractions. Consequently, improved charge carrier mobilities and improved power conversion efficiencies in solar cells are expected for these compounds.

The synthesis of the unit of formula I, its functional derivatives, compounds, homopolymers, and co-polymers can be achieved based on methods that are known to the skilled person and described in the literature, as will be further illustrated herein.

Above and below, the term “polymer” generally means a molecule of high relative molecular mass, the structure of which essentially comprises the multiple repetition of units derived, actually or conceptually, from molecules of low relative molecular mass (Pure Appl. Chem., 1996, 68, 2291). The term “oligomer” generally means a molecule of intermediate relative molecular mass, the structure of which essentially comprises a small plurality of units derived, actually or conceptually, from molecules of lower relative molecular mass (Pure Appl. Chem., 1996, 68, 2291). In a preferred sense according to the present invention a polymer means a compound having >1, i.e. at least 2 repeating units, preferably ≧5 repeating units, and an oligomer means a compound with >1 and <10, preferably <5, repeating units.

Above and below, in a formula showing a unit or a polymer, like formula I and its subformulae, an asterisk (“*”) denotes a linkage to an adjacent unit or group, and in case of a polymer a link to an adjacent repeating unit or to a terminal group in the polymer chain.

The terms “repeating unit” and “monomeric unit” mean the constitutional repeating unit (CRU), which is the smallest constitutional unit the repetition of which constitutes a regular macromolecule, a regular oligomer molecule, a regular block or a regular chain (Pure Appl. Chem., 1996, 68, 2291).

The term “small molecule” means a monomeric compound which typically does not contain a reactive group by which it can be reacted to form a polymer, and which is designated to be used in monomeric form. In contrast thereto, the term “monomer” unless stated otherwise means a monomeric compound that carries one or more reactive functional groups by which it can be reacted to form a polymer.

The terms “donor”/“donating” and “acceptor”/“accepting”, unless stated otherwise, mean an electron donor or electron acceptor, respectively. “Electron donor” means a chemical entity that donates electrons to another compound or another group of atoms of a compound. “Electron acceptor” means a chemical entity that accepts electrons transferred to it from another compound or another group of atoms of a compound. (see also U.S. Environmental Protection Agency, 2009, Glossary of technical terms, http://www.epa.gov/oust/cat/TUMGLOSS.HTM).

The term “leaving group” means an atom or group (charged or uncharged) that becomes detached from an atom in what is considered to be the residual or main part of the molecule taking part in a specified reaction (see also Pure Appl. Chem., 1994, 66, 1134).

The term “conjugated” means a compound containing mainly C atoms with sp²-hybridisation (or optionally also sp-hybridisation), which may also be replaced by hetero atoms. In the simplest case this is for example a compound with alternating C—C single and double (or triple) bonds, but does also include compounds with units like 1,4-phenylene. “Mainly” means in this connection that a compound with naturally (spontaneously) occurring defects, which may lead to interruption of the conjugation, is still regarded as a conjugated compound.

Unless stated otherwise, the molecular weight is given as the number average molecular weight Mₙ or weight average molecular weight M_{W}, which is determined by gel permeation chromatography (GPC) against polystyrene standards in eluent solvents such as tetrahydrofuran, trichloromethane (TCM, chloroform), chlorobenzene or 1,2,4-trichlorobenzene. Unless stated otherwise, 1,2,4-trichlorobenzene is used as solvent. The degree of polymerization, also referred to as total number of repeating units, n, means the number average degree of polymerization given as n=MₙM_{U}, wherein Mₙ is the number average molecular weight and M_{U} is the molecular weight of the single repeating unit, see J. M. G. Cowie, Polymers: Chemistry & Physics of Modern Materials, Blackie, Glasgow, 1991.

The term “carbyl group” as used above and below denotes any monovalent or multivalent organic radical moiety which comprises at least one carbon atom either without any non-carbon atoms (like for example —C≡C—), or optionally combined with at least one non-carbon atom such as N, O, S, P, Si, Se, As, Te or Ge (for example carbonyl etc.). The term “hydrocarbyl group” denotes a carbyl group that does additionally contain one or more H atoms and optionally contains one or more hetero atoms like for example N, O, S, P, Si, Se, As, Te or Ge.

The term “hetero atom” means an atom in an organic compound that is not a H- or C-atom, and preferably means N, O, S, P, Si, Se, As, Te or Ge.

A carbyl or hydrocarbyl group comprising a chain of 3 or more C atoms may be straight-chain, branched and/or cyclic, including spiro and/or fused rings.

Preferred carbyl and hydrocarbyl groups include alkyl, alkoxy, alkylcarbonyl, alkoxycarbonyl, alkylcarbonyloxy and alkoxycarbonyloxy, each of which is optionally substituted and has 1 to 40, preferably 1 to 25, very preferably 1 to 18 C atoms, furthermore optionally substituted aryl or aryloxy having 6 to 40, preferably 6 to 25 C atoms, furthermore alkylaryloxy, arylcarbonyl, aryloxycarbonyl, arylcarbonyloxy and aryloxycarbonyloxy, each of which is optionally substituted and has 6 to 40, preferably 7 to 40 C atoms, wherein all these groups do optionally contain one or more hetero atoms, preferably selected from N, O, S, P, Si, Se, As, Te and Ge.

The carbyl or hydrocarbyl group may be a saturated or unsaturated acyclic group, or a saturated or unsaturated cyclic group. Unsaturated acyclic or cyclic groups are preferred, especially aryl, alkenyl and alkynyl groups (especially ethynyl). Where the C₁-C₄₀ carbyl or hydrocarbyl group is acyclic, the group may be straight-chain or branched. The C₁-C₄₀ carbyl or hydrocarbyl group includes for example: a C₁-C₄₀ alkyl group, a C₁-C₄₀ fluoroalkyl group, a C₁-C₄₀ alkoxy or oxaalkyl group, a C₂-C₄₀ alkenyl group, a C₂-C₄₀ alkynyl group, a C₃-C₄₀ allyl group, a C₄-C₄₀ alkyldienyl group, a C₄-C₄₀ polyenyl group, a C₂-C₄₀ ketone group, a C₂-C₄₀ ester group, a C₆-C₁₈ aryl group, a C₆-C₄₀ alkylaryl group, a C₆-C₄₀ arylalkyl group, a C₄-C₄₀ cycloalkyl group, a C₄-C₄₀ cycloalkenyl group, and the like. Preferred among the foregoing groups are a C₁-C₂₀ alkyl group, a C₁-C₂₀ fluoroalkyl group, a C₂-C₂₀ alkenyl group, a C₂-C₂₀ alkynyl group, a C₃-C₂₀ allyl group, a C₄-C₂₀ alkyldienyl group, a C₂-C₂₀ ketone group, a C₂-C₂₀ ester group, a C₆-C₁₂ aryl group, and a C₄-C₂₀ polyenyl group, respectively. Also included are combinations of groups having carbon atoms and groups having hetero atoms, like e.g. an alkynyl group, preferably ethynyl, that is substituted with a silyl group, preferably a trialkylsilyl group.

Aryl and heteroaryl preferably denote a mono-, bi- or tricyclic aromatic or heteroaromatic group with 4 to 30 ring C atoms that may also comprise condensed rings and is optionally substituted with one or more groups L,

wherein L is selected from halogen, —CN, —NC, —NCO, —NCS, —OCN, —SCN, —C(═O)NR⁰R⁰⁰, —C(═O)X⁰, —C(═O)R⁰, —NH₂, —NR⁰R⁰⁰, —SH, —SR⁰, —SO₃H, —SO₂R⁰, —OH, —NO₂, —CF₃, —SF₅, P-Sp-, optionally substituted silyl, or carbyl or hydrocarbyl with 1 to 40 C atoms that is optionally substituted and optionally comprises one or more hetero atoms, and is preferably alkyl, alkoxy, thiaalkyl, alkylcarbonyl, alkoxycarbonyl or alkoxycarbonyloxy with 1 to 20 C atoms that is optionally fluorinated, and R⁰, R⁰⁰, X⁰, P and Sp have the meanings given above and below.

Very preferred substituents L are selected from halogen, most preferably F, or alkyl, alkoxy, oxaalkyl, thioalkyl, fluoroalkyl and fluoroalkoxy with 1 to 12 C atoms or alkenyl, alkynyl with 2 to 12 C atoms.

Especially preferred aryl and heteroaryl groups are phenyl in which, in addition, one or more CH groups may be replaced by N, naphthalene, thiophene, selenophene, thienothiophene, dithienothiophene, fluorene and oxazole, all of which can be unsubstituted, mono- or polysubstituted with L as defined above. Very preferred rings are selected from pyrrole, preferably N-pyrrole, furan, pyridine, preferably 2- or 3-pyridine, pyrimidine, pyridazine, pyrazine, triazole, tetrazole, pyrazole, imidazole, isothiazole, thiazole, thiadiazole, isoxazole, oxazole, oxadiazole, thiophene preferably 2-thiophene, selenophene, preferably 2-selenophene, thieno[3,2-b]thiophene, indole, isoindole, benzofuran, benzothiophene, benzodithiophene, quinole, 2-methylquinole, isoquinole, quinoxaline, quinazoline, benzotriazole, benzimidazole, benzothiazole, benzisothiazole, benzisoxazole, benzoxadiazole, benzoxazole, benzothiadiazole, all of which can be unsubstituted, mono- or polysubstituted with L as defined above. Further examples of heteroaryl groups are those selected from the following formulae

An alkyl or alkoxy radical, i.e. where the terminal CH₂ group is replaced by —O—, can be straight-chain or branched. It is preferably straight-chain, has 2, 3, 4, 5, 6, 7 or 8 carbon atoms and accordingly is preferably ethyl, propyl, butyl, pentyl, hexyl, heptyl, octyl, ethoxy, propoxy, butoxy, pentoxy, hexoxy, heptoxy, or octoxy, furthermore methyl, nonyl, decyl, undecyl, dodecyl, tridecyl, tetradecyl, pentadecyl, nonoxy, decoxy, undecoxy, dodecoxy, tridecoxy or tetradecoxy, for example.

An alkenyl group, wherein one or more CH₂ groups are replaced by —CH═CH— can be straight-chain or branched. It is preferably straight-chain, has 2 to 10 C atoms and accordingly is preferably vinyl, prop-1-, or prop-2-enyl, but-1-, 2- or but-3-enyl, pent-1-, 2-, 3- or pent-4-enyl, hex-1-, 2-, 3-, 4- or hex-5-enyl, hept-1-, 2-, 3-, 4-, 5- or hept-6-enyl, oct-1-, 2-, 3-, 4-, 5-, 6- or oct-7-enyl, non-1-, 2-, 3-, 4-, 5-, 6-, 7- or non-8-enyl, dec-1-, 2-, 3-, 4-, 5-, 6-, 7-, 8- or dec-9-enyl.

Especially preferred alkenyl groups are C₂-C₇-1E-alkenyl, C₄-C₇-3E-alkenyl, C₅-C₇-4-alkenyl, C₆-C₇-5-alkenyl and C₇-6-alkenyl, in particular C₂-C₇-1E-alkenyl, C₄-C₇-3E-alkenyl and C₅-C₇-4-alkenyl. Examples for particularly preferred alkenyl groups are vinyl, 1E-propenyl, 1E-butenyl, 1E-pentenyl, 1E-hexenyl, 1E-heptenyl, 3-butenyl, 3E-pentenyl, 3E-hexenyl, 3E-heptenyl, 4-pentenyl, 4Z-hexenyl, 4E-hexenyl, 4Z-heptenyl, 5-hexenyl, 6-heptenyl and the like. Groups having up to 5 C atoms are generally preferred.

An oxaalkyl group, i.e. where one CH₂ group is replaced by —O—, is preferably straight-chain 2-oxapropyl (=methoxymethyl), 2-(=ethoxymethyl) or 3-oxabutyl (=2-methoxyethyl), 2-, 3-, or 4-oxapentyl, 2-, 3-, 4-, or 5-oxahexyl, 2-, 3-, 4-, 5-, or 6-oxaheptyl, 2-, 3-, 4-, 5-, 6- or 7-oxaoctyl, 2-, 3-, 4-, 5-, 6-, 7- or 8-oxanonyl or 2-, 3-, 4-, 5-, 6-, 7-, 8- or 9-oxadecyl, for example. Oxaalkyl, i.e. where one CH₂ group is replaced by —O—, is preferably straight-chain 2-oxapropyl (=methoxymethyl), 2-(=ethoxymethyl) or 3-oxabutyl (=2-methoxyethyl), 2-, 3-, or 4-oxapentyl, 2-, 3-, 4-, or 5-oxahexyl, 2-, 3-, 4-, 5-, or 6-oxaheptyl, 2-, 3-, 4-, 5-, 6- or 7-oxaoctyl, 2-, 3-, 4-, 5-, 6-, 7- or 8-oxanonyl or 2-, 3-, 4-, 5-, 6-, 7-, 8- or 9-oxadecyl, for example.

In an alkyl group wherein one CH₂ group is replaced by —O— and one by —C(O)—, these radicals are preferably neighboured. Accordingly these radicals together form a carbonyloxy group —C(O)—O— or an oxycarbonyl group —O—C(O)—. Preferably this group is straight-chain and has 2 to 6 C atoms. It is accordingly preferably acetyloxy, propionyloxy, butyryloxy, pentanoyloxy, hexanoyloxy, acetyloxymethyl, propionyloxymethyl, butyryloxymethyl, pentanoyloxymethyl, 2-acetyloxyethyl, 2-propionyloxy-ethyl, 2-butyryloxyethyl, 3-acetyloxypropyl, 3-propionyloxypropyl, 4-acetyloxybutyl, methoxycarbonyl, ethoxycarbonyl, propoxycarbonyl, butoxycarbonyl, pentoxycarbonyl, methoxycarbonylmethyl, ethoxy-carbonylmethyl, propoxycarbonylmethyl, butoxycarbonylmethyl, 2-(methoxycarbonyl)ethyl, 2-(ethoxycarbonyl)ethyl, 2-(propoxy-carbonyl)ethyl, 3-(methoxycarbonyl)propyl, 3-(ethoxycarbonyl)propyl, 4-(methoxycarbonyl)-butyl.

An alkyl group wherein two or more CH₂ groups are replaced by —O— and/or —C(O)O— can be straight-chain or branched. It is preferably straight-chain and has 3 to 12 C atoms. Accordingly it is preferably bis-carboxy-methyl, 2,2-bis-carboxy-ethyl, 3,3-bis-carboxy-propyl, 4,4-bis-carboxy-butyl, 5,5-bis-carboxy-pentyl, 6,6-bis-carboxy-hexyl, 7,7-bis-carboxy-heptyl, 8,8-bis-carboxy-octyl, 9,9-bis-carboxy-nonyl, 10,10-bis-carboxy-decyl, bis-(methoxycarbonyl)-methyl, 2,2-bis-(methoxycarbonyl)-ethyl, 3,3-bis-(methoxycarbonyl)-propyl, 4,4-bis-(methoxycarbonyl)-butyl, 5,5-bis-(methoxycarbonyl)-pentyl, 6,6-bis-(methoxycarbonyl)-hexyl, 7,7-bis-(methoxycarbonyl)-heptyl, 8,8-bis-(methoxycarbonyl)-octyl, bis-(ethoxycarbonyl)-methyl, 2,2-bis-(ethoxycarbonyl)-ethyl, 3,3-bis-(ethoxycarbonyl)-propyl, 4,4-bis-(ethoxycarbonyl)-butyl, 5,5-bis-(ethoxycarbonyl)-hexyl.

A thioalkyl group, i.e where one CH₂ group is replaced by —S—, is preferably straight-chain thiomethyl (—SCH₃), 1-thioethyl (—SCH₂CH₃), 1-thiopropyl (═—SCH₂CH₂CH₃), 1-(thiobutyl), 1-(thiopentyl), 1-(thiohexyl), 1-(thioheptyl), 1-(thiooctyl), 1-(thiononyl), 1-(thiodecyl), 1-(thioundecyl) or 1-(thiododecyl), wherein preferably the CH₂ group adjacent to the sp² hybridised vinyl carbon atom is replaced.

A fluoroalkyl group is preferably perfluoroalkyl CᵢF₂ᵢ₊₁, wherein i is an integer from 1 to 15, in particular CF₃, C₂F₅, C₃F₇, C₄F₉, C₅F₁₁, C₆F₁₃, C₇F₁₅ or C₈F₁₇, very preferably C₆F₁₃, or partially fluorinated alkyl, in particular 1,1-difluoroalkyl, all of which are straight-chain or branched.

The above-mentioned alkyl, alkoxy, alkenyl, oxaalkyl, thioalkyl, carbonyl and carbonyloxy groups can be achiral or chiral groups. Particularly preferred chiral groups are 2-butyl (=1-methylpropyl), 2-methylbutyl, 2-methylpentyl, 3-methylpentyl, 2-ethylhexyl, 2-propylpentyl, in particular 2-methylbutyl, 2-methylbutoxy, 2-methylpentoxy, 3-methylpentoxy, 2-ethyl-hexoxy, 1-methylhexoxy, 2-octyloxy, 2-oxa-3-methylbutyl, 3-oxa-4-methylpentyl, 4-methylhexyl, 2-hexyl, 2-octyl, 2-nonyl, 2-decyl, 2-dodecyl, 6-meth-oxyoctoxy, 6-methyloctoxy, 6-methyloctanoyloxy, 5-methylheptyloxy-carbonyl, 2-methylbutyryloxy, 3-methylvaleroyloxy, 4-methylhexanoyloxy, 2-chloropropionyloxy, 2-chloro-3-methylbutyryloxy, 2-chloro-4-methyl-valeryl-oxy, 2-chloro-3-methylvaleryloxy, 2-methyl-3-oxapentyl, 2-methyl-3-oxahexyl, 1-methoxypropyl-2-oxy, 1-ethoxypropyl-2-oxy, 1-propoxypropyl-2-oxy, 1-butoxypropyl-2-oxy, 2-fluorooctyloxy, 2-fluorodecyloxy, 1,1,1-trifluoro-2-octyloxy, 1,1,1-trifluoro-2-octyl, 2-fluoromethyloctyloxy for example. Very preferred are 2-hexyl, 2-octyl, 2-octyloxy, 1,1,1-trifluoro-2-hexyl, 1,1,1-trifluoro-2-octyl and 1,1,1-trifluoro-2-octyloxy.

Preferred achiral branched groups are isopropyl, isobutyl (=methylpropyl), isopentyl (=3-methylbutyl), tert. butyl, isopropoxy, 2-methyl-propoxy and 3-methylbutoxy.

In another preferred embodiment of the present invention, R^{1,2} are independently of each other selected from primary, secondary or tertiary alkyl or alkoxy with 1 to 30 C atoms, wherein one or more H atoms are optionally replaced by F, or aryl, aryloxy, heteroaryl or heteroaryloxy that is optionally alkylated or alkoxylated and has 4 to 30 ring atoms. Very preferred groups of this type are selected from the group consisting of the following formulae

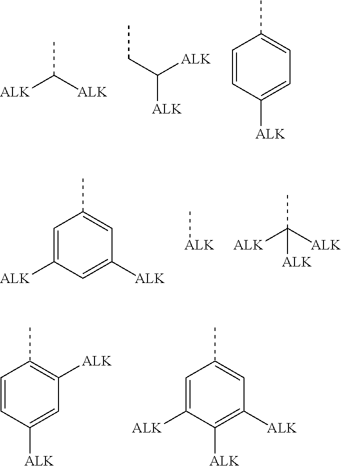

wherein “ALK” denotes optionally fluorinated, preferably linear, alkyl or alkoxy with 1 to 20, preferably 1 to 12 C-atoms, in case of tertiary groups very preferably 1 to 9 C atoms, and the dashed line denotes the link to the ring to which these groups are attached. Especially preferred among these groups are those wherein all ALK subgroups are identical.

—CY¹═CY²— is preferably —CH═CH—, —CF═CF— or —CH═C(CN)—.

Halogen is F, Cl, Br or I, preferably F, Cl or Br.

—CO—, —C(═O)— and —C(O)— denote a carbonyl group, i.e.

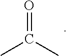

The compounds, units and polymers according to the present invention may also be substituted with a polymerisable or crosslinkable reactive group, which is optionally protected during the process of forming the polymer. Particular preferred units polymers of this type are those comprising one or more units of formula I wherein one or more of R¹⁻⁴ denote or contain a group P-Sp-. These units and polymers are particularly useful as semiconductors or charge transport materials, as they can be crosslinked via the groups P, for example by polymerisation in situ, during or after processing the polymer into a thin film for a semiconductor component, to yield crosslinked polymer films with high charge carrier mobility and high thermal, mechanical and chemical stability.

Preferably the polymerisable or crosslinkable group P is selected from CH₂═CW¹—C(O)—O—, CH₂═CW¹—C(O)—,

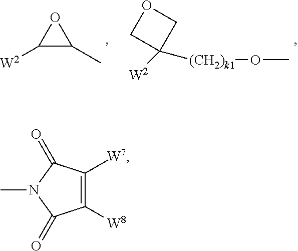

CH₂═CW²—(O)ₖ₁—, CW¹═CH—C(O)—(O)ₖ₃—, CW¹═CH—C(O)—NH—, CH₂═CW¹—C(O)—NH—, CH₃—CH═CH—O—, (CH₂═CH)₂CH—OC(O)—, (CH₂═CH—CH₂)₂CH—O—C(O)—, (CH₂═CH)₂CH—O—, (CH₂═CH—CH₂)₂N—, (CH₂═CH—CH₂)₂N—C(O)—, HO—CW²W³—, HS—CW²W³—, HW²N—, HO—CW²W³—NH—, CH₂═CH—(C(O)—O)ₖ₁-Phe-(O)ₖ₂—, CH₂═CH—(C(O))ₖ₁-Phe-(O)ₖ₂—, Phe-CH═CH—, HOOC—, OCN—, and W⁴W⁵W⁶Si—, with W¹ being H, F, Cl, CN, CF₃, phenyl or alkyl with 1 to 5 C-atoms, in particular H, Cl or CH₃, W² and W³ being independently of each other H or alkyl with 1 to 5 C-atoms, in particular H, methyl, ethyl or n-propyl, W⁴, W⁵ and W⁶ being independently of each other Cl, oxaalkyl or oxacarbonylalkyl with 1 to 5 C-atoms, W⁷ and W⁸ being independently of each other H, Cl or alkyl with 1 to 5 C-atoms, Phe being 1,4-phenylene that is optionally substituted by one or more groups L as defined above, k₁, k₂ and k₃ being independently of each other 0 or 1, k₃ preferably being 1, and k₄ being an integer from 1 to 10.

Alternatively P is a protected derivative of these groups which is non-reactive under the conditions described for the process according to the present invention. Suitable protective groups are known to the ordinary expert and described in the literature, for example in Green, “Protective Groups in Organic Synthesis”, John Wiley and Sons, New York (1981), like for example acetals or ketals.

Especially preferred groups P are CH₂═CH—C(O)—O—, CH₂═C(CH₃)—C(±)—O—, CH₂═CF—C(O)—O—, CH₂═CH—O—, (CH₂═CH)₂CH—O—C(O)—, (CH₂═CH)₂CH—O—,

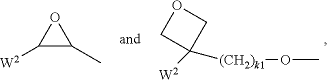

or protected derivatives thereof. Further preferred groups P are selected from the group consisting of vinyloxy, acrylate, methacrylate, fluoroacrylate, chloracrylate, oxetan and epoxy groups, very preferably from an acrylate or methacrylate group.

Polymerisation of group P can be carried out according to methods that are known to the ordinary expert and described in the literature, for example in D. J. Broer; G. Challa; G. N. Mol, Macromol. Chem., 1991, 192, 59.

The term “spacer group” is known in prior art and suitable spacer groups Sp are known to the ordinary expert (see e.g. Pure Appl. Chem. 73(5), 888 (2001). The spacer group Sp is preferably of formula Sp′-X′, such that P-Sp- is P-Sp′-X′-, wherein
Sp′ is alkylene with up to 30 C atoms which is unsubstituted or mono- or polysubstituted by F, Cl, Br, I or CN, it being also possible for one or more non-adjacent CH₂ groups to be replaced, in each case independently from one another, by —O—, —S—, —NH—, —NR⁰—, —SiR⁰R⁰⁰—, —C(O)—, —C(O)O—, —OC(O)—, —OC(O)—O—, —S—C(O)—, —C(O)—S—, —CH═CH— or —C≡C— in such a manner that O and/or S atoms are not linked directly to one another,
X′ is —O—, —S—, —C(O)—, —C(O)O—, —OC(O)—, —O—C(O)O—, —C(O)—NR⁰—, —NR⁰—C(O)—, —NR⁰—C(O)—NR⁰⁰—, —OCH₂—, —CH₂O—, —SCH₂—, —CH₂S—, —CF₂O—, —OCF₂—, —CF₂S—, —SCF₂—, —CF₂CH₂—, —CH₂CF₂—, —CF₂CF₂—, —CH═N—, —N═CH—, —N═N—, —CH═CR⁰—, —CY¹═CY²—, —C≡C—, —CH═CH—C(O)O—, —OC(O)—CH═CH— or a single bond,
R⁰ and R⁰⁰ are independently of each other H or alkyl with 1 to 12 C-atoms, and
Y¹ and Y² are independently of each other H, F, Cl or CN.
X′ is preferably —O—, —S—, —OCH₂—, —CH₂O—, —SCH₂—, —CH₂S—, —CF₂O—, —OCF₂—, —CF₂S—, —SCF₂—, —CH₂CH₂—, —CF₂CH₂—, —CH₂CF₂—, —CF₂CF₂—, —CH═N—, —N═CH—, —N═N—, —CH═CR⁰—, —CY¹═CY²—, —C≡C— or a single bond, in particular —O—, —S—, —C≡C—, —CY¹═CY²— or a single bond. In another preferred embodiment X′ is a group that is able to form a conjugated system, such as —C≡C— or —CY¹═CY²—, or a single bond.

Typical groups Sp′ are, for example, —(CH₂)ₚ—, —(CH₂CH₂O)_{q}—CH₂CH₂—, —CH₂CH₂—S—CH₂CH₂— or —CH₂CH₂—NH—CH₂CH₂— or —(SiR⁰R⁰⁰—O)ₚ—, with p being an integer from 2 to 12, q being an integer from 1 to 3 and R⁰ and R⁰⁰ having the meanings given above.

Preferred groups Sp′ are ethylene, propylene, butylene, pentylene, hexylene, heptylene, octylene, nonylene, decylene, undecylene, dodecylene, octadecylene, ethyleneoxyethylene, methyleneoxybutylene, ethylene-thioethylene, ethylene-N-methyl-iminoethylene, 1-methylalkylene, ethenylene, propenylene and butenylene for example.

Preferably in the units of formula I X¹, X², X³ and X⁴ denote S, O or Se, very preferably S.

Preferably the units of formula I are selected from the following formulae:

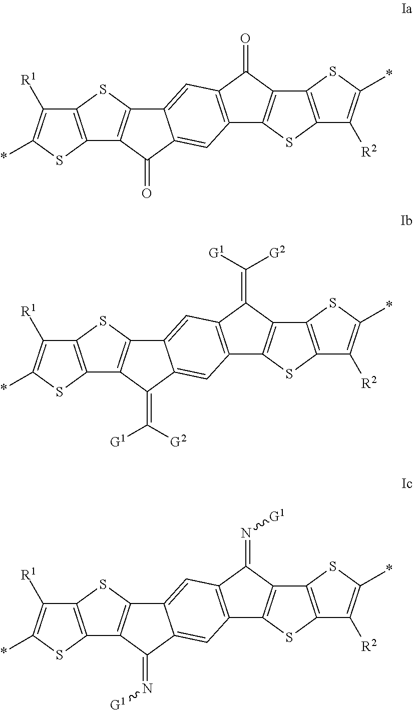

wherein R¹, R², G¹ and G² have the meanings given above and below.

In the units of formula I and its preferred subformulae, the electron withdrawing groups G¹ and G² are preferably selected from —CN, —C(═O)OR^{A}, —C(═O)R^{A}, —C(═O)—N(R^{A}R^{B}), perfluoroalkyl with 1 to 20 C atoms, —SO₃R^{A}, or —NO. Therein R^{A} and R^{B} independently of each other denote H, straight-chain alkyl with 1 to 20 C atoms, branched or cyclic alkyl with 3 to 30 C atoms, in which one or more H atoms are optionally replaced by F, or aryl, heteroaryl, aryloxy or heteroaryloxy with 4 to 20 ring atoms which is optionally substituted.

In the units of formula I and its preferred subformulae, R¹ and R² preferably denote straight-chain, branched or cyclic alkyl with 1 to 30 C atoms which is unsubstituted or substituted by one or more F atoms.

Further preferably one of R¹ and R² is H and the other is different from H, and is preferably straight-chain, branched or cyclic alkyl with 1 to 30 C atoms which is unsubstituted or substituted by one or more F atoms.

Further preferably R¹ and/or R² are independently of each other selected from the group consisting of aryl and heteroaryl, each of which is optionally fluorinated, alkylated or alkoxylated and has 4 to 30 ring atoms.

If R¹ and/or R² in formula I denote substituted aryl or heteroaryl, it is preferably substituted by one or more groups L, wherein L is selected from P-Sp-, F, Cl, Br, I, —OH, —CN, —NO₂, —NCO, —NCS, —OCN, —SCN, —C(═O)NR⁰R⁰⁰, —C(═O)X⁰, —C(═O)R⁰, —NR⁰R⁰⁰, C(═O)OH, optionally substituted aryl or heteroaryl having 4 to 20 ring atoms, or straight chain, branched or cyclic alkyl with 1 to 20, preferably 1 to 12 C atoms wherein one or more non-adjacent CH₂ groups are optionally replaced, in each case independently from one another, by —O—, —S—, —NR⁰—, —SiR⁰R⁰⁰—, —C(═O)—, —C(═O)O—, —CY¹═CY²— or —C≡C— in such a manner that 0 and/or S atoms are not linked directly to one another and which is unsubstituted or substituted with one or more F or Cl atoms or OH groups, and X⁰ is halogen, preferably F, Cl or Br, and Y¹, Y², R⁰ and R⁰⁰ have the meanings given above and below.

The compounds according to the present invention include small molecules, monomers, oligomers and polymers.

Oligomers and polymers according to the present invention preferably comprise one or more units of formula I as defined above and below.

Preferred polymers according to the present invention comprise one or more repeating units of formula II:

—[(Ar¹)ₐ—(U)_{b}—(Ar²)_{c}—(Ar³)_{d}]— II

wherein
U is a unit of formula I,
Ar¹, Ar², Ar^{a} are, on each occurrence identically or differently, and independently of each other, aryl or heteroaryl that is different from U, preferably has 5 to 30 ring atoms, and is optionally substituted, preferably by one or more groups R^{S},
R^{S} is on each occurrence identically or differently F, Br, Cl, —CN, —NC, —NCO, —NCS, —OCN, —SCN, —C(O)NR⁰R⁰⁰, —C(O)X⁰, —C(O)R⁰, —C(O)OR⁰, —NH₂, —NR⁰R⁰⁰, —SH, —SR⁰, —SO₃H, —SO₂R⁰, —OH, —NO₂, —CF₃, —SF₅, optionally substituted silyl, carbyl or hydrocarbyl with 1 to 40 C atoms that is optionally substituted and optionally comprises one or more hetero atoms, or P-Sp-,
R⁰ and R⁰⁰ are independently of each other H or optionally substituted C₁₋₄₀ carbyl or hydrocarbyl,
P is a polymerisable or crosslinkable group,
Sp is a spacer group or a single bond,
X⁰ is halogen, preferably F, Cl or Br,
a, b and c are on each occurrence identically or differently 0, 1 or 2,
d is on each occurrence identically or differently 0 or an integer from 1 to 10,
   wherein the polymer comprises at least one repeating unit of formula II wherein b is at least 1.

Further preferred polymers according to the present invention comprise, in addition to the units of formula I or II, one or more repeating units selected from monocyclic or polycyclic aryl or heteroaryl groups that are optionally substituted.

These additional repeating units are preferably selected of formula III

—[(Ar¹)ₐ-(D)_{b}-(Ar²)_{c}—(Ar³)_{d}]— III

wherein Ar¹, Ar², Ar³, a, b, c and d are as defined in formula II, and D is an aryl or heteroaryl group that is different from U and Ar¹⁻³, preferably has 5 to 30 ring atoms, is optionally substituted by one or more groups R^{S} as defined above and below, and is preferably selected from aryl or heteroaryl groups having electron donor properties, wherein the polymer comprises at least one repeating unit of formula III wherein b is at least 1.

R^{s} preferably has one of the meanings given for R¹.

The conjugated polymers according to the present invention are preferably selected of formula IV:

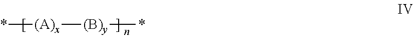

wherein
A is a unit of formula I or II or its preferred subformulae,
B is a unit that is different from A and comprises one or more aryl or heteroaryl groups that are optionally substituted, and is preferably selected of formula III,
x is >0 and 1,
y is 0 and <1,
x+y is 1, and
n is an integer >1.

Preferred polymers of formula IV are selected of the following formulae

*-[(Ar¹—U—Ar²)ₓ—(Ar³)]-* IVa

*-[(Ar¹—U—Ar²)ₓ—(Ar³—Ar³)_{y}]ₙ-* IVb

*-[(Ar¹—U—Ar²)ₓ—(Ar³—Ar³—Ar³)_{y}]ₙ-* IVc

*-[(Ar¹)ₐ—(U)_{b}—(Ar²)_{c}—(Ar³)_{d}]ₙ-* IVd

*-([(Ar¹)ₐ—(U)_{b}—(Ar²)_{c}—(Ar³)_{d}]ₓ—[(Ar¹)ₐ-(D)_{b}-(Ar²)_{c}—(Ar³)_{d}]_{y})-* IVe

wherein U, Ar¹, Ar², Ar³, a, b, c and d have in each occurrence identically or differently one of the meanings given in formula II, D has on each occurrence identically or differently one of the meanings given in formula III, and x, y and n are as defined in formula IV, wherein these polymers can be alternating or random copolymers, and wherein in formula IVd and IVe in at least one of the repeating units [(Ar¹)ₐ—(U)_{b}—(Ar²)_{c}—(Ar³)_{d}] and in at least one of the repeating units [(Ar¹)ₐ-(D)_{b}-(Ar²)_{c}—(Ar³)_{d}] b is at least 1.

In the polymers according to the present invention, the total number of repeating units n is preferably from 2 to 10,000. The total number of repeating units n is preferably ≧5, very preferably ≧10, most preferably ≧50, and preferably ≦500, very preferably ≦1,000, most preferably ≦2,000, including any combination of the aforementioned lower and upper limits of n.

The polymers of the present invention include homopolymers and copolymers, like statistical or random copolymers, alternating copolymers and block copolymers, as well as combinations thereof.

Especially preferred are polymers selected from the following groups:
Group A consisting of homopolymers of the unit U or (Ar¹—U) or (Ar¹—U—Ar²) or (Ar¹—U—Ar³) or (U—Ar²—Ar³) or (Ar¹—U—Ar²—Ar³), i.e. where all repeating units are identical,
Group B consisting of random or alternating copolymers formed by identical units (Ar¹—U—Ar²) and identical units (Ar³),
Group C consisting of random or alternating copolymers formed by identical units (Ar¹—U—Ar²) and identical units (A¹),
Group D consisting of random or alternating copolymers formed by identical units (Ar¹—U—Ar²) and identical units (Ar¹-D-Ar²),
   wherein in all these groups U, D, Ar¹, Ar² and Ar³ are as defined above and below, in groups A, B and C Ar¹, Ar² and Ar³ are different from a single bond, and in group D one of Ar¹ and Ar² may also denote a single bond.

Preferred polymers of formula IV and IVa to IVe are selected of formula V

R⁵-chain-R⁶ V

wherein “chain” denotes a polymer chain of formulae IV or IVa to IVe, and R⁵ and R⁶ have independently of each other one of the meanings of R¹ as defined above, and preferably denote, independently of each other, H, F, Br, Cl, I, —CH₂Cl, —CHO, —CR′═CR″₂, —SiR′R″R′″, —SiR′X′X″, —SiR′R″X′, —SnR′R″R′″, —BR′R″, —B(OR′)(OR″), —B(OH)₂, —O—SO₂—R′, —C≡CH, —C≡C—SiR′₃, —ZnX′, P-Sp- or an endcap group, wherein P and Sp are as defined in formula II, X′ and X″ denote halogen, R′, R″ and R′″ have independently of each other one of the meanings of R⁰ given in formula I, and two of R′, R″ and R′″ may also form a ring together with the hetero atom to which they are attached.

In the polymers represented by formula IV, IVa to IVe and V, x denotes the mole fraction of units A, y denotes the mole fraction of units B, and n denotes the degree of polymerisation or total number of units A and B. These formulae includes block copolymers, random or statistical copolymers and alternating copolymers of A and B, as well as homopolymers of A for the case when x is >0 and y is 0.

Another aspect of the invention relates to monomers of formula VI

R⁵—(Ar¹)ₐ—U—(Ar²)_{b}—R⁶ VI

wherein U, Ar¹, Ar², R⁵, R⁶, a and b have the meanings of formula II and V, or one of the preferred meanings as described above and below.

Especially preferred are monomers of the following formulae

R⁵—Ar¹—U—Ar²—R⁶ VI1

R⁵—U—R⁶ VI2

R⁵—Ar¹—U—R⁶ VI3

R⁵—U—Ar²—R⁶ VI4

wherein U, Ar¹, Ar², R⁵ and R⁶ are as defined in formula VI.

Especially preferred are monomers of formula VI wherein R⁵ and R⁶ are, preferably independently of each other, selected from the group consisting of Cl, Br, I, O-tosylate, O-triflate, O-mesylate, O-nonaflate, —SiMe₂F, —SiMeF₂, —O—SO₂Z¹, —B(OZ²)₂, —CZ³═C(Z³)₂, —C≡CH, —C≡CSi(Z¹)₃, —ZnX⁰ and —Sn(Z⁴)₃, wherein X⁰ is halogen, preferably Cl, Br or I, Z¹⁻⁴ are selected from the group consisting of alkyl and aryl, each being optionally substituted, and two groups Z² may also together form a cyclic group.

Preferably R¹ and/or R² denote independently of each other straight-chain or branched alkyl with 1 to 20 C atoms which is unsubstituted or substituted by one or more F atoms.

Especially preferred are repeating units, monomers and polymers of formulae I, II, Ill, IV, IVa-IVe, V, VI and their subformulae wherein one or more of D, Ar¹, Ar² and Ar³ denote aryl or heteroaryl, preferably having electron donor properties, selected from the group consisting of the following formulae

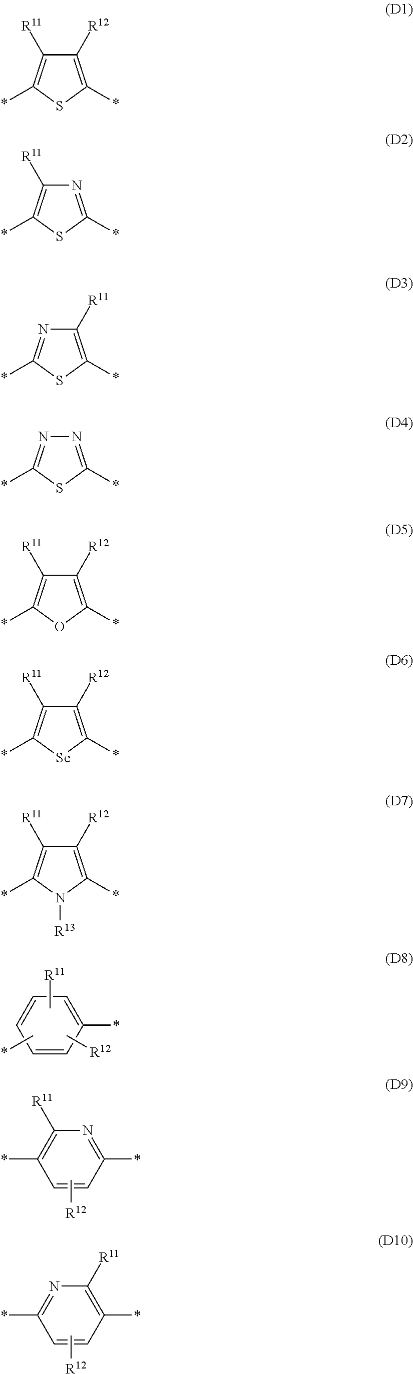

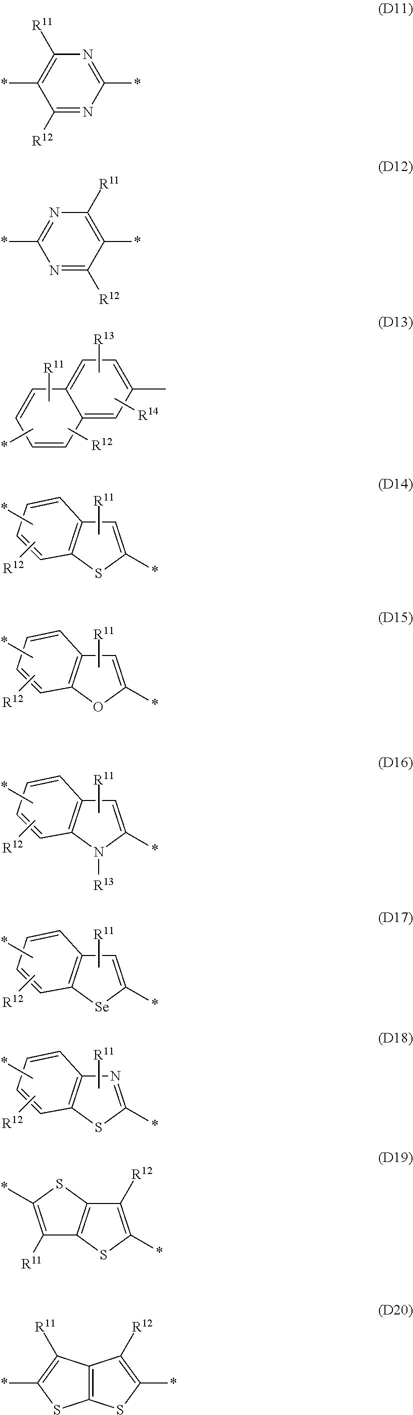

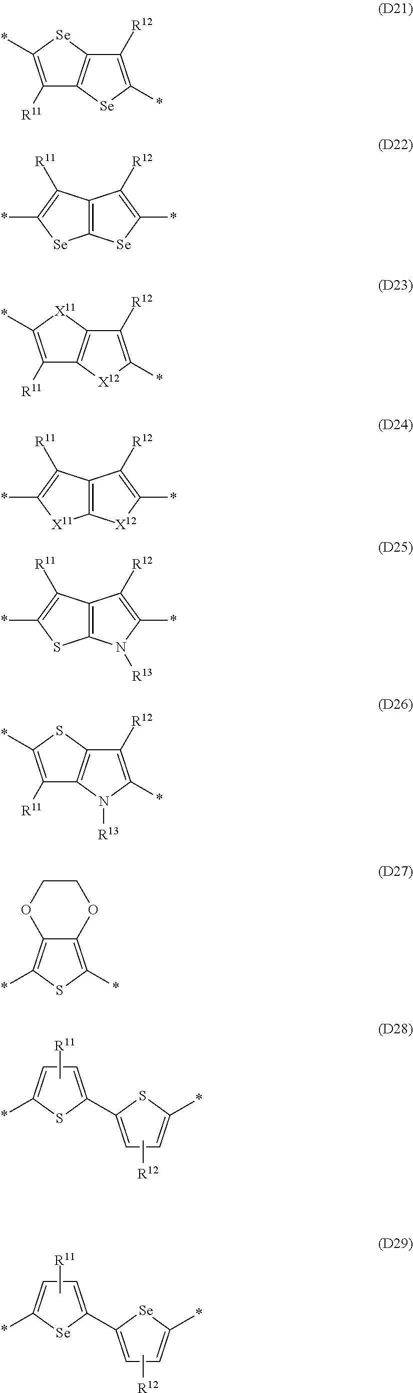

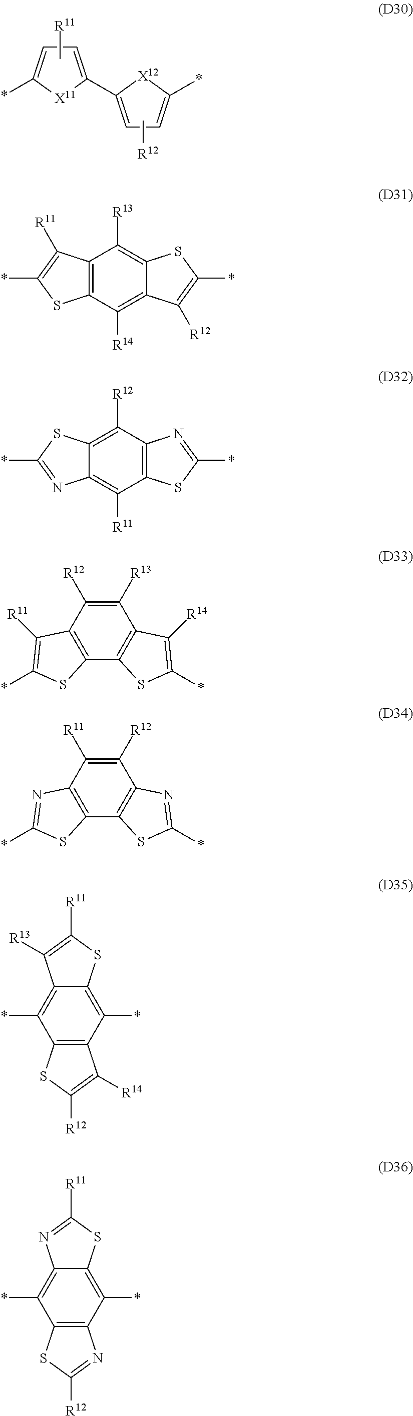

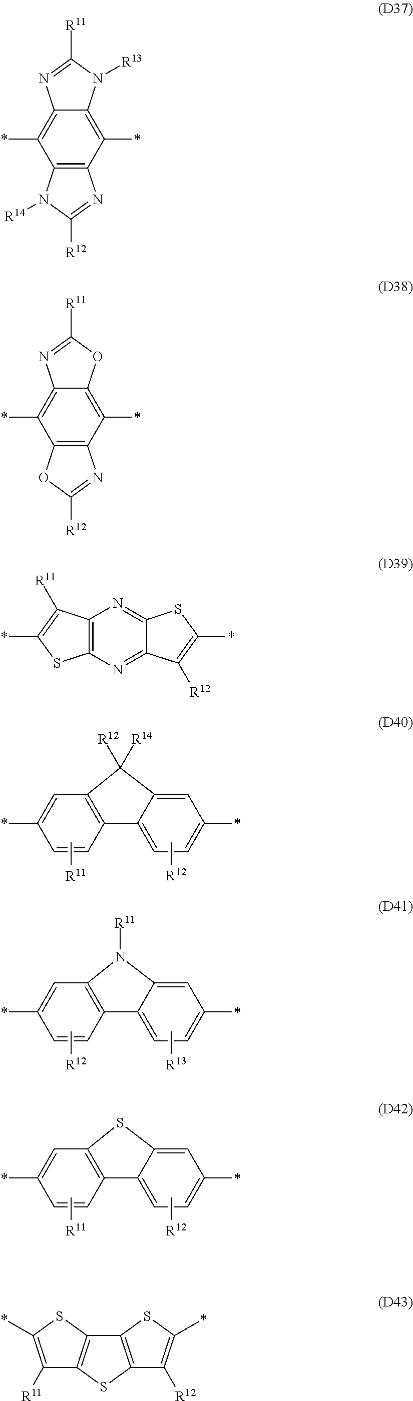

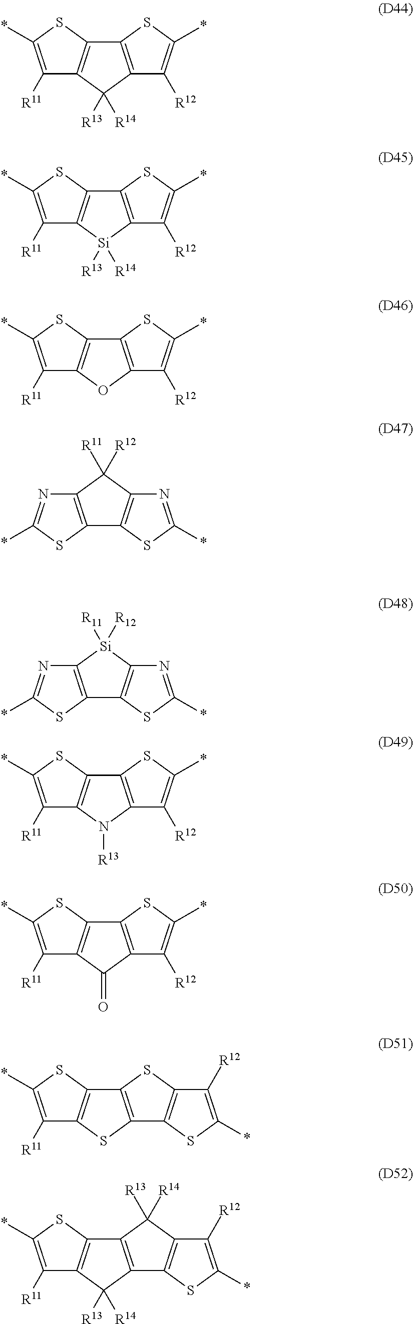

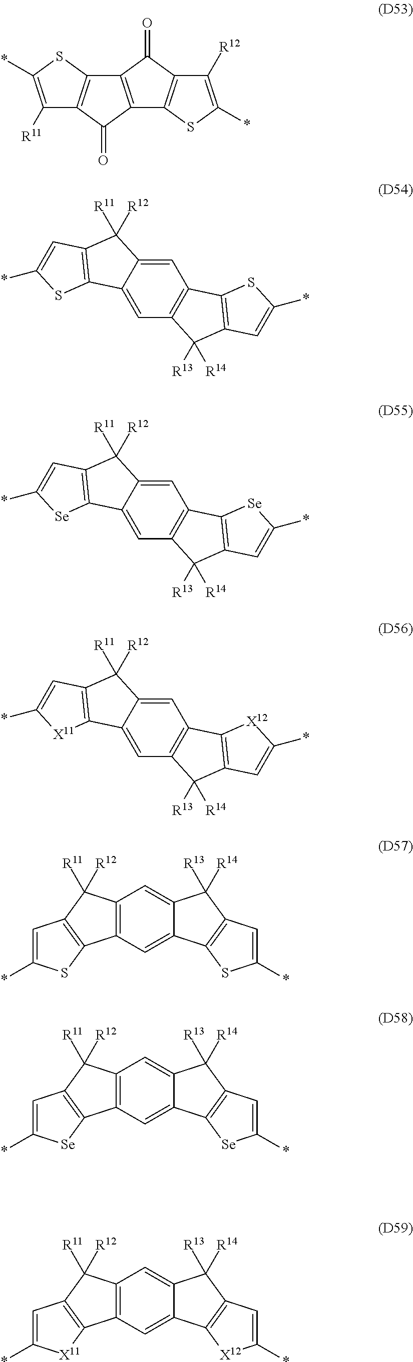

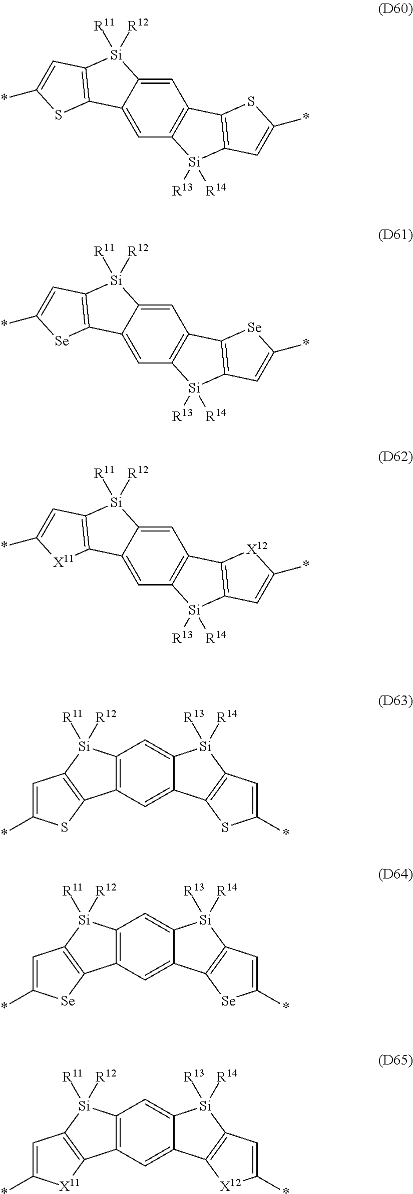

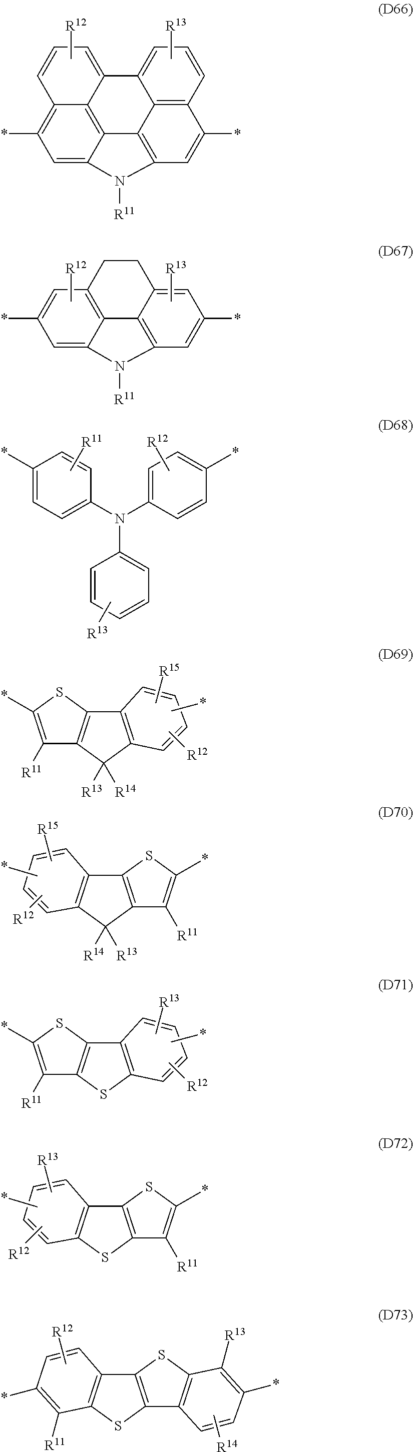

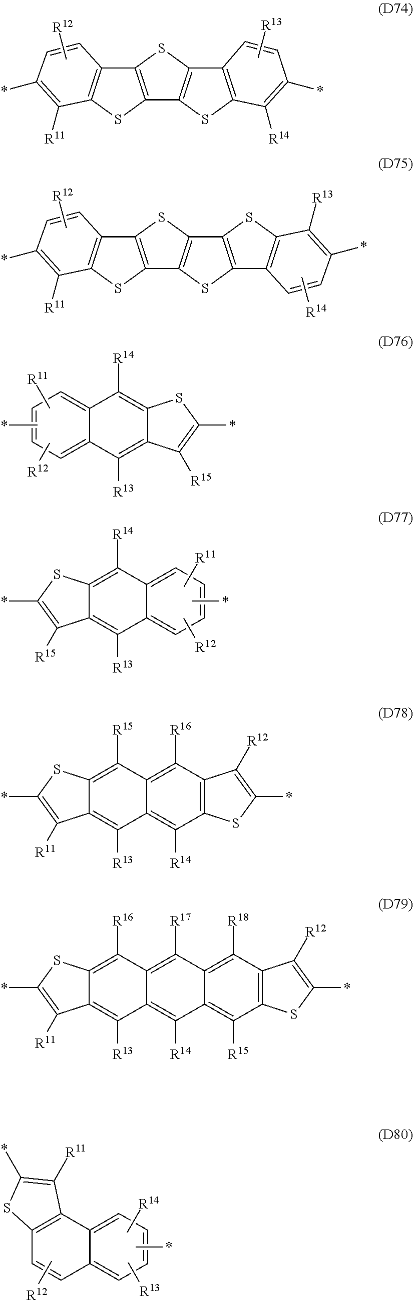

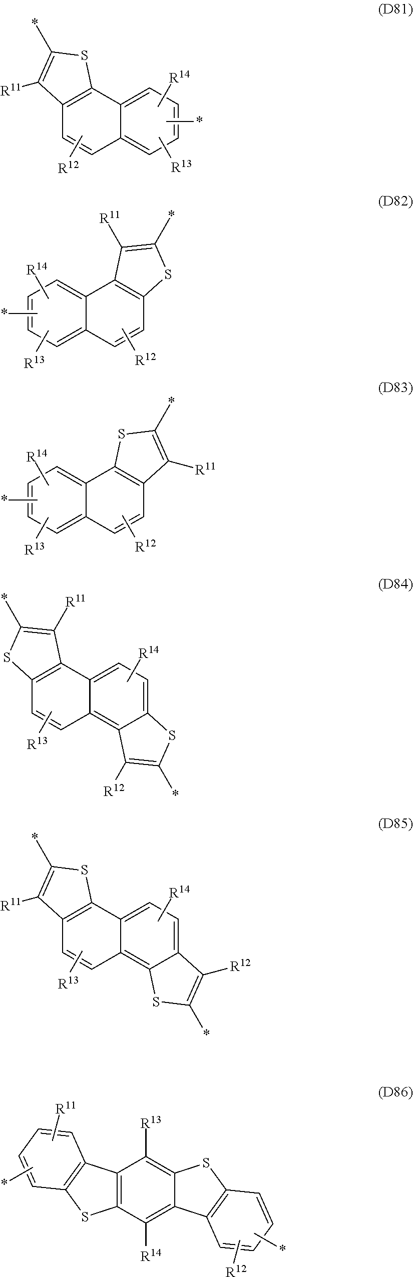

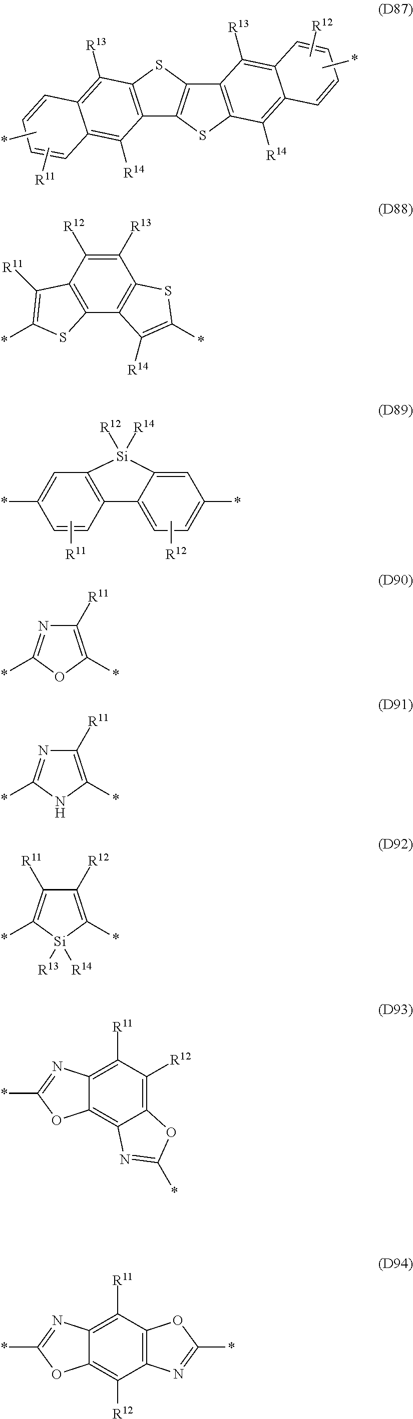

wherein one of X¹¹ and X¹² is S and the other is Se, and R¹¹, R¹², R¹³, R¹⁴, R¹⁵, R¹⁶, R¹⁷ and R¹⁸ independently of each other denote H or have one of the meanings of R³ as defined above and below.

Preferably one or more of D, Ar¹, Ar² and Ar³ are selected from the group consisting of formulae D1, D2, D3, D4, D5, D6, D7, D19, D21, D23, D28, D29 and D30, very preferably from formulae D1, D2, D3, D5, D19 and D28.

In another preferred embodiment invention in formula D1 R¹¹ and R¹² denote H or F. In another preferred embodiment of the present invention in formulae D2, D5, D6, D19, D20 and D28 R¹¹ and R¹² denote H or F.

Further preferred are repeating units, monomers and polymers of formulae I, II, Ill, IV, IVa to IVe, V, VI and their subformulae wherein Ar³ denotes aryl or heteroaryl, preferably having electron acceptor properties, selected from the group consisting of the following formulae

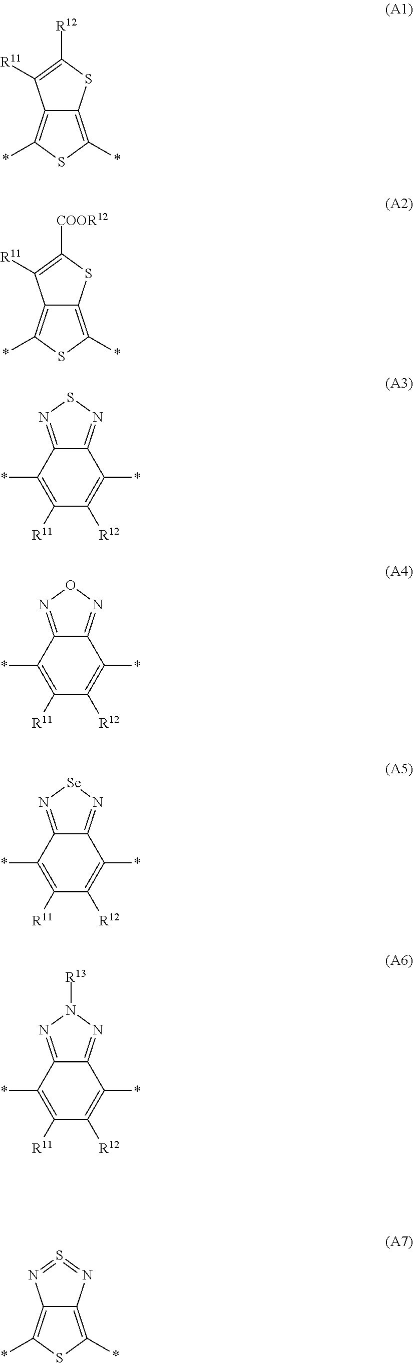

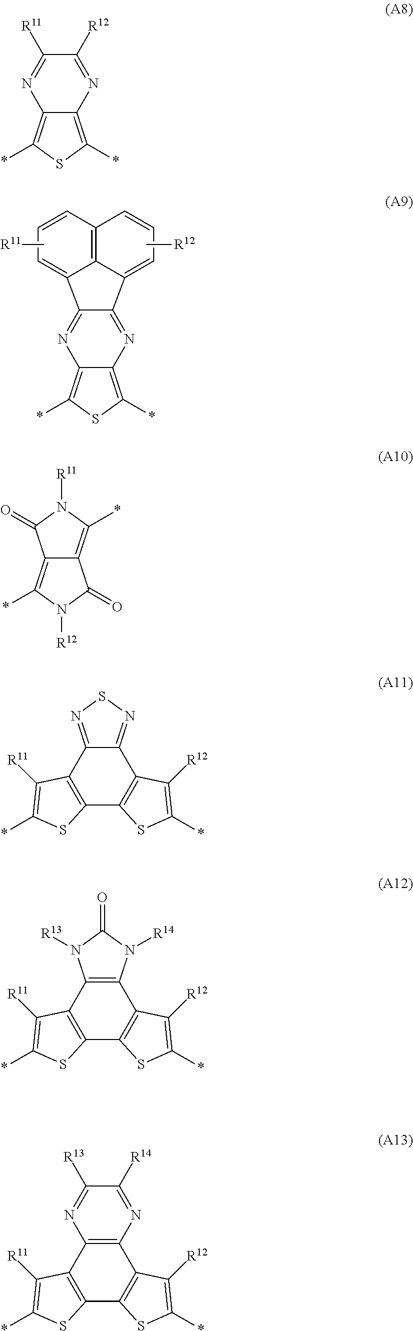

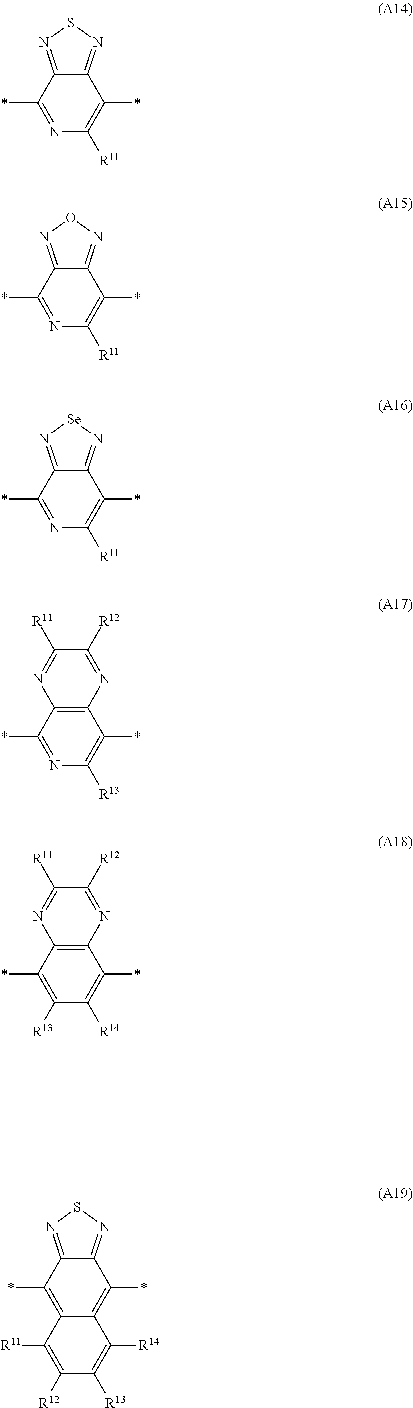

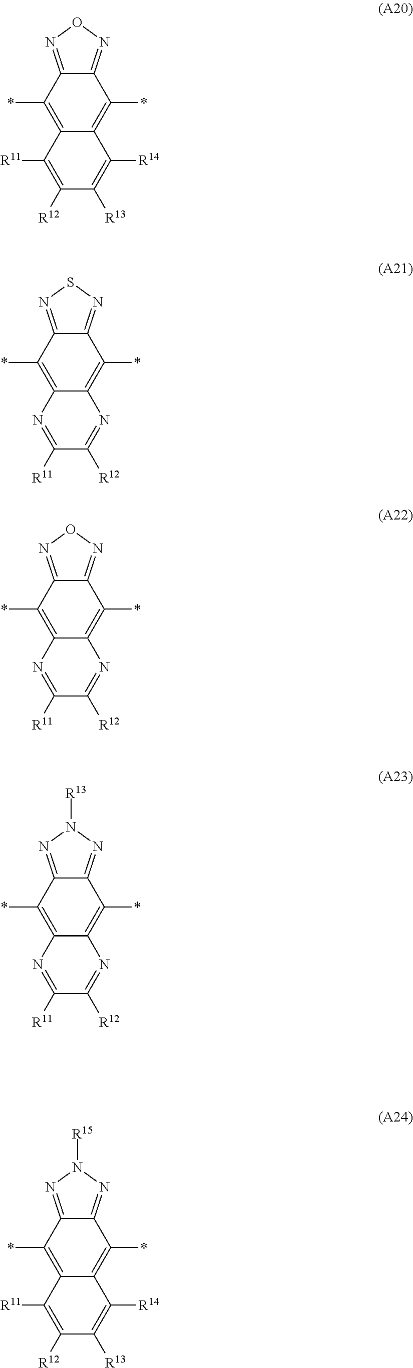

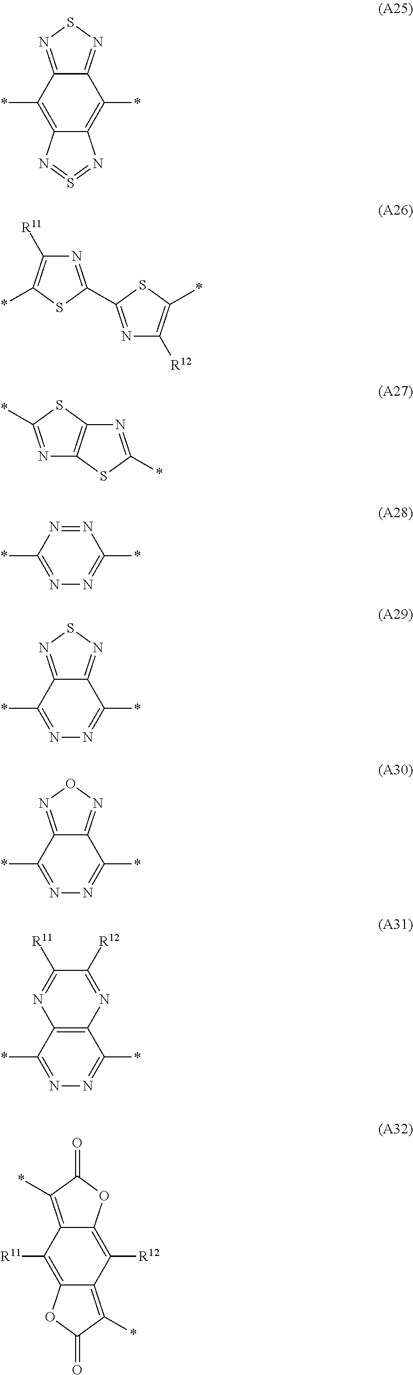

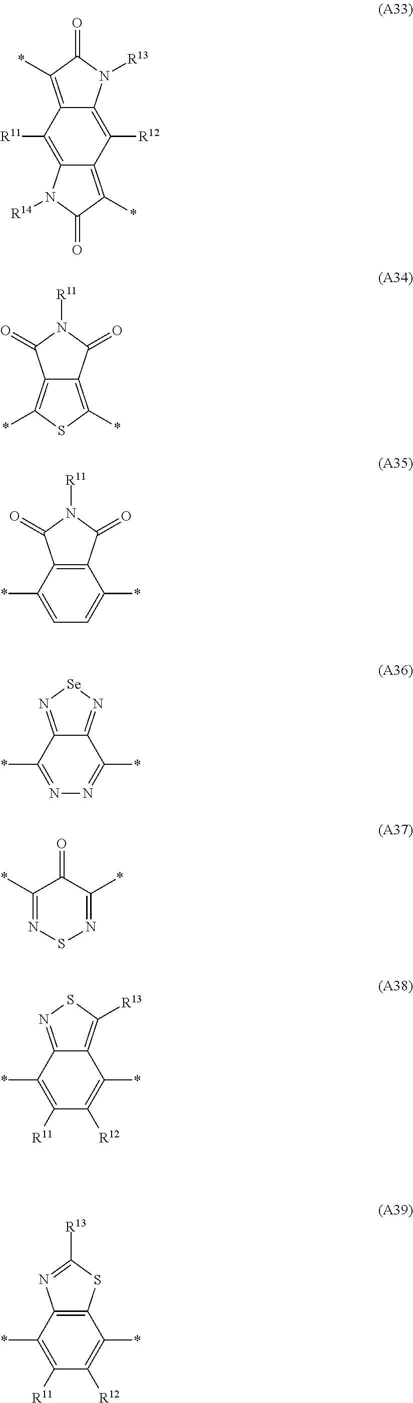

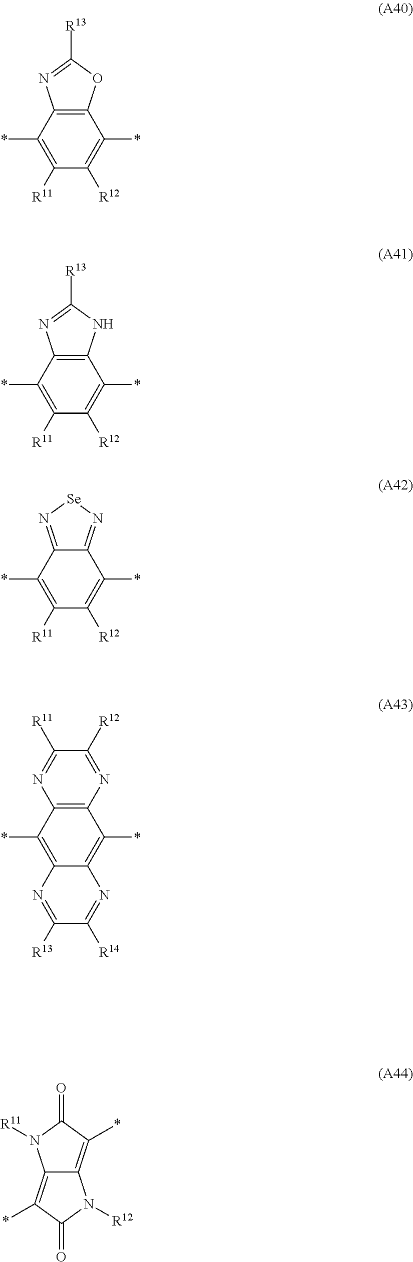

wherein one of X¹¹ and X¹² is S and the other is Se, and R¹¹, R¹², R¹³, R¹⁴ and R¹⁵ independently of each other denote H or have one of the meanings of R³ as defined above and below.

Preferably Ar³ is selected from the group consisting of formulae A1, A2, A3, A4, A5, A38 and A44, very preferably from formulae A2 and A3.

Further preferred are copolymers selected from the group consisting of the following subformulae

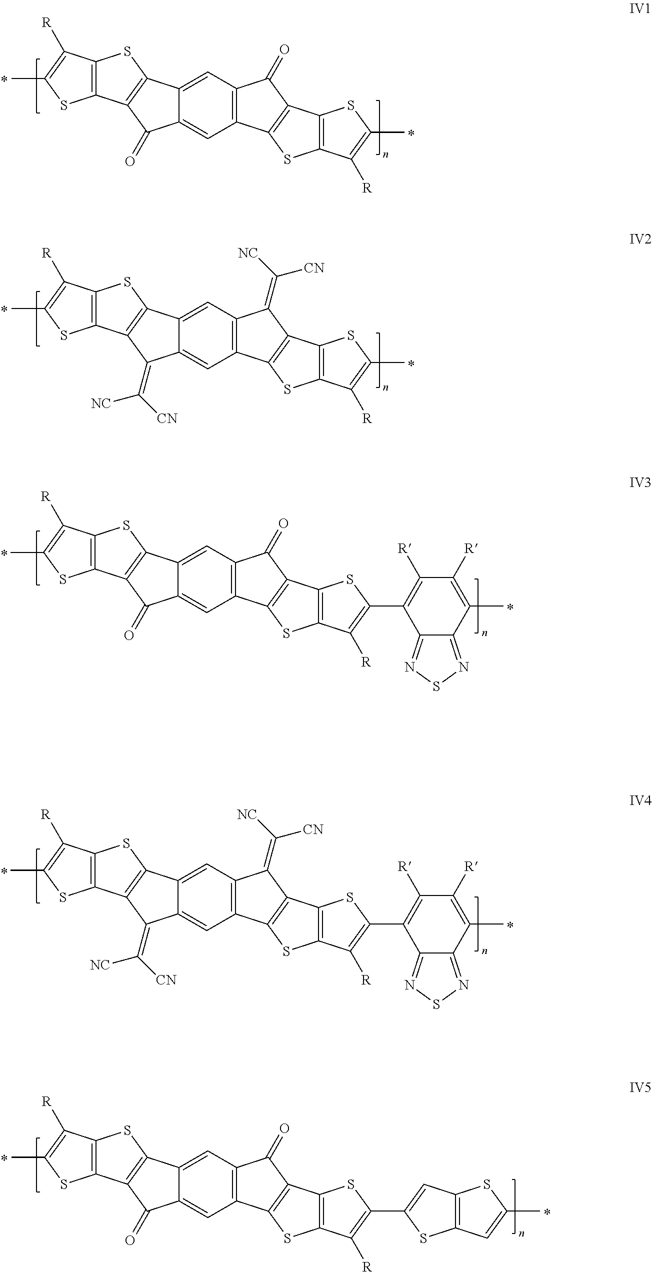

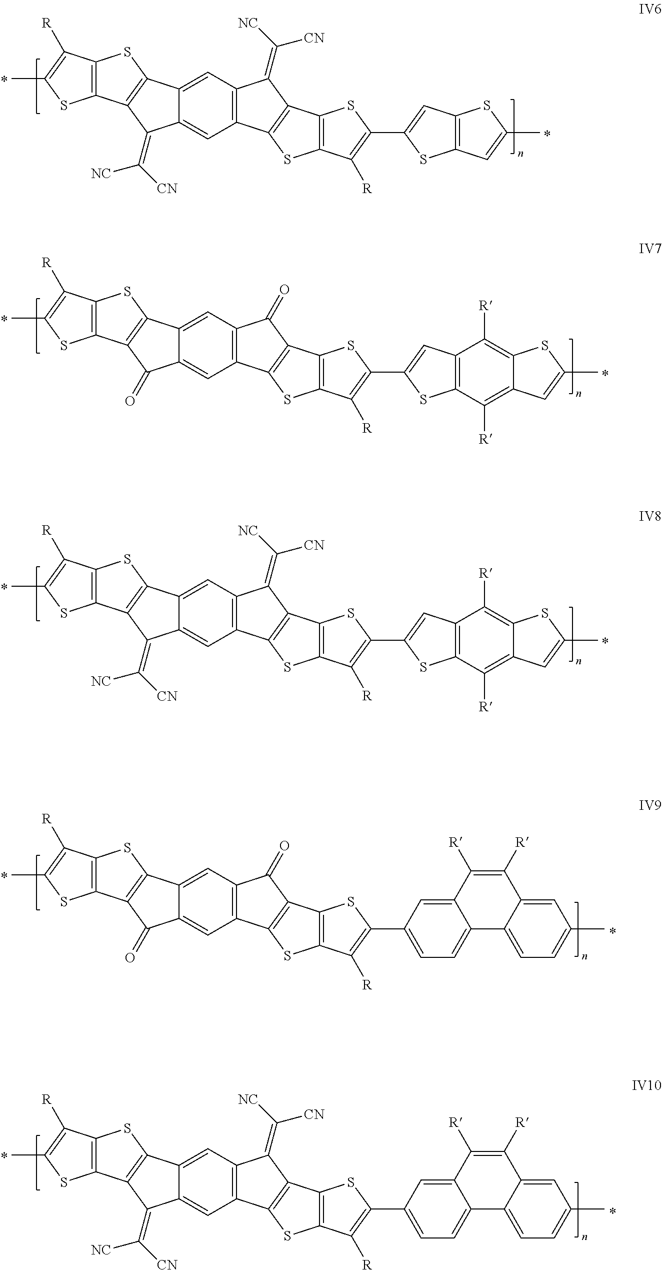

wherein R and R′ have independently of each other one of the meanings of R¹ as given above, and n has one of the meanings given above.

Small molecule compounds and oligomers according to the present invention are preferably selected of formula VII, VIII and IX,

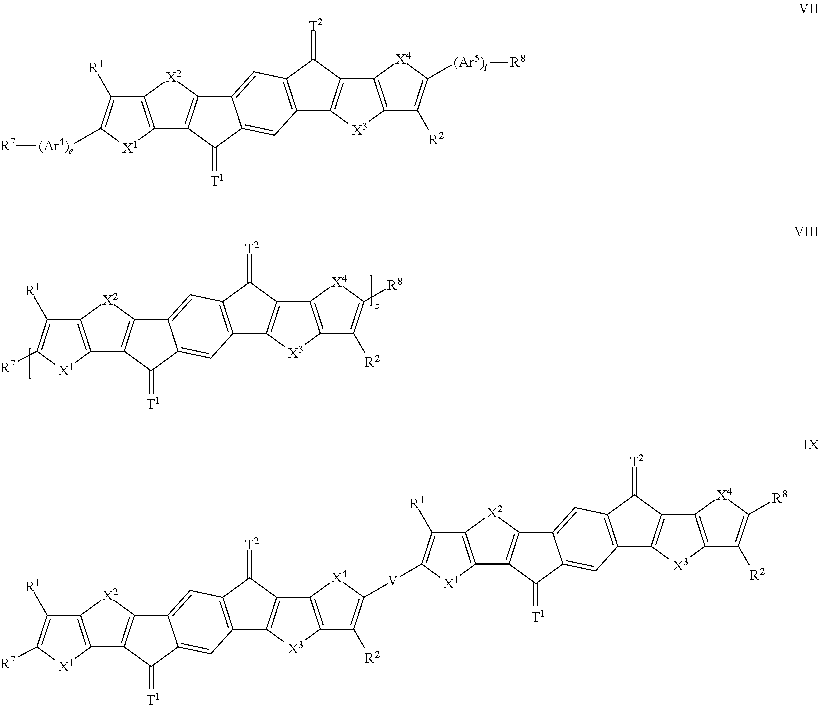

wherein R¹, R², T¹, T², X¹, X², X³ and X⁴ are as defined in formula I,
Ar⁴, Ar⁵ independently of each other and on each occurrence identically or differently have one of the meanings of Ar¹ or Ar³ as given in formula II or one of their preferred meanings given above and below, and one or two of Ar⁴ and Ar⁵ may also denote a unit of formula I,
R⁷, R⁸ independently of each other denote H, F, Br, Cl, —CN, —NC, —NCO, —NCS, —OCN, —SCN, —C(O)NR⁰R⁰⁰, —C(O)X⁰, —C(O)R⁰, —C(O)OR⁰, —O—C(O)R⁰, —NH₂, —NR⁰R⁰⁰, —SH, —SR⁰, —SO₃H, —SO₂R⁰, —OH, —NO₂, —CF₃, —SF₅, P-Sp-, or optionally substituted silyl, carbyl or hydrocarbyl with 1 to 40 C atoms that is optionally substituted and optionally comprises one or more hetero atoms, and wherein one or more C atoms are optionally replaced by a hetero atom, and R⁰, R⁰⁰ and X⁰ are as defined in formula II,
V is aryl or heteroaryl with 3 to 30 ring atoms which is optionally substituted, or denotes CY¹═CY² or C≡C,
Y¹, Y² are independently of each other H, F, Cl or CN,
e, f independently of each other denote 0, 1, 2 or 3, and
z is 2, 3 or 4.

Preferably R⁷ and R⁸ denote H, F or straight chain or branched alkyl or fluoroalkyl with 1 to 20 C atoms.

Especially preferred are compounds selected from the following formulae

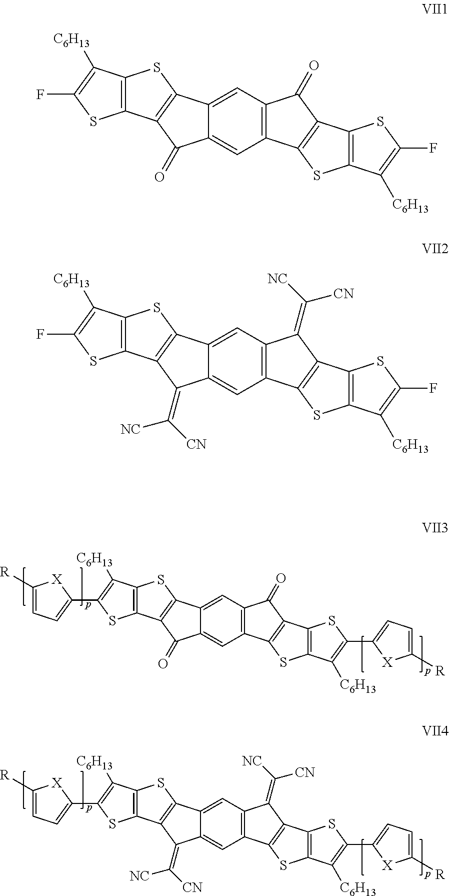

wherein p is 0, 1, 2, 3 or 4, X is O, S or Se, and R has one of the meanings of R⁷ as given above.

Further preferred are repeating units, monomers and polymers of formulae I, Ia-Ic, II, III, IV, IVa-IVe, IV1-IV10, V, VI, VII, VIII, IX, VII1-VII4 and their subformulae selected from the following list of preferred embodiments:
y is 0 and 1,
b=d=1 and a=c=0, preferably in all repeating units,
a=b=c=d=1, preferably in all repeating units,
a=b=d=1 and c=0, preferably in all repeating units,
a=b=c=1 and d=0, preferably in all repeating units,
a=c=2, b=1 and d=0, preferably in all repeating units,
a=c=2 and b=d=1, preferably in all repeating units,
X¹ and X² are S,
X¹ and X² are Se,
X¹ and X² are O,
X¹ and X² are Te,
T¹ and T² denote 0,
T¹ and T² denote CG¹G²,
T¹ and T² denote N-G¹,
G¹ and G² are selected from —CN, —C(═O)OR^{A}, —C(═O)R^{A}, —C(═O)—N(R^{A}R^{B}), perfluoroalkyl with 1 to 20 C atoms, —SO₃R^{A}, or —NO, wherein R^{A} and R^{B} independently of each other denote H, straight-chain alkyl with 1 to 20 C atoms, branched or cyclic alkyl with 3 to 30 C atoms, in which one or more H atoms are optionally replaced by F, or aryl, heteroaryl, aryloxy or heteroaryloxy with 4 to 20 ring atoms which is optionally substituted,
G¹ and G² are selected from —CN, —C(═O)H, —C(═O)OR^{C}, —C(═O)R^{C}, R^{D}, SO₃R^{C} wherein R^{C} is C₁-C₂₀ alkyl and R^{D} is C₁-C₂₀ perfluoroalkyl,
G¹ and G² denote CN,
n is at least 5, preferably at least 10, very preferably at least 50, and up to 2,000, preferably up to 500.
M_{w} is at least 5,000, preferably at least 8,000, very preferably at least 10,000, and preferably up to 300,000, very preferably up to 100,000,
one of R¹ and R² is H and the other is different from H,
R¹ and R² are different from H,
R¹ and/or R² are independently of each other selected from the group consisting of primary alkyl with 1 to 30 C atoms, secondary alkyl with 3 to 30 C atoms, and tertiary alkyl with 4 to 30 C atoms, wherein in all these groups one or more H atoms are optionally replaced by F,
R¹ and/or R² are independently of each other selected from the group consisting of aryl and heteroaryl, each of which is optionally fluorinated, alkylated or alkoxylated and has 4 to 30 ring atoms,
R¹ and/or R² are independently of each other selected from the group consisting of primary alkoxy or sulfanylalkyl with 1 to 30 C atoms, secondary alkoxy or sulfanylalkyl with 3 to 30 C atoms, and tertiary alkoxy or sulfanylalkyl with 4 to 30 C atoms, wherein in all these groups one or more H atoms are optionally replaced by F,
R¹ and/or R² are independently of each other selected from the group consisting of aryloxy, heteroaryloxy, each of which is optionally alkylated or alkoxylated and has 4 to 30 ring atoms,
R¹ and/or R² are independently of each other selected from the group consisting of alkylcarbonyl, alkoxycarbonyl and alkylcarbonyloxy, all of which are straight-chain or branched, are optionally fluorinated, and have from 1 to 30 C atoms,
R⁰ and R⁰⁰ are selected from H or C₁-C₁₀-alkyl,
R⁵ and R⁶ are selected from H, halogen, —CH₂Cl, —CHO, —CH═CH₂—SiR′R″R′″, —SnR′R″R′″, —BR′R″, —B(OR′)(OR″), —B(OH)₂, P-Sp, C₁-C₂₀-alkyl, C₁-C₂₀-alkoxy, C₂-C₂₀-alkenyl, C₁-C₂₀-fluoroalkyl and optionally substituted aryl or heteroaryl,

R⁵ and R⁶ are, preferably independently of each other, selected from the group consisting of Cl, Br, I, O-tosylate, O-triflate, O-mesylate, O-nonaflate, —SiMe₂F, —SiMeF₂, —O—SO₂Z¹, —B(OZ²)₂, —CZ³═C(Z⁴)₂, —C≡CH, C≡CSi(Z¹)₃, —ZnX⁰ and —Sn(Z⁴)₃, wherein X⁰ is halogen, Z¹⁻⁴ are selected from the group consisting of alkyl and aryl, each being optionally substituted, and two groups Z² may also form a cyclic group,
R⁷ and R⁸ denote H,
R⁷ and/or R⁸ denote F,
R⁷ and/or R⁸ have one of the meanings of R¹ as given in formula I or one of the preferred meanings of R¹ as given above an below,
R⁷ and/or R⁸ are independently of each other selected from the group consisting of primary alkyl with 1 to 30 C atoms, secondary alkyl with 3 to 30 C atoms, and tertiary alkyl with 4 to 30 C atoms, wherein in all these groups one or more H atoms are optionally replaced by F,
R⁷ and/or R⁸ are independently of each other selected from the group consisting of aryl and heteroaryl, each of which is optionally fluorinated, alkylated or alkoxylated and has 4 to 30 ring atoms
e and f are 0,
e and/or f denote 1 or 2.

The compounds of the present invention can be synthesized according to or in analogy to methods that are known to the skilled person and are described in the literature. Other methods of preparation can be taken from the examples. For example, the polymers can be suitably prepared by aryl-aryl coupling reactions, such as Yamamoto coupling, Suzuki coupling, Stille coupling, Sonogashira coupling, Heck coupling or Buchwald coupling. Suzuki coupling and Yamamoto coupling are especially preferred. The monomers which are polymerised to form the repeat units of the polymers can be prepared according to methods which are known to the person skilled in the art.

Preferably the polymers are prepared from monomers of formula Ia or its preferred embodiments as described above and below.

Another aspect of the invention is a process for preparing a polymer by coupling one or more identical or different monomeric units of formula I or monomers of formula Ia with each other and/or with one or more comonomers in a polymerisation reaction, preferably in an aryl-aryl coupling reaction.

Suitable and preferred comonomers are selected from the following formulae

R⁵—(Ar¹)ₐ-D-(Ar²)_{c}—R⁶ C

R⁵—Ar¹—R⁶ D

R⁵—Ar³—R⁶ E

wherein Ar¹, Ar², Ar³, a and c have one of the meanings of formula II or one of the preferred meanings given above and below, D has one of the meanings of formula III or one of the preferred meanings given above and below, and R⁵ and R⁶ have one of meanings of formula V or one of the preferred meanings given above and below.

Very preferred is a process for preparing a polymer by coupling one or more monomers selected from formula VI or formulae VI1-VI4 with one or more monomers of formula C, and optionally with one or more monomers selected from formula D and E, in an aryl-aryl coupling reaction.

For example, a first preferred embodiment of the present invention relates to a process of preparing a polymer by coupling a monomer of formula VI1

R⁵—Ar¹—U—Ar²—R⁶ VI1

with a monomer of formula C1

R⁵-D-R⁶ C1

in an aryl-aryl coupling reaction.

A second preferred embodiment of the present invention relates to a process of preparing a polymer by coupling a monomer of formula VI2

R⁵—U—R⁶ VI2

with a monomer of formula C2

R⁵—Ar¹-D-Ar^{e}—R⁶ C2

in an aryl-aryl coupling reaction.

A third preferred embodiment of the present invention relates to a process of preparing a polymer by coupling a monomer of formula VI2

R⁵—U—R⁶ VI2

with a monomer of formula C1

R⁵-D-R⁶ C1

and a monomer of formula D1

R⁵—Ar¹—R⁶ D1

in an aryl-aryl coupling reaction.

Preferred aryl-aryl coupling methods used in the processes described above and below are Yamamoto coupling, Kumada coupling, Negishi coupling, Suzuki coupling, Stille coupling, Sonogashira coupling, Heck coupling, C—H activation coupling, Ullmann coupling or Buchwald coupling. Especially preferred are Suzuki coupling, Negishi coupling, Stille coupling and Yamamoto coupling. Suzuki coupling is described for example in WO 0053656 A1. Negishi coupling is described for example in J. Chem. Soc., Chem. Commun., 1977, 683-684. Yamamoto coupling is described in for example in T. Yamamoto et al., Prog. Polym. Sci., 1993, 17, 1153-1205, or WO 2004022626 A1. For example, when using Yamamoto coupling, monomers having two reactive halide groups are preferably used. When using Suzuki coupling, monomers having two reactive boronic acid or boronic acid ester groups or two reactive halide groups are preferably used. When using Stille coupling, monomers having two reactive stannane groups or two reactive halide groups are preferably used. When using Negishi coupling, monomers having two reactive organozinc groups or two reactive halide groups are preferably used.

Suzuki and Stille polymerisation may be used to prepare homopolymers as well as statistical, alternating and block random copolymers. Statistical or block copolymers can be prepared for example from the above monomers wherein one of the reactive groups is halogen and the other reactive group is a boronic acid, boronic acid derivative group or and alkylstannane. The synthesis of statistical, alternating and block copolymers is described in detail for example in WO 03048225 A2 or WO 2005014688 A2.

Preferred catalysts, especially for Suzuki, Negishi or Stille coupling, are selected from Pd(0) complexes or Pd(II) salts. Preferred Pd(0) complexes are those bearing at least one phosphine ligand such as Pd(Ph₃P)₄. Another preferred phosphine ligand is tris(ortho-tolyl)phosphine, i.e. Pd(o-Tol₃P)₄. Preferred Pd(II) salts include palladium acetate, i.e. Pd(OAc)₂. Alternatively the Pd(0) complex can be prepared by mixing a Pd(0) dibenzylideneacetone complex, for example tris(dibenzyl-ideneacetone)dipalladium(0), bis(dibenzylideneacetone)palladium(0), or Pd(II) salts e.g. palladium acetate, with a phosphine ligand, for example triphenylphosphine, tris(ortho-tolyl)phosphine or tri(tert-butyl)phosphine. Suzuki coupling is performed in the presence of a base, for example sodium carbonate, potassium carbonate, lithium hydroxide, potassium phosphate or an organic base such as tetraethylammonium carbonate or tetraethylammonium hydroxide. Yamamoto coupling employs a Ni(0) complex, for example bis(1,5-cyclooctadienyl) nickel(0).

As alternatives to halogens as described above, leaving groups of formula —O—SO₂Z¹ can be used wherein Z¹ is as described above. Particular examples of such leaving groups are tosylate, mesylate and triflate.

Especially suitable and preferred synthesis methods of the repeating units, monomers and polymers of formulae I, Ia-Ic, II, III, IV, IVa-IVe, IV1-IV10, V, VI, VII, VIII, IX, VII1-VII4 and their subformulae are illustrated in the synthesis schemes shown hereinafter.

The synthetic protocol of both IDTT-dione type and IDTT-alkylidene type units is exemplarily shown in Scheme 1 below, in which the solublising alkyl group is exemplified by a 1-heptyldecyl group. 2-Heptylundecanoic acid (1) was transformed into the acid chloride (2) followed by a Friedel-Crafts acylation with 3,4-dibromothiophene to yield ketone (3). Nucleophilic substitution of the 3-bromine with ethyl 2-mercaptoacetate followed by a intramolecular condensation to yield the thieno[3,2-b]thiopene (TT) precursor 4. The carboxylic ester group on 4 was removed by a hydrolysis followed by a thermal decarboxylation to afford 3-bromo-6-alkyl-TT 6, which was then debrominated through a lithiation-protonation process to yield 3-alkyl-TT 7. One-pot lithiation-stannylation of 7 followed by a Stille cross-coupling with diethyl 2,5-dibromoterephthalate yielded the bis-TT terephthalate 8, which was hydrolysed to the corresponding diacid 9 under standard conditions. The diacid chloride, which was prepared by treating 9 with oxalyl chloride, underwent a two-fold ring-closure in the presence of AlCl₃ to yield 3,9-IDTT-dione 10. 3,9-dialkyl-2,8-dibromo IDTT-dione (11) was synthesised by direct bromination of 10 with N-bromosuccinimide (NBS).

2,8-Dibromo-TCNM-IDTT 12 was obtained by treating the dione with malononitrile and TiCl₄. Alternatively, 3,9-dialkyl-IDTT-dione (10) could be transformed into 3,9-dialkyl-TCNM-IDTT, which was then subjected to a dibromination to afford the monomer 12.

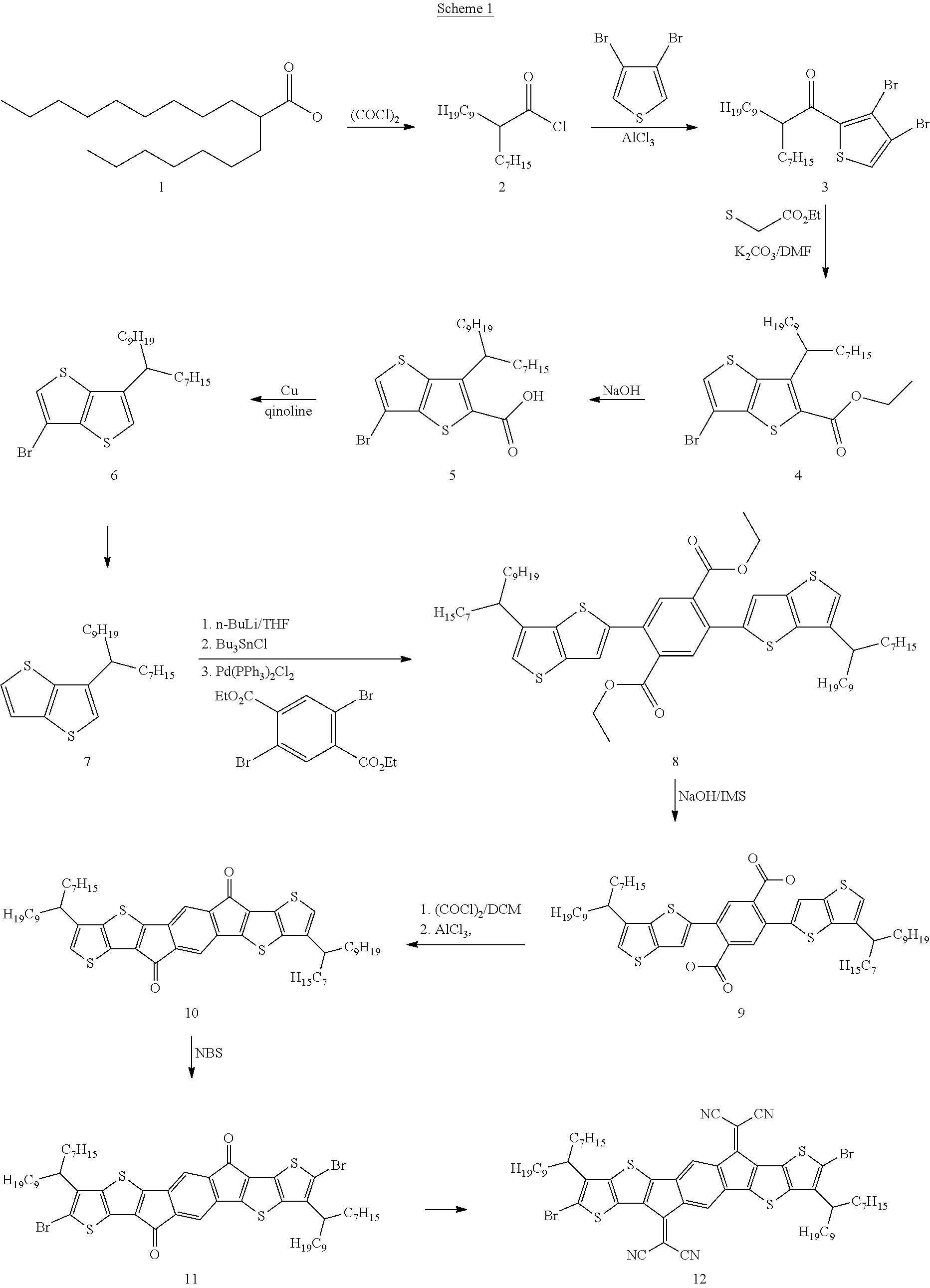

Typical copolymerization reactions of the IDTT unit are exemplarily illustrated for specific co-monomers in Scheme 2.

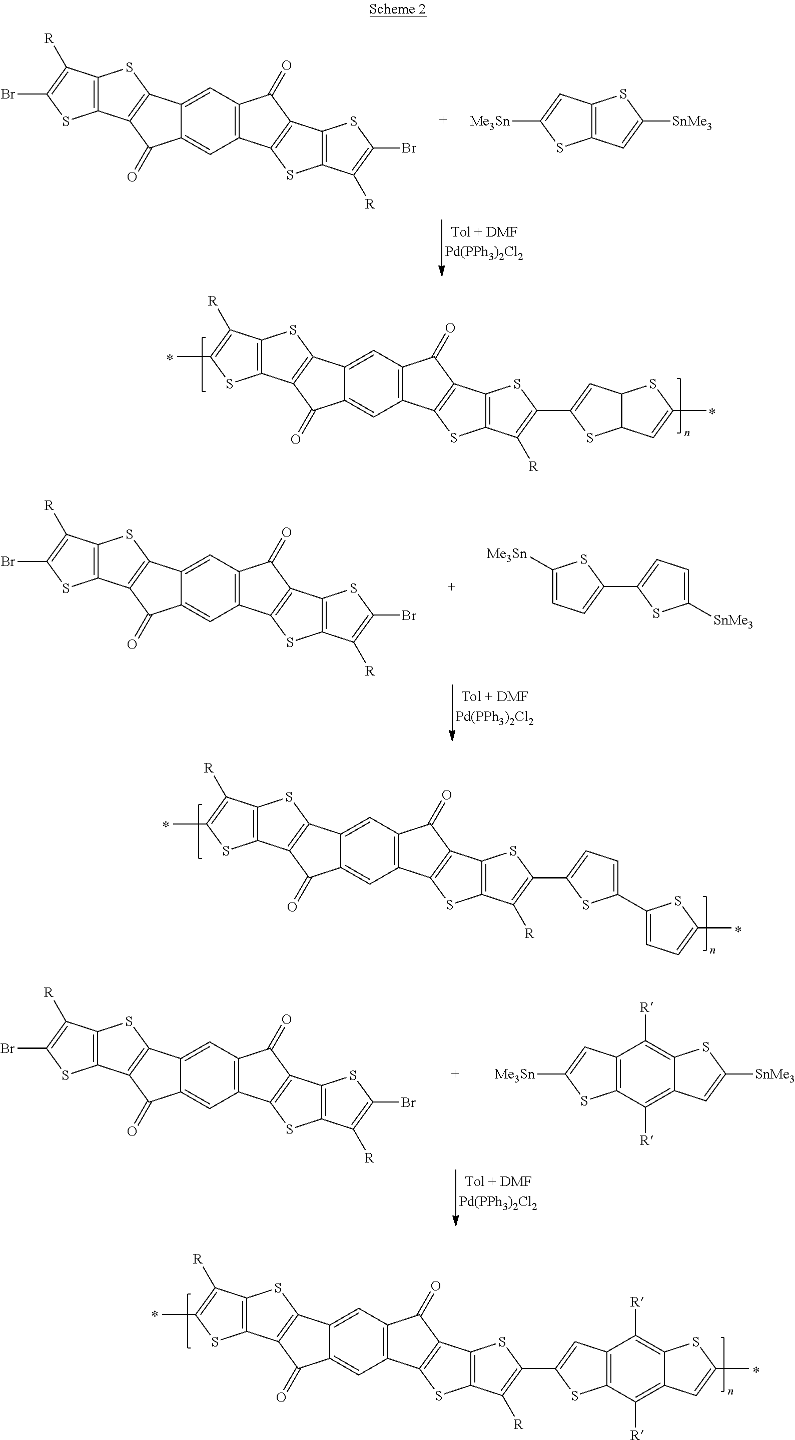

The novel methods of preparing monomers and polymers as described above and below are another aspect of the invention.

The compounds and polymers according to the present invention can also be used in mixtures or polymer blends, for example together with monomeric compounds or together with other polymers having charge-transport, semiconducting, electrically conducting, photoconducting and/or light emitting semiconducting properties, or for example with polymers having hole blocking or electron blocking properties for use as interlayers or charge blocking layers in OLED devices. Thus, another aspect of the invention relates to a polymer blend comprising one or more polymers according to the present invention and one or more further polymers having one or more of the above-mentioned properties. These blends can be prepared by conventional methods that are described in prior art and known to the skilled person. Typically the polymers are mixed with each other or dissolved in suitable solvents and the solutions combined.

Another aspect of the invention relates to a formulation comprising one or more small molecules, polymers, mixtures or polymer blends as described above and below and one or more organic solvents.

Preferred solvents are aliphatic hydrocarbons, chlorinated hydrocarbons, aromatic hydrocarbons, ketones, ethers and mixtures thereof. Additional solvents which can be used include 1,2,4-trimethylbenzene, 1,2,3,4-tetra-methyl benzene, pentylbenzene, mesitylene, cumene, cymene, cyclohexylbenzene, diethylbenzene, tetralin, decalin, 2,6-lutidine, 2-fluoro-m-xylene, 3-fluoro-o-xylene, 2-chlorobenzotrifluoride, N,N-dimethylformamide, 2-chloro-6-fluorotoluene, 2-fluoroanisole, anisole, 2,3-dimethylpyrazine, 4-fluoroanisole, 3-fluoroanisole, 3-trifluoro-methylanisole, 2-methylanisole, phenetol, 4-methylanisole, 3-methylanisole, 4-fluoro-3-methylanisole, 2-fluorobenzonitrile, 4-fluoroveratrol, 2,6-dimethylanisole, 3-fluorobenzo-nitrile, 2,5-dimethylanisole, 2,4-dimethylanisole, benzonitrile, 3,5-dimethyl-anisole, N,N-dimethylaniline, ethyl benzoate, 1-fluoro-3,5-dimethoxy-benzene, 1-methylnaphthalene, N-methylpyrrolidinone, 3-fluorobenzo-trifluoride, benzotrifluoride, dioxane, trifluoromethoxy-benzene, 4-fluorobenzotrifluoride, 3-fluoropyridine, toluene, 2-fluoro-toluene, 2-fluorobenzotrifluoride, 3-fluorotoluene, 4-isopropylbiphenyl, phenyl ether, pyridine, 4-fluorotoluene, 2,5-difluorotoluene, 1-chloro-2,4-difluorobenzene, 2-fluoropyridine, 3-chlorofluoro-benzene, 1-chloro-2,5-difluorobenzene, 4-chlorofluorobenzene, chloro-benzene, o-dichlorobenzene, 2-chlorofluorobenzene, p-xylene, m-xylene, o-xylene or mixture of o-, m-, and p-isomers. Solvents with relatively low polarity are generally preferred. For inkjet printing solvents and solvent mixtures with high boiling temperatures are preferred. For spin coating alkylated benzenes like xylene and toluene are preferred.

Examples of especially preferred solvents include, without limitation, dichloromethane, trichloromethane, chlorobenzene, o-dichlorobenzene, tetrahydrofuran, anisole, morpholine, toluene, o-xylene, m-xylene, p-xylene, 1,4-dioxane, acetone, methylethylketone, 1,2-dichloroethane, 1,1,1-trichloroethane, 1,1,2,2-tetrachloroethane, ethyl acetate, n-butyl acetate, N,N-dimethylformamide, dimethylacetamide, dimethylsulfoxide, tetraline, decaline, indane, methyl benzoate, ethyl benzoate, mesitylene and/or mixtures thereof.

The concentration of the compounds or polymers in the solution is preferably 0.1 to 10% by weight, more preferably 0.5 to 5% by weight. Optionally, the solution also comprises one or more binders to adjust the rheological properties, as described for example in WO 2005055248 A1.

After the appropriate mixing and ageing, solutions are evaluated as one of the following categories: complete solution, borderline solution or insoluble. The contour line is drawn to outline the solubility parameter-hydrogen bonding limits dividing solubility and insolubility. ‘Complete’ solvents falling within the solubility area can be chosen from literature values such as published in “Crowley, J. D., Teague, G. S. Jr and Lowe, J. W. Jr., Journal of Paint Technology, 1966, 38 (496), 296”. Solvent blends may also be used and can be identified as described in “Solvents, W. H. Ellis, Federation of Societies for Coatings Technology, p9-10, 1986”. Such a procedure may lead to a blend of ‘non’ solvents that will dissolve both the polymers of the present invention, although it is desirable to have at least one true solvent in a blend.

The compounds and polymers according to the present invention can also be used in patterned OSC layers in the devices as described above and below. For applications in modern microelectronics it is generally desirable to generate small structures or patterns to reduce cost (more devices/unit area), and power consumption. Patterning of thin layers comprising a polymer according to the present invention can be carried out for example by photolithography, electron beam lithography or laser patterning.

For use as thin layers in electronic or electrooptical devices the compounds, polymers, polymer blends or formulations of the present invention may be deposited by any suitable method. Liquid coating of devices is more desirable than vacuum deposition techniques. Solution deposition methods are especially preferred. The formulations of the present invention enable the use of a number of liquid coating techniques. Preferred deposition techniques include, without limitation, dip coating, spin coating, ink jet printing, nozzle printing, letter-press printing, screen printing, gravure printing, doctor blade coating, roller printing, reverse-roller printing, offset lithography printing, dry offset lithography printing, flexographic printing, web printing, spray coating, curtain coating, brush coating, slot dye coating or pad printing.

Ink-jet printing is particularly preferred when high resolution layers and devices needs to be prepared. Selected formulations of the present invention may be applied to prefabricated device substrates by ink jet printing or microdispensing. Preferably industrial piezoelectric print heads such as but not limited to those supplied by Aprion, Hitachi-Koki, InkJet Technology, On Target Technology, Picojet, Spectra, Trident, Xaar may be used to apply the organic semiconductor layer to a substrate. Additionally semi-industrial heads such as those manufactured by Brother, Epson, Konica, Seiko Instruments Toshiba TEC or single nozzle microdispensers such as those produced by Microdrop and Microfab may be used.

In order to be applied by ink jet printing or microdispensing, the compounds or polymers should be first dissolved in a suitable solvent. Solvents must fulfil the requirements stated above and must not have any detrimental effect on the chosen print head. Additionally, solvents should have boiling points >100° C., preferably >140° C. and more preferably >150° C. in order to prevent operability problems caused by the solution drying out inside the print head. Apart from the solvents mentioned above, suitable solvents include substituted and non-substituted xylene derivatives, di-C₁₋₂-alkyl formamide, substituted and non-substituted anisoles and other phenol-ether derivatives, substituted heterocycles such as substituted pyridines, pyrazines, pyrimidines, pyrrolidinones, substituted and non-substituted N,N-di-C₁₋₂-alkylanilines and other fluorinated or chlorinated aromatics.

A preferred solvent for depositing a compound or polymer according to the present invention by ink jet printing comprises a benzene derivative which has a benzene ring substituted by one or more substituents wherein the total number of carbon atoms among the one or more substituents is at least three. For example, the benzene derivative may be substituted with a propyl group or three methyl groups, in either case there being at least three carbon atoms in total. Such a solvent enables an ink jet fluid to be formed comprising the solvent with the compound or polymer, which reduces or prevents clogging of the jets and separation of the components during spraying. The solvent(s) may include those selected from the following list of examples: dodecylbenzene, 1-methyl-4-tert-butylbenzene, terpineol, limonene, isodurene, terpinolene, cymene, diethylbenzene. The solvent may be a solvent mixture, that is a combination of two or more solvents, each solvent preferably having a boiling point >100° C., more preferably >140° C. Such solvent(s) also enhance film formation in the layer deposited and reduce defects in the layer.

The ink jet fluid (that is mixture of solvent, binder and semiconducting compound) preferably has a viscosity at 20° C. of 1-100 mPa·s, more preferably 1-50 mPa·s and most preferably 1-30 mPa·s.

The polymer blends and formulations according to the present invention can additionally comprise one or more further components or additives selected for example from surface-active compounds, lubricating agents, wetting agents, dispersing agents, hydrophobing agents, adhesive agents, flow improvers, defoaming agents, deaerators, diluents which may be reactive or non-reactive, auxiliaries, colourants, dyes or pigments, sensitizers, stabilizers, nanoparticles or inhibitors.

The compounds and polymers to the present invention are useful as charge transport, semiconducting, electrically conducting, photoconducting or light emitting materials in optical, electrooptical, electronic, electroluminescent or photoluminescent components or devices. In these devices, the polymers of the present invention are typically applied as thin layers or films.

Thus, the present invention also provides the use of the semiconducting compound, polymer, polymers blend, formulation or layer in an electronic device. The formulation may be used as a high mobility semiconducting material in various devices and apparatus. The formulation may be used, for example, in the form of a semiconducting layer or film. Accordingly, in another aspect, the present invention provides a semiconducting layer for use in an electronic device, the layer comprising a compound, polymer, polymer blend or formulation according to the invention. The layer or film may be less than about 30 microns. For various electronic device applications, the thickness may be less than about 1 micron thick. The layer may be deposited, for example on a part of an electronic device, by any of the aforementioned solution coating or printing techniques.

The invention additionally provides an electronic device comprising a compound, polymer, polymer blend, formulation or organic semiconducting layer according to the present invention. Especially preferred devices are OFETs, TFTs, ICs, logic circuits, capacitors, RFID tags, OLEDs, OLETs, OPEDs, OPVs, OPDs, solar cells, laser diodes, photoconductors, photodetectors, electrophotographic devices, electrophotographic recording devices, organic memory devices, sensor devices, charge injection layers, Schottky diodes, planarising layers, antistatic films, conducting substrates and conducting patterns.

Especially preferred electronic device are OFETs, OLEDs, OPV and OPD devices, in particular bulk heterojunction (BHJ) OPV devices. In an OFET, for example, the active semiconductor channel between the drain and source may comprise the layer of the invention. As another example, in an OLED device, the charge (hole or electron) injection or transport layer may comprise the layer of the invention.

For use in OPV or OPD devices the polymer according to the present invention is preferably used in a formulation that comprises or contains, more preferably consists essentially of, very preferably exclusively of, a p-type (electron donor) semiconductor and an n-type (electron acceptor) semiconductor. The p-type semiconductor is constituted by a polymer according to the present invention. The n-type semiconductor can be an inorganic material such as zinc oxide (ZnOₓ), zinc tin oxide (ZTO), titan oxide (TiOₓ), molybdenum oxide (MoOₓ), nickel oxide (NiOₓ), or cadmium selenide (CdSe), or an organic material such as graphene or a fullerene or substituted fullerene, for example an indene-C₆₀-fullerene bisaduct like ICBA, or a (6,6)-phenyl-butyric acid methyl ester derivatized methano C₆₀ fullerene, also known as “PCBM-C₆₀” or “C₆₀PCBM”, as disclosed for example in G. Yu, J. Gao, J. C. Hummelen, F. Wudl, A. J. Heeger, Science 1995, Vol. 270, p. 1789 ff and having the structure shown below, or structural analogous compounds with e.g. a C₆₁ fullerene group, a C₇₀ fullerene group, or a C₇₁ fullerene group, or an organic polymer (see for example Coakley, K. M. and McGehee, M. D. Chem. Mater. 2004, 16, 4533).

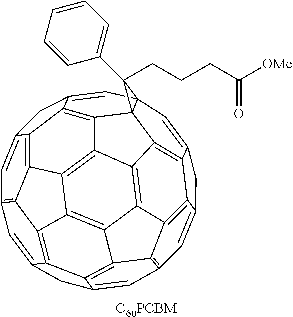

Preferably the polymer according to the present invention is blended with an n-type semiconductor such as a fullerene or substituted fullerene, like for example PCBM-C₆₀, PCBM-C₇₀, PCBM-C₆₁, PCBM-C₇₁, bis-PCBM-C₆₁, bis-PCBM-C₇₁, ICBA (1′,1″,4′,4″-tetrahydro-di[1,4]methanonaphthaleno [1,2:2′,3′; 56,60:2″,3″][5,6]fullerene-C60-Ih), graphene, or a metal oxide, like for example, ZnOₓ, TiOₓ, ZTO, MoOₓ, NiOₓ to form the active layer in an OPV or OPD device. The device preferably further comprises a first transparent or semi-transparent electrode on a transparent or semi-transparent substrate on one side of the active layer, and a second metallic or semi-transparent electrode on the other side of the active layer.

Further preferably the OPV or OPD device comprises, between the active layer and the first or second electrode, one or more additional buffer layers acting as hole transporting layer and/or electron blocking layer, which comprise a material such as metal oxide, like for example, ZTO, MoOₓ, NiOₓ a conjugated polymer electrolyte, like for example PEDOT:PSS, a conjugated polymer, like for example polytriarylamine (PTAA), an organic compound, like for example N,N′-diphenyl-N,N′-bis(1-naphthyl)(1,1′-biphenyl)-4,4′ diamine (NPB), N,N′-diphenyl-N,N′-(3-methylphenyl)-1,1′-biphenyl-4,4′-diamine (TPD), or alternatively as hole blocking layer and/or electron transporting layer, which comprise a material such as metal oxide, like for example, ZnOₓ, TiOₓ, a salt, like for example LiF, NaF, CsF, a conjugated polymer electrolyte, like for example poly[3-(6-trimethylammoniumhexyl)thiophene], poly(9,9-bis(2-ethylhexyl)-fluorene]-b-poly[3-(6-trimethylammoniumhexyl)thiophene], or poly [(9,9-bis(3′-(N,N-dimethylamino)propyl)-2,7-fluorene)-alt-2,7-(9,9-dioctylfluorene)] or an organic compound, like for example tris(8-quinolinolato)-aluminium(III) (Alq₃), 4,7-diphenyl-1,10-phenanthroline.

In a blend or mixture of a polymer according to the present invention with a fullerene or modified fullerene, the ratio polymer:fullerene is preferably from 5:1 to 1:5 by weight, more preferably from 1:1 to 1:3 by weight, most preferably 1:1 to 1:2 by weight. A polymeric binder may also be included, from 5 to 95% by weight. Examples of binder include polystyrene (PS), polypropylene (PP) and polymethylmethacrylate (PMMA).

To produce thin layers in BHJ OPV devices the compounds, polymers, polymer blends or formulations of the present invention may be deposited by any suitable method. Liquid coating of devices is more desirable than vacuum deposition techniques. Solution deposition methods are especially preferred. The formulations of the present invention enable the use of a number of liquid coating techniques. Preferred deposition techniques include, without limitation, dip coating, spin coating, ink jet printing, nozzle printing, letter-press printing, screen printing, gravure printing, doctor blade coating, roller printing, reverse-roller printing, offset lithography printing, dry offset lithography printing, flexographic printing, web printing, spray coating, dip coating, curtain coating, brush coating, slot dye coating or pad printing. For the fabrication of OPV devices and modules area printing method compatible with flexible substrates are preferred, for example slot dye coating, spray coating and the like.

Suitable solutions or formulations containing the blend or mixture of a polymer according to the present invention with a C₆₀ or C₇₀ fullerene or modified fullerene like PCBM must be prepared. In the preparation of formulations, suitable solvent must be selected to ensure full dissolution of both component, p-type and n-type and take into account the boundary conditions (for example rheological properties) introduced by the chosen printing method.

Organic solvent are generally used for this purpose. Typical solvents can be aromatic solvents, halogenated solvents or chlorinated solvents, including chlorinated aromatic solvents. Examples include, but are not limited to chlorobenzene, 1,2-dichlorobenzene, chloroform, 1,2-dichloroethane, dichloromethane, carbon tetrachloride, toluene, cyclohexanone, ethylacetate, tetrahydrofuran, anisole, morpholine, o-xylene, m-xylene, p-xylene, 1,4-dioxane, acetone, methylethylketone, 1,2-dichloroethane, 1,1,1-trichloroethane, 1,1,2,2-tetrachloroethane, ethyl acetate, n-butyl acetate, dimethylformamide, dimethylacetamide, dimethylsulfoxide, tetraline, decaline, indane, methyl benzoate, ethyl benzoate, mesitylene and combinations thereof.

The OPV device can for example be of any type known from the literature (see e.g. Waldauf et al., Appl. Phys. Lett., 2006, 89, 233517).

A first preferred OPV device according to the invention comprises the following layers (in the sequence from bottom to top):
optionally a substrate,
a high work function electrode, preferably comprising a metal oxide, like for example ITO, serving as anode,
an optional conducting polymer layer or hole transport layer, preferably comprising an organic polymer or polymer blend, for example of PEDOT:PSS (poly(3,4-ethylenedioxythiophene): poly(styrene-sulfonate), or TBD (N,N′-dyphenyl-N-N′-bis(3-methylphenyl)-1,1′ biphenyl-4,4′-diamine) or NBD (N,N′-dyphenyl-N-N′-bis(1-napthylphenyl)-1,1′ biphenyl-4,4′-diamine),
a layer, also referred to as “active layer”, comprising a p-type and an n-type organic semiconductor, which can exist for example as a p-typen-type bilayer or as distinct p-type and n-type layers, or as blend or p-type and n-type semiconductor, forming a BHJ,
optionally a layer having electron transport properties, for example comprising LiF,
a low work function electrode, preferably comprising a metal like for example aluminum, serving as cathode,
wherein at least one of the electrodes, preferably the anode, is transparent to visible light, and
wherein the p-type semiconductor is a polymer according to the present invention.

A second preferred OPV device according to the invention is an inverted OPV device and comprises the following layers (in the sequence from bottom to top):
optionally a substrate,
a high work function metal or metal oxide electrode, comprising for example ITO, serving as cathode,
a layer having hole blocking properties, preferably comprising a metal oxide like TiOₓ or Znₓ,
an active layer comprising a p-type and an n-type organic semiconductor, situated between the electrodes, which can exist for example as a p-typen-type bilayer or as distinct p-type and n-type layers, or as blend or p-type and n-type semiconductor, forming a BHJ,
an optional conducting polymer layer or hole transport layer, preferably comprising an organic polymer or polymer blend, for example of PEDOT:PSS or TBD or NBD,
an electrode comprising a high work function metal like for example silver, serving as anode,
wherein at least one of the electrodes, preferably the cathode, is transparent to visible light, and
wherein the p-type semiconductor is a polymer according to the present invention.

In the OPV devices of the present invention the p-type and n-type semiconductor materials are preferably selected from the materials, like the polymerfullerene systems, as described above.

When the active layer is deposited on the substrate, it forms a BHJ that phase separates at nanoscale level. For discussion on nanoscale phase separation see Dennler et al, Proceedings of the IEEE, 2005, 93 (8), 1429 or Hoppe et al, Adv. Func. Mater, 2004, 14(10), 1005. An optional annealing step may be then necessary to optimize blend morpohology and consequently OPV device performance.

Another method to optimize device performance is to prepare formulations for the fabrication of OPV(BHJ) devices that may include high boiling point additives to promote phase separation in the right way. 1,8-Octanedithiol, 1,8-dilodooctane, nitrobenzene, chloronaphthalene, and other additives have been used to obtain high-efficiency solar cells. Examples are disclosed in J. Peet, et al, Nat. Mater, 2007, 6, 497 or Fréchet et al. J. Am. Chem. Soc., 2010, 132, 7595-7597.

The compounds, polymers, formulations and layers of the present invention are also suitable for use in an OFET as the semiconducting channel. Accordingly, the invention also provides an OFET comprising a gate electrode, an insulating (or gate insulator) layer, a source electrode, a drain electrode and an organic semiconducting channel connecting the source and drain electrodes, wherein the organic semiconducting channel comprises a compound, polymer, polymer blend, formulation or organic semiconducting layer according to the present invention. Other features of the OFET are well known to those skilled in the art.

OFETs where an OSC material is arranged as a thin film between a gate dielectric and a drain and a source electrode, are generally known, and are described for example in U.S. Pat. No. 5,892,244, U.S. Pat. No. 5,998,804, U.S. Pat. No. 6,723,394 and in the references cited in the background section. Due to the advantages, like low cost production using the solubility properties of the compounds according to the invention and thus the processability of large surfaces, preferred applications of these FETs are such as integrated circuitry, TFT displays and security applications.

The gate, source and drain electrodes and the insulating and semiconducting layer in the OFET device may be arranged in any sequence, provided that the source and drain electrode are separated from the gate electrode by the insulating layer, the gate electrode and the semiconductor layer both contact the insulating layer, and the source electrode and the drain electrode both contact the semiconducting layer.

An OFET device according to the present invention preferably comprises:
a source electrode,
a drain electrode,
a gate electrode,
a semiconducting layer,
one or more gate insulator layers,
optionally a substrate.
   wherein the semiconductor layer preferably comprises a compound, polymer, polymer blend or formulation as described above and below.

The OFET device can be a top gate device or a bottom gate device. Suitable structures and manufacturing methods of an OFET device are known to the skilled in the art and are described in the literature, for example in US 20070102696 A1.

The gate insulator layer preferably comprises a fluoropolymer, like e.g. the commercially available Cytop 809M® or Cytop 107M® (from Asahi Glass). Preferably the gate insulator layer is deposited, e.g. by spin-coating, doctor blading, wire bar coating, spray or dip coating or other known methods, from a formulation comprising an insulator material and one or more solvents with one or more fluoro atoms (fluorosolvents), preferably a perfluorosolvent. A suitable perfluorosolvent is e.g. FC75® (available from Acros, catalogue number 12380). Other suitable fluoropolymers and fluorosolvents are known in prior art, like for example the perfluoropolymers Teflon AF® 1600 or 2400 (from DuPont) or Fluoropel® (from Cytonix) or the perfluorosolvent FC 43® (Acros, No. 12377). Especially preferred are organic dielectric materials having a low permittivity (or dielectric constant) from 1.0 to 5.0, very preferably from 1.8 to 4.0 (“low k materials”), as disclosed for example in US 20070102696 A1 or U.S. Pat. No. 7,095,044.

In security applications, OFETs and other devices with semiconducting materials according to the present invention, like transistors or diodes, can be used for RFID tags or security markings to authenticate and prevent counterfeiting of documents of value like banknotes, credit cards or ID cards, national ID documents, licenses or any product with monetary value, like stamps, tickets, shares, cheques etc.

Alternatively, the materials according to the invention can be used in OLEDs, e.g. as the active display material in a flat panel display applications, or as backlight of a flat panel display like e.g. a liquid crystal display. Common OLEDs are realized using multilayer structures. An emission layer is generally sandwiched between one or more electron-transport and/or hole-transport layers. By applying an electric voltage electrons and holes as charge carriers move towards the emission layer where their recombination leads to the excitation and hence luminescence of the lumophor units contained in the emission layer. The inventive compounds, materials and films may be employed in one or more of the charge transport layers and/or in the emission layer, corresponding to their electrical and/or optical properties. Furthermore their use within the emission layer is especially advantageous, if the compounds, materials and films according to the invention show electroluminescent properties themselves or comprise electroluminescent groups or compounds. The selection, characterization as well as the processing of suitable monomeric, oligomeric and polymeric compounds or materials for the use in OLEDs is generally known by a person skilled in the art, see, e.g., Müller et al, Synth. Metals, 2000, 111-112, 31-34, Alcala, J. Appl. Phys., 2000, 88, 7124-7128 and the literature cited therein.

According to another use, the materials according to this invention, especially those showing photoluminescent properties, may be employed as materials of light sources, e.g. in display devices, as described in EP 0 889 350 A1 or by C. Weder et al., Science, 1998, 279, 835-837.

A further aspect of the invention relates to both the oxidised and reduced form of the compounds according to this invention. Either loss or gain of electrons results in formation of a highly delocalised ionic form, which is of high conductivity. This can occur on exposure to common dopants.

Suitable dopants and methods of doping are known to those skilled in the art, e.g. from EP 0 528 662, U.S. Pat. No. 5,198,153 or WO 9621659.

The doping process typically implies treatment of the semiconductor material with an oxidating or reducing agent in a redox reaction to form delocalised ionic centres in the material, with the corresponding counterions derived from the applied dopants. Suitable doping methods comprise for example exposure to a doping vapor in the atmospheric pressure or at a reduced pressure, electrochemical doping in a solution containing a dopant, bringing a dopant into contact with the semiconductor material to be thermally diffused, and ion-implantantion of the dopant into the semiconductor material.

When electrons are used as carriers, suitable dopants are for example halogens (e.g., I₂, Cl₂, Br₂, ICl, ICl₃, IBr and IF), Lewis acids (e.g., PF₅, AsF₅, SbF₅, BF₃, BCl₃, SbCl₅, BBr₃ and SO₃), protonic acids, organic acids, or amino acids (e.g., HF, HCl, HNO₃, H₂SO₄, HClO₄, FSO₃H and ClSO₃H), transition metal compounds (e.g., FeCl₃, FeOCl, Fe(ClO₄)₃, Fe(4-CH₃C₆H₄SO₃)₃, TiCl₄, ZrCl₄, HfCl₄, NbF₅, NbCl₅, TaCl₅, MoF₅, MoCl₅, WF₅, WCl₆, UF₆ and LnCl₃ (wherein Ln is a lanthanoid), anions (e.g., Cl⁻, Br⁻, I⁻, I₃⁻, HSO₄⁻, SO₄²⁻, NO₃⁻, ClO₄⁻, BF₄⁻, PF₆⁻, AsF₆⁻, SbF₆⁻, FeCl₄⁻, Fe(CN)₆³⁻, and anions of various sulfonic acids, such as aryl-SO₃⁻). When holes are used as carriers, examples of dopants are cations (e.g., H⁺, Li⁺, Na⁺, K⁺, Rb⁺ and Cs⁺), alkali metals (e.g., Li, Na, K, Rb, and Cs), alkaline-earth metals (e.g., Ca, Sr, and Ba), O₂, XeOF₄, (NO₂⁺) (SbF₆⁻), (NO₂⁺) (SbCl₆⁻), (NO₂⁺) (BF₄⁻), AgClO₄, H₂IrCl₆, La(NO₃)₃.6H₂O, FSO₂OOSO₂F, Eu, acetylcholine, R₄N⁺, (R is an alkyl group), R₄P⁺ (R is an alkyl group), R₆As⁺ (R is an alkyl group), and R₃S⁺ (R is an alkyl group).

The conducting form of the compounds of the present invention can be used as an organic “metal” in applications including, but not limited to, charge injection layers and ITO planarising layers in OLED applications, films for flat panel displays and touch screens, antistatic films, printed conductive substrates, patterns or tracts in electronic applications such as printed circuit boards and condensers.

The compounds and formulations according to the present invention may also be suitable for use in organic plasmon-emitting diodes (OPEDs), as described for example in Koller et al., Nat. Photonics, 2008, 2, 684.

According to another use, the materials according to the present invention can be used alone or together with other materials in or as alignment layers in LCD or OLED devices, as described for example in US 2003/0021913. The use of charge transport compounds according to the present invention can increase the electrical conductivity of the alignment layer. When used in an LCD, this increased electrical conductivity can reduce adverse residual dc effects in the switchable LCD cell and suppress image sticking or, for example in ferroelectric LCDs, reduce the residual charge produced by the switching of the spontaneous polarisation charge of the ferroelectric LCs. When used in an OLED device comprising a light emitting material provided onto the alignment layer, this increased electrical conductivity can enhance the electroluminescence of the light emitting material. The compounds or materials according to the present invention having mesogenic or liquid crystalline properties can form oriented anisotropic films as described above, which are especially useful as alignment layers to induce or enhance alignment in a liquid crystal medium provided onto said anisotropic film. The materials according to the present invention may also be combined with photoisomerisable compounds and/or chromophores for use in or as photoalignment layers, as described in US 2003/0021913 A1.

According to another use the materials according to the present invention, especially their water-soluble derivatives (for example with polar or ionic side groups) or ionically doped forms, can be employed as chemical sensors or materials for detecting and discriminating DNA sequences. Such uses are described for example in L. Chen, D. W. McBranch, H. Wang, R. Helgeson, F. Wudl and D. G. Whitten, Proc. Natl. Acad. Sci. U.S.A., 1999, 96, 12287; D. Wang, X. Gong, P. S. Heeger, F. Rininsland, G. C. Bazan and A. J. Heeger, Proc. Natl. Acad. Sci. U.S.A., 2002, 99, 49; N. DiCesare, M. R. Pinot, K. S. Schanze and J. R. Lakowicz, Langmuir, 2002, 18, 7785; D. T. McQuade, A. E. Pullen, T. M. Swager, Chem. Rev., 2000, 100, 2537.

Unless the context clearly indicates otherwise, as used herein plural forms of the terms herein are to be construed as including the singular form and vice versa.

Throughout the description and claims of this specification, the words “comprise” and “contain” and variations of the words, for example “comprising” and “comprises”, mean “including but not limited to”, and are not intended to (and do not) exclude other components.

It will be appreciated that variations to the foregoing embodiments of the invention can be made while still falling within the scope of the invention. Each feature disclosed in this specification, unless stated otherwise, may be replaced by alternative features serving the same, equivalent or similar purpose. Thus, unless stated otherwise, each feature disclosed is one example only of a generic series of equivalent or similar features.

All of the features disclosed in this specification may be combined in any combination, except combinations where at least some of such features and/or steps are mutually exclusive. In particular, the preferred features of the invention are applicable to all aspects of the invention and may be used in any combination. Likewise, features described in non-essential combinations may be used separately (not in combination).

Above and below, unless stated otherwise percentages are percent by weight and temperatures are given in degrees Celsius. The values of the dielectric constant ∈ (“permittivity”) refer to values taken at 20° C. and 1,000 Hz.

The invention will now be described in more detail by reference to the following examples, which are illustrative only and do not limit the scope of the invention.

### Example 1

### The monomer 2,8-Dibromo-3,9-bis(1-heptyldecyl)IDTT-6,12-dione (11) was Prepared as Described Below

### 2-Heptylundecanoyl chloride (2)

To a solution of 2-heptylundecanoic acid (50.0 cm³; 146.94 mmol) and DMF (0.5 cm³) in dry dichloromethane (100 cm³) were added oxalyl dichloride (30 cm³; 354.54 mmol) dropwise over 1 hour. The yellow solution (slightly milky) was stirred at 22° C. for 20 h. The solvent was removed by vacuum evaporation and yellow oil residue was distilled in vacuo (0.27 mBar) at 126-130° C. to yield a pale yellow liquid (43.0 g, 97%). The product was used directly for the subsequent reaction.

### 3,4-Dibromothienyl-2-heptylundecan-1-one (3)

To a suspension of 3,4-dibromothiophene (12.84 cm³; 115.00 mmol) and AlCl₃ (33.7 g; 253.00 mmol) in dry DCM (250 cm³) at −5° C. was added through a syringe 2-heptylundecanoyl chloride (35.0 g; 115.5 mmol) dropwise. The resultant deep orange suspension was stirred with cooling for 1 hour then hydrolysed by pouring into crunched ice (ca 500 g). The mixture was vigorously stirred for 30 min. The milky white DCM layer was separated and the aqueous layer was extracted once with diethyl ether (100 cm³). The combined organic milky solution was dried over K₂CO₃ and MgSO₄ then vacuum evaporated to dryness. The residual yellow oil was flash chromatographed on silica (4:1 light petrol-dcm) to yield a pale yellow liquid (43.29 g, 74%). GCMS: 507 [M⁺] 100%. ¹H-NMR (CDCl₃, 300 MHz): δ=0.87 (m, 6H), 1.23 (m, 24H), 1.50 (m, 2H), 1.76 (m, 2H), 3.46 (m, 1H), 7.60 (s, 1H).

### Ethyl 6-bromo-3-(1-heptyldecyl)thieno[3,2-b]thiophene-2-carboxylate (4)

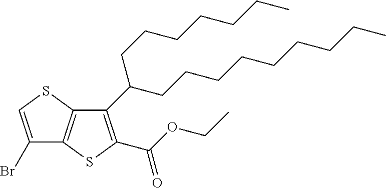 [SMILES: CCCCCCCCCC(CCCCCCC)c1c(C(=O)OCC)sc2c(Br)csc12]

To a mixture of compound 3 (38.20 g; 75.14 mmol) and K₂CO₃ (31.154 g;

225.42 mmol) in DMF (200.0 cm³) was added ethyl mercaptoacetate (9.25 cm³; 82.65 mmol) and of 18-crown-6 (0.500 g). The suspension was stirred at 100° C. (external) for 23 hours to yield an orange solution with white solids. The mixture was cooled to 22° C. and the inorganic precipitate was removed by suction filtration and washed with diethyl ether. The filtrate was vacuum evaporated to dryness and the residual dark yellow oil was dissolved in petroleum ether (40-60) then filtered through a silica plug washed with 2:1 petroleum ether-dcm to yield a clear yellow liquid (32.68 g, 82%). GCMS: 530 [M⁺] 100%. ¹H-NMR (CDCl₃, 300 MHz): g=0.85 (m, 6H), 1.18 (m, 24H), 1.40 (t, J=7.2 Hz, 3H), 1.74 (m, 4H), 4.11 (m, 1H), 4.36 (q, J=7.2 Hz, 2H), 7.41 (s, 1H).

### 6-Bromo-3-(1-heptyldecyl)thieno[3,2-b]thiophene-2-carboxylic acid (5)

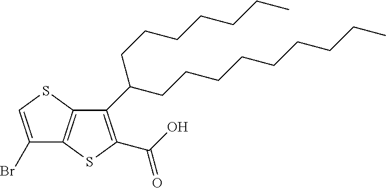 [SMILES: CCCCCCCCCC(CCCCCCC)c1c(C(=O)O)sc2c(Br)csc12]

To a solution of compound 4 (37.00 g; 69.86 mmol) in ethanol (200 cm³) was added a solution of sodium hydroxide (8.382 g; 209.58 mmol) in water (20 cm³). The reaction mixture was stirred at reflux for 20 hours to yield an orange clear solution. The solvent was removed by vacuum evaporation. Water 200 cm³ was added follow by the addition of con hydrochloric acid dropwise under stirring till the aqueous phase was acidic. The mixture was stirred at r.t. for 30 min and the oil precipitate was taken into dcm (2×100 cm³). The dcm solution was flash columned on silica washed with 3:1 petroleum ether-dcm, pure dcm and then with 3:1 dcm-dithyl ether. The product was obtained from the last fraction as a yellow oil (32.09 g, 92%).

¹H-NMR (CDCl₃, 300 MHz): δ=0.85 (m, 6H), 1.20 (m, 24H), 1.76 (m, 4H), 4.14 (m, 1H), 5.30 (s, 1H), 7.47 (s, 1H). ¹³C-NMR (CDCl₃, 75.48 MHz): δ=14.07, 14.10, 22.60, 22.65, 27.68, 29.09, 29.26, 29.41, 29.54, 29.59, 29.63, 31.81, 31.87, 34.91, 38.85, 53.40, 103.14, 128.44, 128.68, 137.04, 143.89, 150.07, 168.70.

### 3-Bromo-6-(1-heptyldecyl)-thieno[3,2-b]thiophene (6)

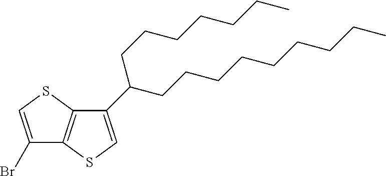 [SMILES: CCCCCCCCCC(CCCCCCC)c1csc2c(Br)csc12]

The suspension of compound 5 (32.09 g; 63.98 mmol), copper Powder (2.44 g; 38.39 mmol) in quinoline (50 cm³; 421.96 mmol) was heated to 230° C. (external) for 1.5 hour with stirring under nitrogen atmosphere till the CO₂ evolution ceased. The reaction mixture was then cooled to r.t. naturally and petroleum ether (40-60) (200 cm³) was added. The mixture was suction filtered through a Celite pad, and washed well with petroleum ether. The filtrate was cooled with an ice-bath follow by the addition of 10% HCl under stirring till the aqueous phase was acidic (pH ca 1) and the mixture was stirred vigorously for 30 min. The mixture was extracted with petroleum ether (40-60) (2×100 cm³) and the solution was dried over MgSO₄ then concentrated under vacuum to dryness to yield a pale-brown oil. The oil was dissolved in petroleum ether and flash columned on silica (washed with petroleum ether) to yield a pale-yellow liquid (26.13 g, 89%). GCMS: 458 [M⁺]. ¹H-NMR (CDCl₃, 300 MHz): δ=0.86 (m, 6H), 1.20 (m, 24H), 1.67 (m, 4H), 2.72 (m, 1H), 7.00 (d, J=1.5 Hz, 1H), 7.23 (d, J=1.51 Hz, 1H).

### 3-(1 Heptyldecyl)thieno[3,2-b]thiophene (7)

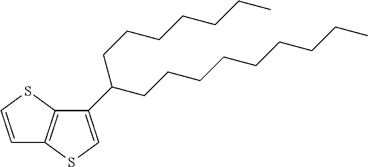 [SMILES: CCCCCCCCCC(CCCCCCC)c1csc2ccsc12]

The solution of 3-bromo-6-(1-heptyldecyl)thieno[3,2-b]thiophene (13.727 g; 30.00 mmol) in anhydrous diethyl ether (100 cm³) was cooled to −78° C. followed by the addition of n-BuLi (16.0 cm³; 40.00 mmol) dropwise over 20 min to yield a clear yellow solution. The solution was stirred with cooling for 40 min and water (10 cm³) was added. The cooling bath was removed and the mixture was stirred at rt for 10 min. Ammonium chloride solution (saturated, 50 cm³) was added and the mixture was stirred for 30 min. The ether layer was separated and the aqueous layer was extracted once with diethyl ether (30 cm³). The combined ether solution was evaporated to dryness and the residual yellow oil was dissolved in PE (40-60) then filtered through a silica plug (10 cm) washed with PE to yield a yellow oil (11.24 g, 99%). GCMS: 378 [M⁺]. ¹H-NMR (CDCl₃, 300 MHz): δ=0.85 (m, 6H), 1.21 (m, 24H), 1.69 (m, 4H), 2.75 (m, 1H), 6.95 (d, J=1.4 Hz, 1H), 7.24 (d, J=5.2 Hz, 1H), 7.34 (dd, J1=5.2 Hz, J2=1.5 Hz, 1H).

### Diethyl 2,5-bis-[6-(1-heptyldecyl)thieno[3,2-b]thiophen-2-yl]terephthalate (8)

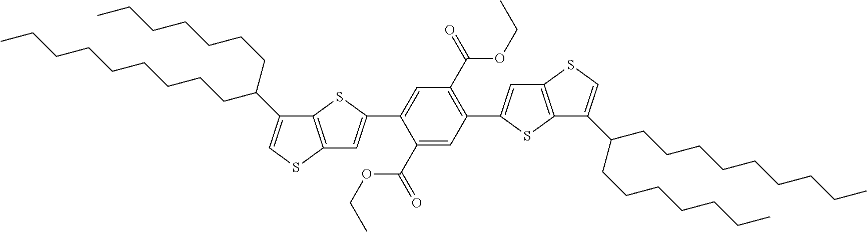 [SMILES: CCCCCCCCCC(CCCCCCC)c1csc2cc(-c3cc(C(=O)OCC)c(-c4cc5scc(C(CCCCCCC)CCCCCCCCC)c5s4)cc3C(=O)OCC)sc12]

The solution of 3-(1-heptyldecyl)thieno[3,2-b]thiophene (11.06 g; 29.21 mmol) in anhydrous THF (100 cm³) was cooled to −78° C. and n-BuLi (11.7 cm³; 29.21 mmol) was added over 10 min. The mixture was stirred at the low temperature for 3 hours to yield a yellow suspension. Tributyltin chloride (8.3 cm³; 29.21 mmol) was syringed into the solution in one portion. The clear yellow solution was stirred with the cooling bath for 15 h and the temperature was allowed to rise to room temperature naturally. The solid of diethyl 2,5-dibromoterephthalate (4.750 g; 12.50 mmol), Pd₂(PPh₃)₂Cl₂ (264 mg; 0.38 mmol) and dry DMF (25 cm³) were added sequentially and the mixture was heated to reflux. A distillation head was fitted on the flask and ca 100 cm³ of the solvents was removed by distillation. The residual orange solution was stirred at reflux for 22 hours to yield a pale-brown solution. The solution was evaporated under vacuum to dryness. The residual pale-brown liquid was flash columned on silica eluted with 3:1 PE/dcm then with 2:1 PE/dcm to yield the product as yellow oil (8.82 g, 72%). The oil turned into yellow crystals upon standing in the fume cupboard over a weekend. ¹H-NMR (CDCl₃, 300 MHz): δ=0.86 (m, 6H), 1.07 (t, J=7.1 Hz, 3H), 1.22 (m, 24H), 1.70 (m, 4H), 2.76 (m, 1H), 4.22 (q, J=7.2 Hz, 2H), 6.97 (s, 1H), 7.27 (s, 1H), 7.89 (s, 1H).

### 2,5-Bis-[6-(1-heptyldecyl)thieno[3,2-b]thiophen-2-yl]terephthalic acid (9)

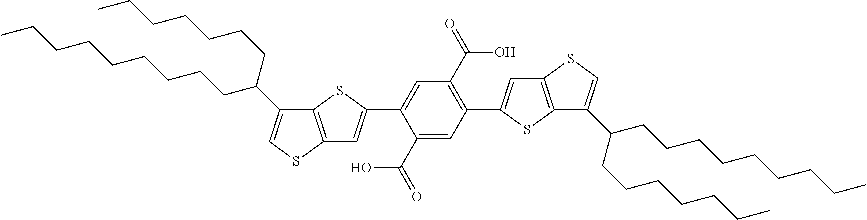 [SMILES: CCCCCCCCCC(CCCCCCC)c1csc2cc(-c3cc(C(=O)O)c(-c4cc5scc(C(CCCCCCC)CCCCCCCCC)c5s4)cc3C(=O)O)sc12]

The diethyl ester 8 (9.040 g; 9.27 mmol) was mixed with methanol (150 cm³) and THF (50 cm³) followed by the addition of a solution of NaOH (3.0 g; 75.00 mmol) in water (5 cm³). The suspension was stirred at reflux for 15 h to yield a clear yellow solution. The solvents were removed by vacuum evaporation. DCM (50 cm³) and water (50 cm³) were added followed by the addition of conc HCl under stirring till the aqueous phase was acidic. The DCM phase was separated and the aqueous phase was extracted with dcm (2×25 cm³). The combined yellow DCM solution was dried over MgSO₄ then filtered through a silica plug (10 cm) washed with DCM containing 5% diethyl ether. The bright yellow filtrate was evaporated to dryness to yield the product as a yellow solid (8.61 g, 100%). The product was directly used for the subsequent reaction without further purification. ¹H-NMR (acetone-d₆, 300 MHz): δ=0.86 (m, 6H), 1.26 (m, 24H), 1.77 (m, 4H), 2.90 (m, 1H), 5.64 (s, 1H), 7.29 (s, 1H), 7.60 (s, 1H), 7.98 (s, 1H).

### 3,9-Bis(1-heptyldecyl)IDTT-6,12-dione (10)

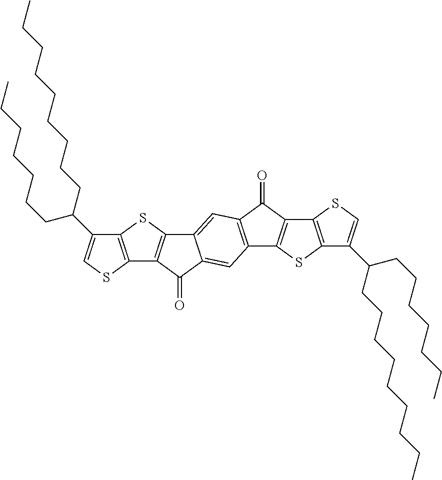 [SMILES: CCCCCCCCCC(CCCCCCC)c1csc2c1sc1c3cc4c(=O)c5c6scc(C(CCCCCCC)CCCCCCCCC)c6sc5c4cc3c(=O)c21]

To a clear yellow solution of the terephthalic acid 9 (8.60 g; 9.35 mmol) in anhydrous DCM (100 cm³) were added oxalyl chloride (10 cm³; 118.18 mmol) and 2 drops of DMF. The red orange mixture was stirred at rt for 20 hours to yield a pale-red solution. The solvent was removed by vacuum evaporation to yield a red oil. The oil was dissolved in dry dcm (50 cm³) and the solution was cannulated into the stirred suspension of AlCl₃ (6.74 g; 50.51 mmol) in dry DCM (50 cm³), cooled with an ice-acetone bath. The brown mixture was stirred with cooling for 2 hours then hydrolysed with crunched ice and water. The DCM was removed with a vacuum evaporator leaving the aqueous phase and the crude product. Methanol (100 cm³) was added and the mixture was triturated well prior to a suction filtration. The brown-blue sticky solid on the filter was washed with water and methanol then air-dried. The solid of the crude product was purified by flash chromatography on silica eluted with 4:1 PE-dcm to yield the pure product as a blue solid (3.67 g, 42.5%). ¹H-NMR (CDCl₃, 300 MHz): δ=0.85 (m, 6H), 1.22 (m, 24H), 1.70 (m, 4H), 2.76 (m, 1H), 6.98 (s, 1H), 7.20 (s, 1H).

### 2,8-Dibromo-3,9-bis(1-heptyldecyl)IDTT-6,12-dione (11)

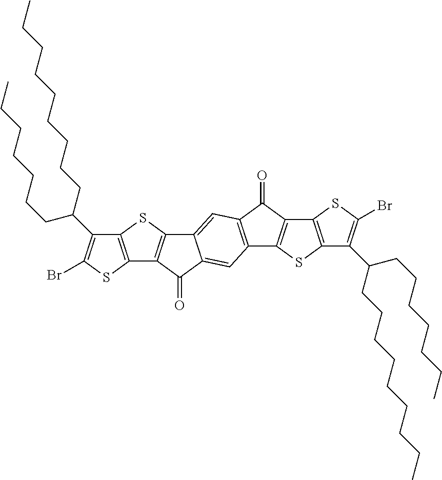 [SMILES: CCCCCCCCCC(CCCCCCC)c1c(Br)sc2c1sc1c3cc4c(=O)c5c6sc(Br)c(C(CCCCCCC)CCCCCCCCC)c6sc5c4cc3c(=O)c21]

To a solution of IDTT-dione 10 (3.670 g; 3.98 mmol) in chloroform (100 cm³) was added acetic acid (25 cm³) and NBS (1.572 g; 8.75 mmol) in one portion. The solution was stirred at 22° C. for 17 hours. The solution was concentrated by rotary evaporation till a solid started crashing out. Methanol (50 cm³) was added and the grey-blue solid was suction filtered off and washed with methanol. The crude product was further purified by flash column chromatography on silica using 4:1 PE (40-60)-dcm as the eluent to yield the pure product as a pale grey-green solid (4.01 g, 97%). ¹H-NMR (CDCl₃, 300 MHz): δ=0.85 (m, 6H), 1.22 (m, 24H), 1.74 (m, 4H), 3.05 (m, 1H), 7.15 (s, 1H).

### Example 2

### Poly[3,9-bis(1-heptyldecyl)IDTT-6,12-dione-alt-2,5-thieno[3,2-b]thiophenylene] was Prepared as Described Below

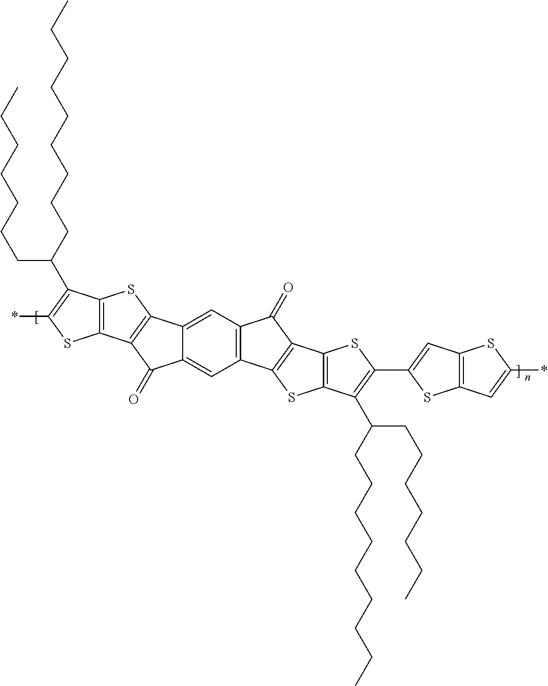

The mixture of 2,8-dibromo-3,9-bis(1-heptyldecyl)IDTT-6,12-dione (11) (520.610 mg; 0.50 mmol), 2,5-bis(trimethylstannyl)thieno[3,2-b]thiophene (232.920 mg; 0.50 mmol), Pd(PPh₃)₂Cl₂ (11.500 mg; 0.02 mmol) and anhydrous toluene (10 cm³) was degassed by bubbling nitrogen for 1 hour in a Schlenk tube. The tube was sealed then stirred at 100° C. for 17 hours to yield a yellow-brown slurry. The tube was lifted from the oil-bath and cooled naturally for 5 min followed by the addition of 2-iodothiophene (0.25 ml). The mixture was stirred at 100° C. for 1 hour followed by the addition of toluene (5 cm³). The mixture was stirred at 100° C. for an additional 1 hour. The yellow-brown viscous solution was precipitated into stirred methanol (300 cm³). The solid precipitate was collected by suction filtration and washed with methanol then subjected to Soxhelet extraction with acetone, cyclohexane and toluene. The residue was finally dissolved off with chlorobenzene and precipitated from methanol again to yield a brown polymer solid after suction filtration and drying (0.41, 80%). Molecular weights by GPC (chlorobenzene, 50° C.); Mn=24,400, Mw=75,800, Pd=3.11.

### Example 3

### Poly[3,9-bis(1-heptyldecyl)IDTT-6,12-dione-alt-2,2′-dithiophen-5,5′-ylene] was Prepared as Described Below

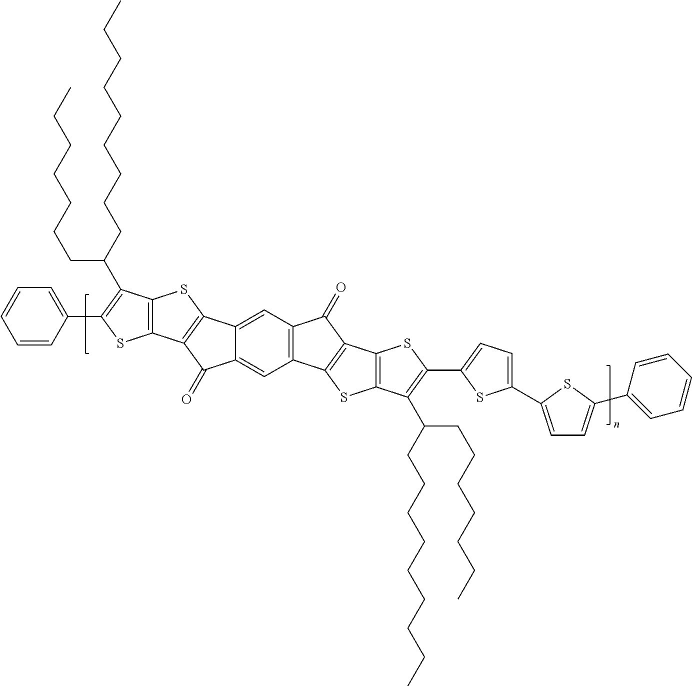

In analogy to the synthesis of Example 2, a mixture of 2,8-dibromo-3,9-bis(1-heptyldecyl)IDTT-6,12-dione (11) (520.610 mg; 0.50 mmol), 5,5′-bis(trimethylstannanyl)[2,2]bithiophene (245.938 mg; 0.50 mmol), Pd(PPh₃)₂Cl₂ (11.500 mg; 0.02 mmol) in toluene (9.0 cm³) and DMF (1.0 cm³) was degassed for 1 h then stirred at 110° C. for 2 h to yield a viscous brown-green solution. Bromobenzene (0.1 cm³; 0.95 mmol) was added at this stage and the mixture was stirred at 110° C. for an additional 1 hour prior to the addition of tributylphenylstannane (0.4 cm³; 1.23 mmol). The brown green mixture was stirred for another hour then cooled to rt and precipitated into stirred methanol (250 cm³). The brownish polymer solid was collected by suction filtration and washed with methanol then with acetone. The polymer was purified by Soxhlet extraction with acetone, petroleum ether (40-60), cyclohexane and chloroform sequentially. The chloroform solution was concentrated and precipitated into methanol. Suction filtration and drying under vacuum yielded the polymer as a brown solid (0.34 g, 64%). The molecular weights were determined by GPC (chlorobenzene, 50° C.): Mn=30,000 g/mol, Mw=72,500 g/mol, Pd=2.42.

### Example 4

### Poly[3,9-bis(1-heptyldecyl)IDTT-6,12-dione-alt-4,8-didodecylbenzo[1,2-b; 4,5-b′]dithiophen-2,6-ylene] was Prepared as Described Below

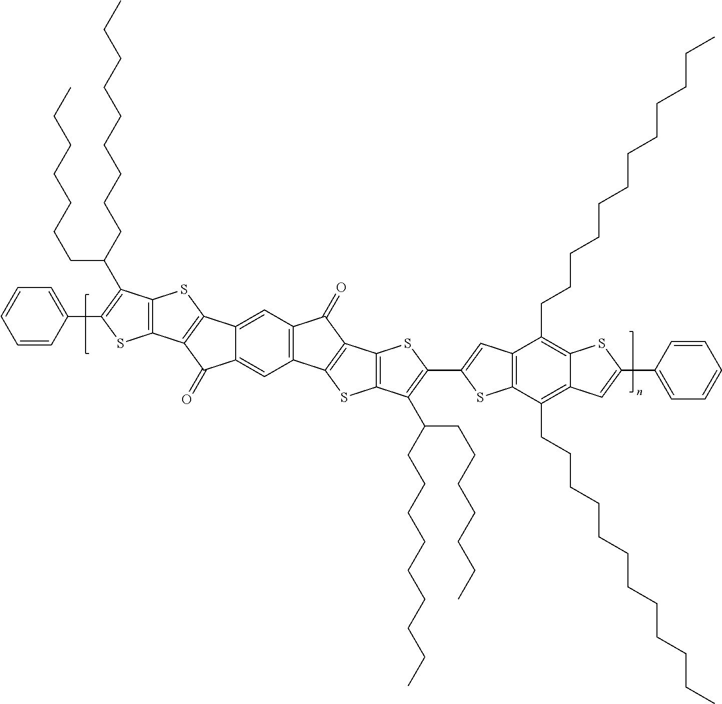

In analogy to the synthesis of Example 2, a mixture of 2,8-dibromo-3,9-bis(1-heptyldecyl)IDTT-6,12-dione (11) (520.610 mg; 0.50 mmol), 4,8-didodecyl-2,6-bis(trimethylstannanyl)benzo[1,2-b; 4,5-b′]dithiophene (426.268 mg; 0.50 mmol), Pd(PPh₃)₂Cl₂ (11.500 mg; 0.02 mmol) in anhydrous toluene (9.0 cm³) and DMF (1.0 cm³) was degassed by bubbling nitrogen for 1 h then stirred at 110° C. for 16 h.

Tributylphenylstannane (0.200 cm³; 0.61 mmol) was added and the mixture was stirred at 110° C. for an additional 1 h prior to the addition of bromobenzene (0.1 cm³; 0.95 mmol). The dark-green mixture was stirred for another hour. The brown-green solution was cooled to rt then precipitated into stirred methanol (300 cm³). The brownish polymer solid fibre was collected by suction filtration and washed with methanol and acetone. The polymer solid was further purified by Soxhlet extraction with acetone, petroleum ether (40-60) and chloroform. The acetone and PE solutions were discarded and the dark green chloroform solution was concentrated then precipitated into methanol. The greenish brown polymer solid was collected by suction filtration, washed with methanol and dried under vacuum (0.22 g, 32%). The molecular weights were determined by GPC (chlorobenzene, 50° C.): Mn=27,000 g/mol, Mw=94,700 g/mol, Pd=3.51.

### Example 5

### Transistor Fabrication and Measurements: a General Procedure

Top-gate thin-film organic field-effect transistors (OFETs) were fabricated on XG glass substrates with thermally evaporated Au source-drain electrodes. The glass substrate was treated with Decon 90 for 30 minutes, rinsed with de-ionised water four times, supersonicated in de-ionised water and methanol sequentially for 1 minute each and finally spin-dried in air. The Au electrodes were deposited under 5×10⁻⁶ mBar vacuum at a rate of 0.1-0.2 nm s. A polymer solution in o-dichlorobenenzene at the concentration of 7 mg/cm³ was spin-coated on top followed by a spin-coated fluoropolymer dielectric material (D139). Finally the Au gate electrode was deposited by thermal evaporation. The electrical characterization of the transistor devices was carried out in ambient air atmosphere using a computer controlled Agilent 4155C Semiconductor Parameter Analyser. Charge carrier mobilities for polymers 2-4 in the saturation regime (μₛₐₜ) were calculated and are shown in Table 1. Field-effect mobilities were calculated in the saturation regime (V_{d}>(V_{g}−V₀)) using equation (1):

$${( \frac{d {I}_{d}^{sat}}{d {V}_{g}} )}_{{V}_{d}} = \frac{{WC}_{i}}{L} {μ}^{sat} ( {V}_{g} - {V}_{0} ) \qquad ( 1 )$$

where W is the channel width, L the channel length, Cᵢ the capacitance of insulating layer, V_{g} the gate voltage, V₀ the turn-on voltage, and μₛₐₜ is the charge carrier mobility in the saturation regime. Turn-on voltage (V₀) was determined as the onset of source-drain current.

TABLE 1
Transistor characteristics

| Polymer Example | Saturated mobility (μₛₐₜ) |
|---|---|
| 2 | 1 × 10⁻³ cm²/Vs |
| 3 | 5 × 10⁻³ cm²/Vs |
| 4 | 5 × 10⁻³ cm²/Vs |

1. Compound comprising one or more divalent units of formula I 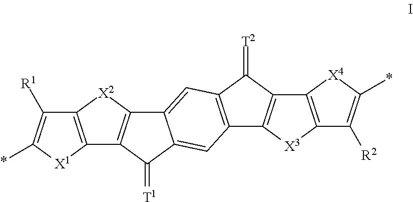
wherein
X¹, X², X³, X⁴ are independently of each other O, S, Se or Te,
T¹ and T² are independently of each other O, C(G¹G²) or N-G¹,
G¹ and G² are independently of each other an electron withdrawing group,
R¹ and R² independently of each other denote H, straight-chain, branched or cyclic alkyl, with 1 to 30 C atoms, in which one or more non-adjacent C atoms are optionally replaced by —O—, —S—, —NR⁰—, —SiR⁰R⁰⁰—, —CY¹═CY²— or —C≡C— in such a manner that 0 and/or S atoms are not linked directly to one another, and in which one or more H atoms are optionally replaced by F, Cl, Br, I or CN, or denote aryl, heteroaryl, aryloxy or heteroaryloxy with 4 to 20 ring atoms which is optionally substituted,
Y¹ and Y² are independently of each other H, F, Cl or CN,
R⁰ and R⁰⁰ are independently of each other H or optionally substituted C₁₋₄₀ carbyl or hydrocarbyl, and preferably denote H or alkyl with 1 to 12 C-atoms.

2. Compound according to claim 1, characterized in that in the units of formula I X¹, X², X³ and X⁴ denote S, O or Se, preferably S.

3. Compound according to claim 1, characterized in that the units of formula I are selected from the following formulae: 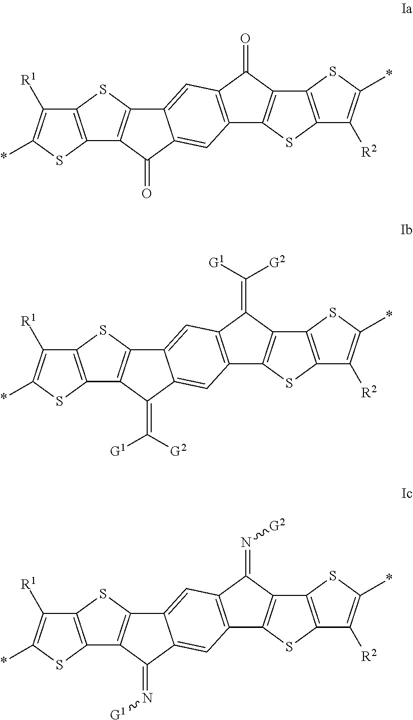
wherein R¹, R², G¹ and G² have the meanings given in claim 1.

4. Compound according to claim 1, characterized in that in the units of formula I the electron withdrawing groups G¹ and G² are selected from —CN, —C(═O)OR^{A}, —C(═O)R^{A}, —C(═O)—N(R^{A}R^{B}), perfluoroalkyl with 1 to 20 C atoms, —SO₃R^{A}, or —NO, wherein R^{A} and R^{B} independently of each other denote H, straight-chain alkyl with 1 to 20 C atoms, branched or cyclic alkyl with 3 to 30 C atoms, in which one or more H atoms are optionally replaced by F, or aryl, heteroaryl, aryloxy or heteroaryloxy with 4 to 20 ring atoms which is optionally substituted.

5. Compound according to claim 1, characterized in that in the units of formula I R¹ and R² denote straight-chain, branched or cyclic alkyl with 1 to 30 C atoms which is unsubstituted or substituted by one or more F atoms.

6. Compound according to claim 1, characterized in that it is a polymer comprising one or more units of formula I as defined in claim 1.

7. Polymer according to claim 6, characterized in that it comprises one or more units of formula II
—[(Ar¹)ₐ—(U)_{b}—(Ar²)_{c}—(Ar³)_{d}]— II
wherein
U is a unit of formula I,
Ar¹, Ar², Ar³ are, on each occurrence identically or differently, and independently of each other, aryl or heteroaryl that is different from U, preferably has 5 to 30 ring atoms and is optionally substituted, preferably by one or more groups R^{S},
R^{S} is on each occurrence identically or differently F, Br, Cl, —CN, —NC, —NCO, —NCS, —OCN, —SCN, —C(O)NR⁰R⁰⁰, —C(O)X⁰, —C(O)R⁰, —NH₂, —NR⁰R⁰⁰, —SH, —SR⁰, —SO₃H, —SO₂R⁰, —OH, —NO₂, —CF₃, —SF_{S}, optionally substituted silyl, carbyl or hydrocarbyl with 1 to 40 C atoms that is optionally substituted and optionally comprises one or more hetero atoms, or P-Sp-,
R⁰ and R⁰⁰ are independently of each other H or optionally substituted C₁₋₄₀ carbyl or hydrocarbyl,
P is a polymerisable or crosslinkable group,
Sp is a spacer group or a single bond,
X⁰ is halogen, preferably F, Cl or Br,
a, b, c are on each occurrence identically or differently 0, 1 or 2,
d is on each occurrence identically or differently 0 or an integer from 1 to 10,
wherein the polymer comprises at least one repeating unit of formula II wherein b is at least 1.

8. Polymer according to claim 6, characterized in that it additionally comprises one or more repeating units selected of formula III
—[(Ar¹)ₐ—(D)_{b}-(Ar²)_{c}—(Ar³)_{d}]— III
wherein Ar¹, Ar², Ar³, a, b, c and d are as defined in claim 7, and D is an aryl or heteroaryl group that is different from U and Ar¹⁻³, has 5 to 30 ring atoms, is optionally substituted by one or more groups R^{S} as defined in claim 7, and is selected from aryl or heteroaryl groups having electron donor properties, wherein the polymer comprises at least one repeating unit of formula III wherein b is at least 1.

9. Polymer according to claim 7, characterized in that it is selected of formula IV: 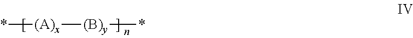
wherein
A is a unit of formula I
B is a unit that is different from A and comprises one or more aryl or heteroaryl groups that are optionally substituted,
x is >0 and ≦1,
y is ≧0 and <1,
x+y is 1, and
n is an integer >1.

10. Polymer according to claim 7, characterized in that it is selected from the following formulae
*-[(Ar¹—U—Ar²)ₓ—(Ar³)]-* IVa
*-[(Ar¹—U—Ar²)ₓ—(Ar³—Ar³)_{y}]ₙ-* IVb
*-[(Ar¹—U—Ar²)ₓ—(Ar³—Ar³—Ar³)_{y}]ₙ-* IVc
*-[(Ar¹)ₐ—(U)_{b}—(Ar²)_{c}—(Ar³)_{d}]ₙ-* IVd
*-([(Ar¹)ₐ—(U)_{b}—(Ar²)_{c}—(Ar³)_{d}]ₓ—[(Ar¹)ₐ-(D)_{b}-(Ar²)_{c}—(Ar³)_{d}]_{y})-* IVe
wherein U, Ar¹, Ar², Ar³, a, b, c and d have in each occurrence identically or differently one of the meanings given in claim 7, D is on each occurrence identically or differently an aryl or heteroaryl group that is different from U and Ar¹⁻³,
x is >0 and ≦1,
y is ≧0 and <1,
x+y is 1, and
n is an integer >1,
wherein these polymers can be alternating or random copolymers, and wherein in formula IVd and We in at least one of the repeating units [(Ar¹)ₐ—(U)_{b}—(Ar²)_{c}—(Ar³)_{d}] and in at least one of the repeating units [(Ar¹)ₐ-(D)_{b}-(Ar²)_{c}-(Ar³)_{d}] b is at least 1.

11. Polymer according to claim 9, characterized in that it is selected of formula V
R⁵-chain-R⁶ V
wherein “chain” is a polymer chain selected of formulae IV or IVa-IVe as defined in claim 9, and R⁵ and R⁶ denote independently of each other H, F, Br, Cl, I, —CH₂Cl, —CHO, —CR′═CR″₂, —SiR′R″R′″, —SiR′X′X″, —SiR′R″X′, —SnR′R″R′″, —BR′R″, —B(OR′)(OR″), —B(OH)₂, —O—SO₂—R′, —C≡CH, —C≡C—SiR′₃, —ZnX′, P-Sp- or an endcap group, wherein P and Sp are as defined, X′ and X″ denote halogen, R′, R″ and R′″ have independently of each other one of the meanings of R⁰, and two of R′, R″ and R′″ may also form a ring together with the hetero atom to which they are attached.

12. Polymer according to claim 8, wherein one or more of D, Ar¹, Ar² and Ar³ denote aryl or heteroaryl selected from the group consisting of the following formulae 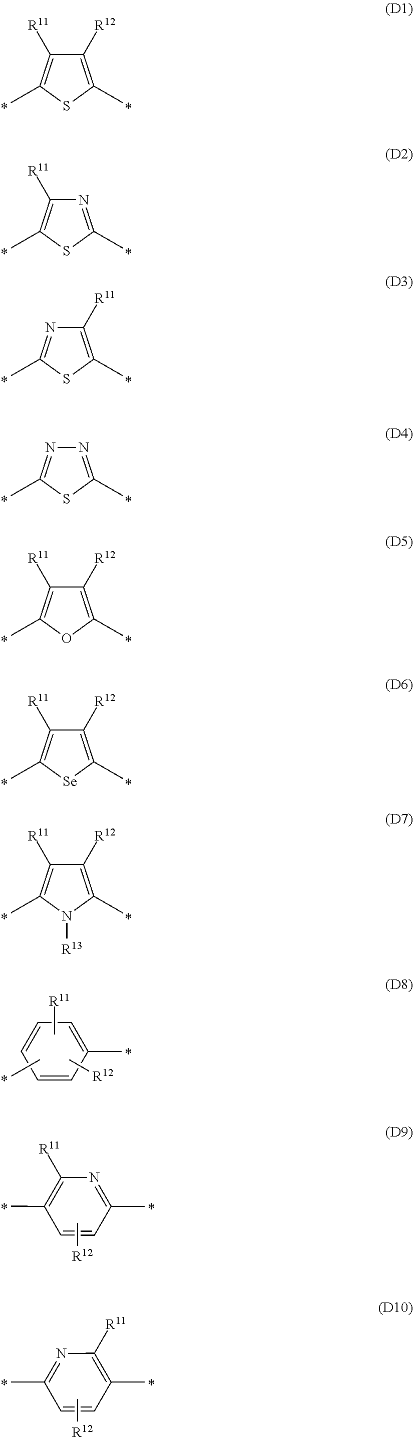 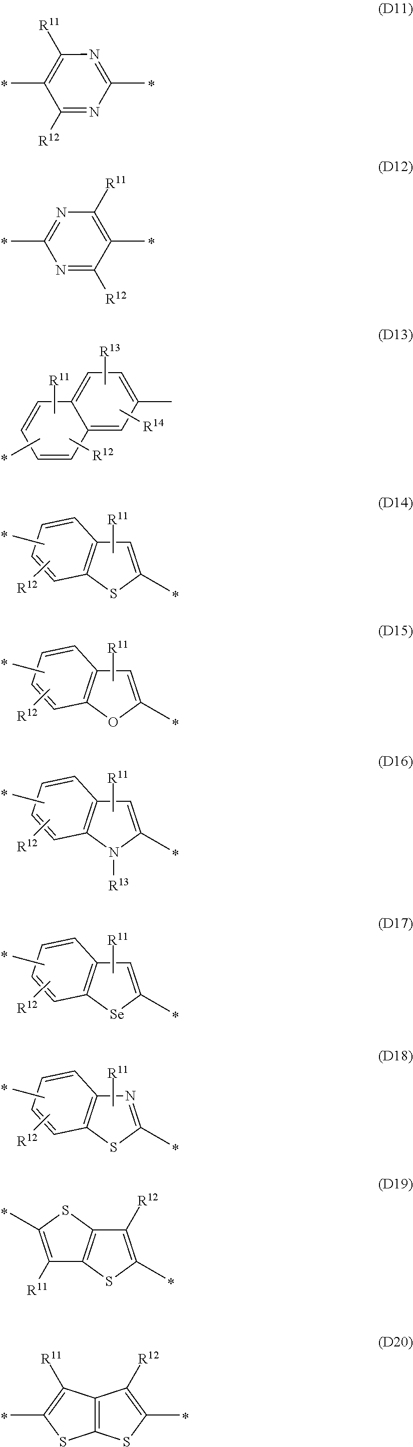 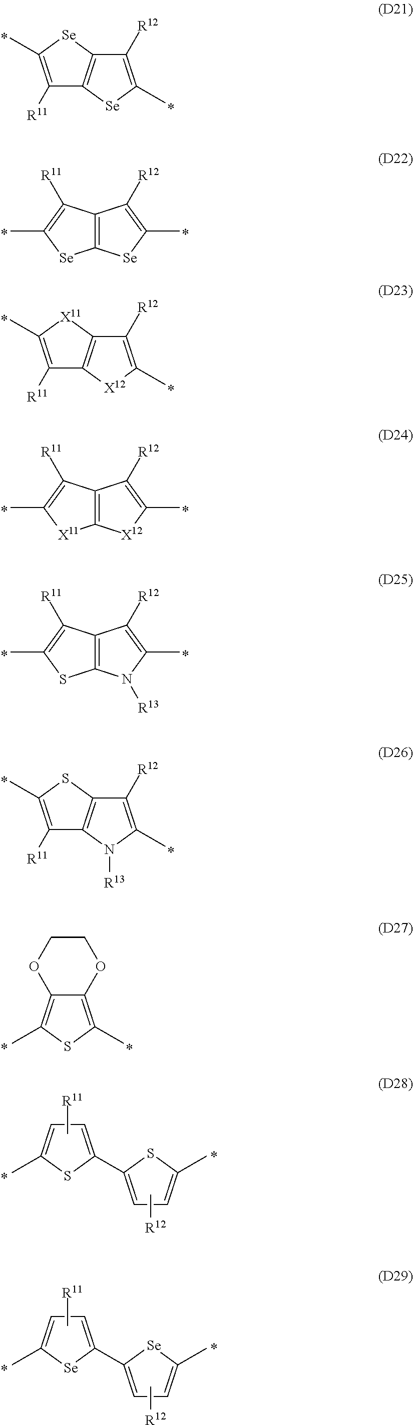 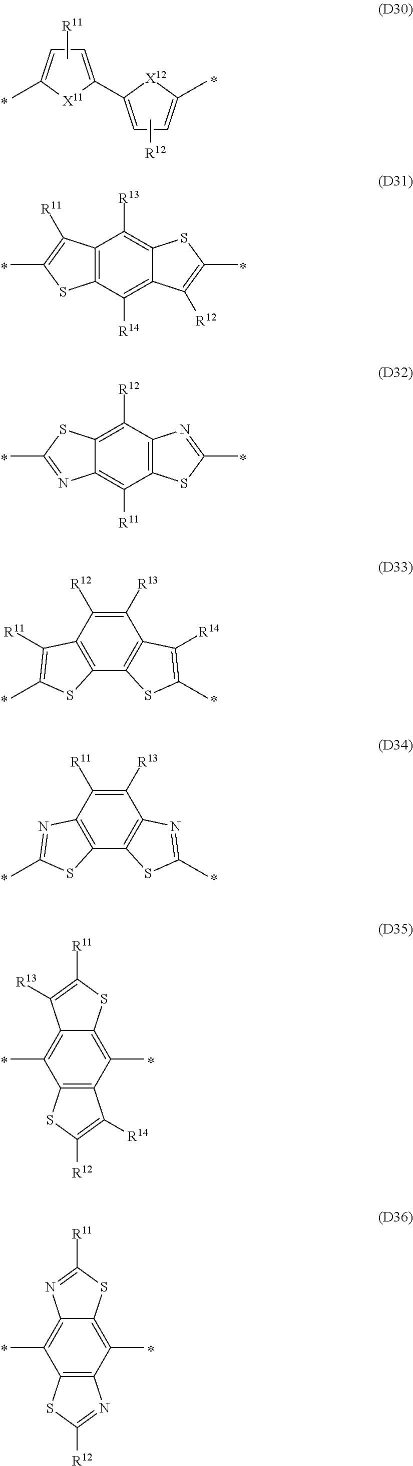 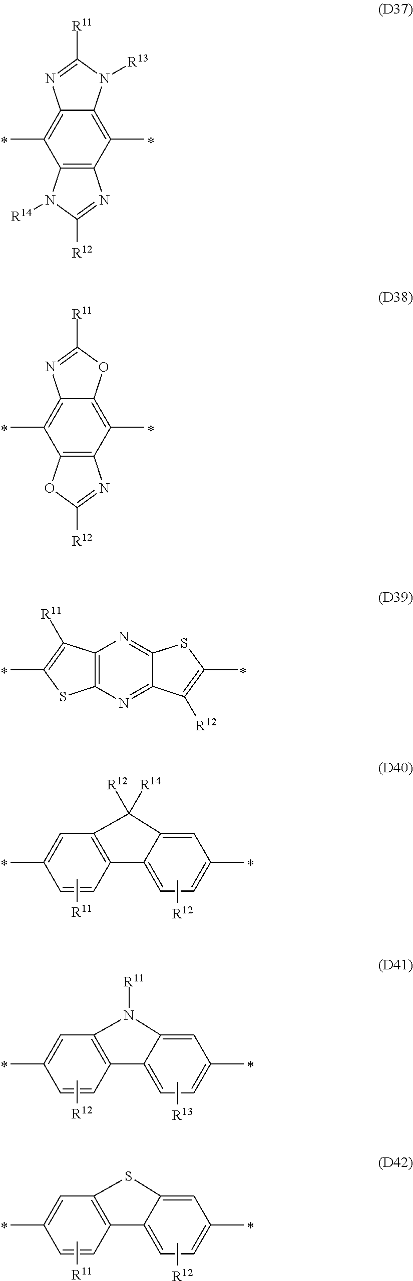 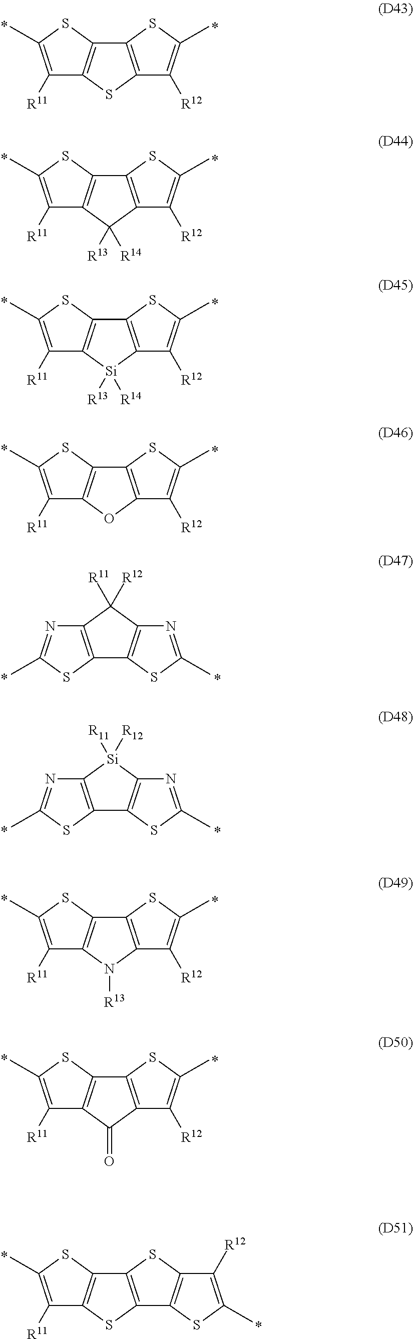 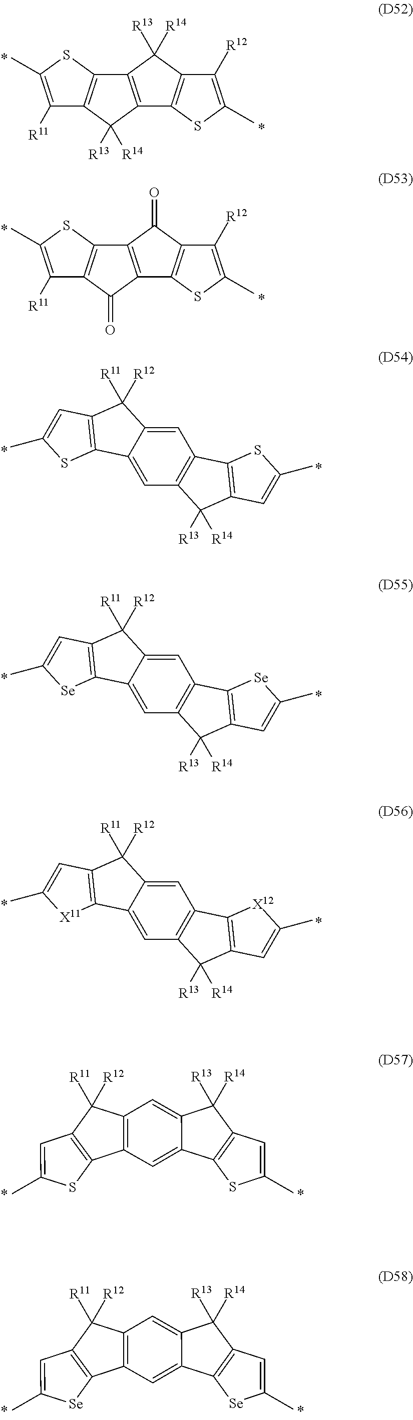 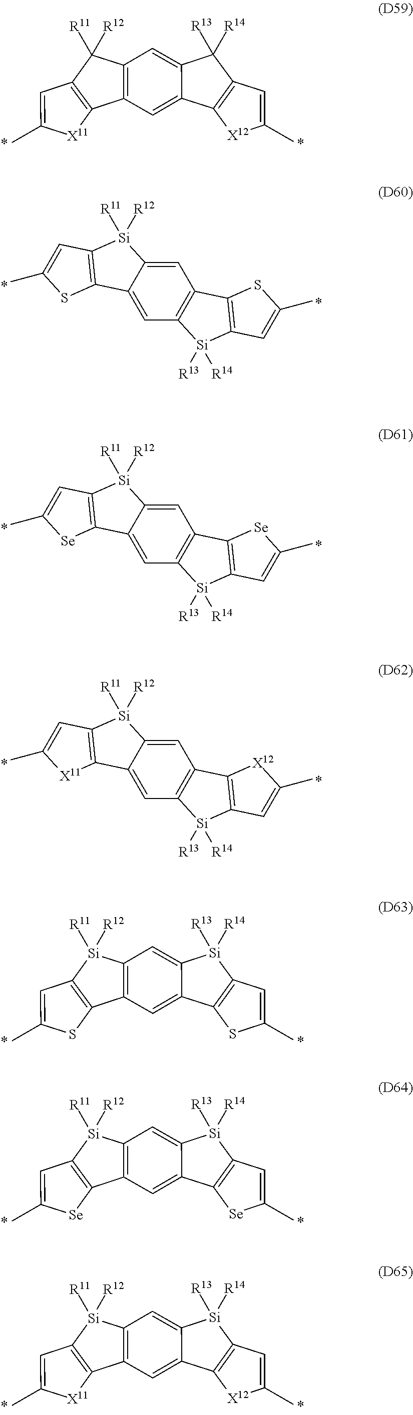 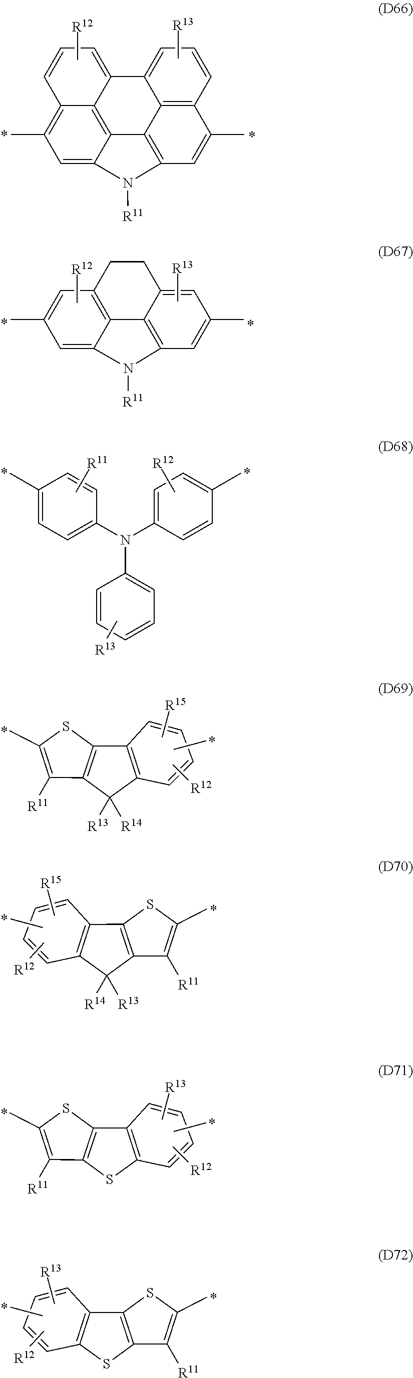 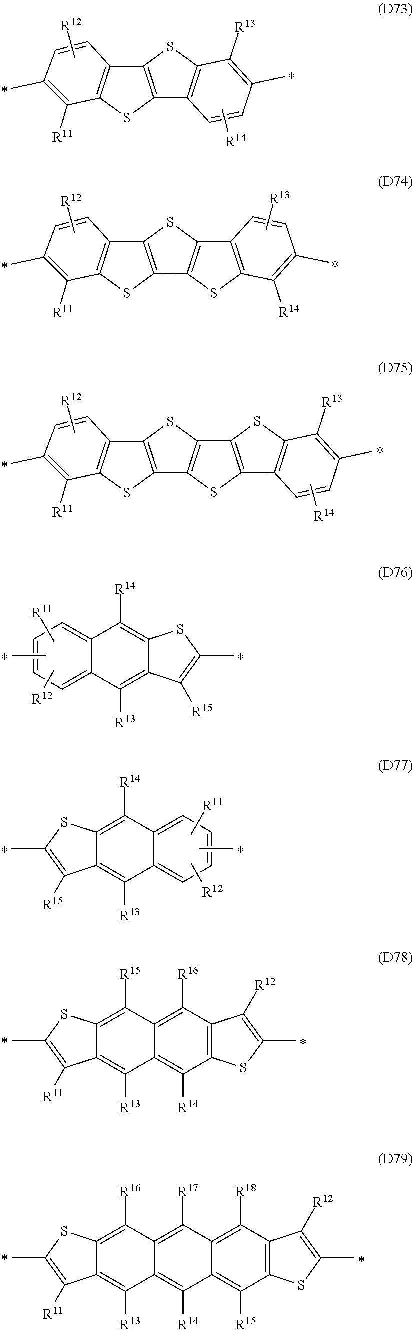 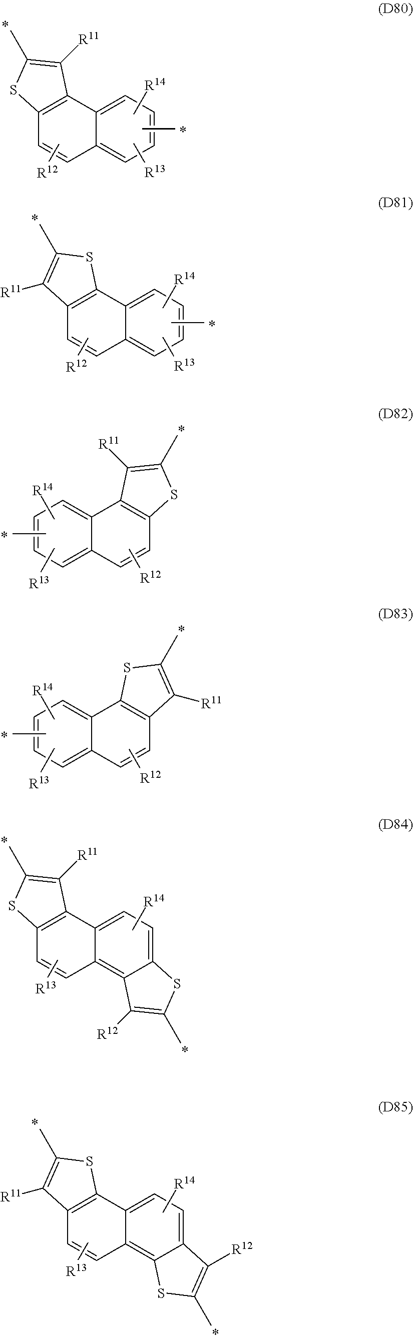 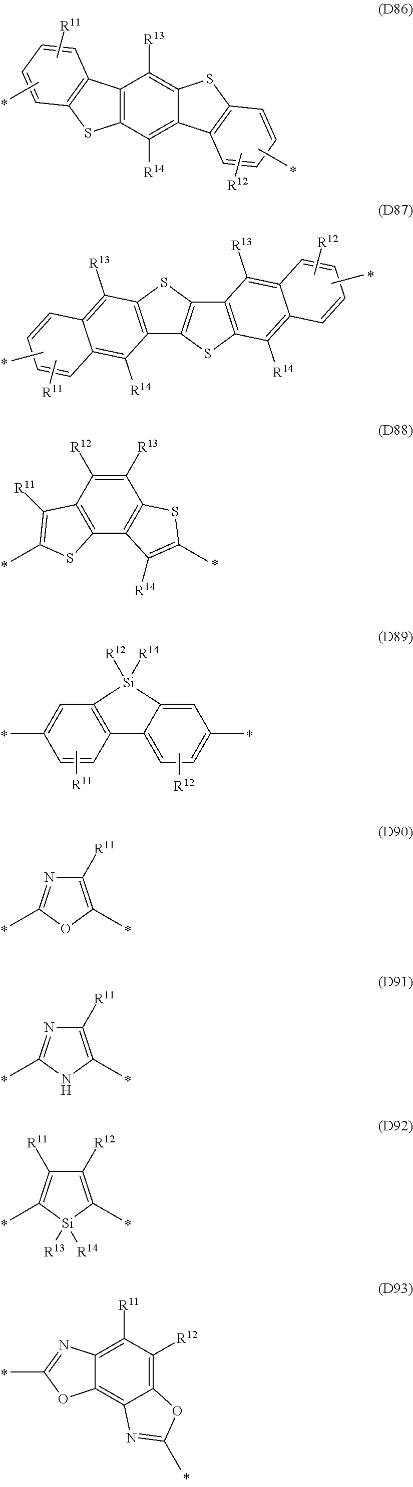 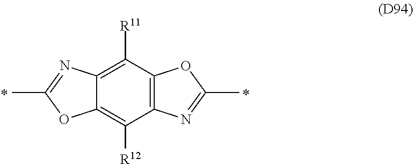
wherein one of X¹¹ and X¹² is S and the other is Se, and R¹¹, R¹², R¹³, R¹⁴, R¹⁵, R¹⁶, R¹⁷ and R¹⁸ independently of each other denote H or have one of the meanings of R¹.

13. Polymer according to claim 7, wherein Ar³ denotes aryl or heteroaryl selected from the group consisting of the following formulae 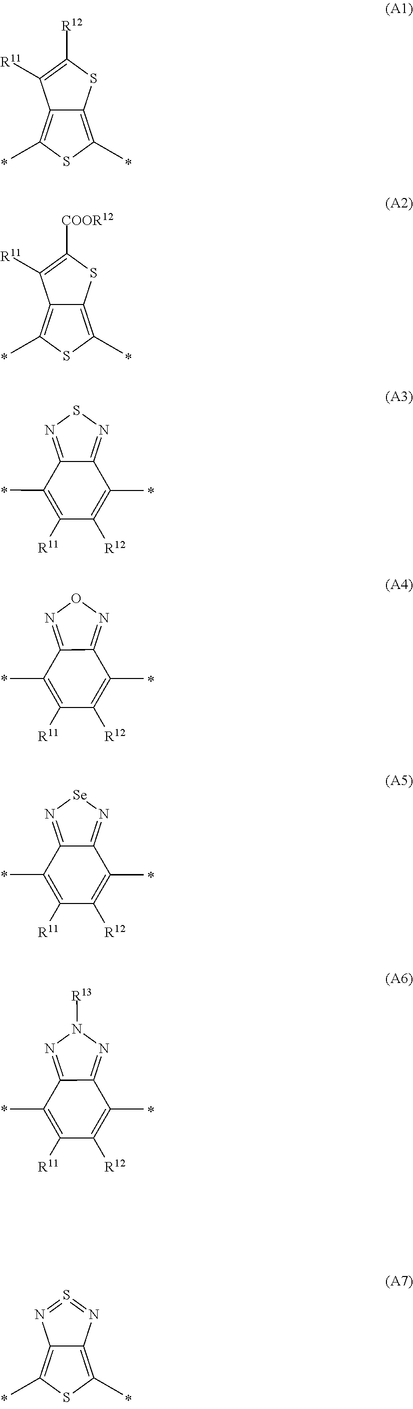 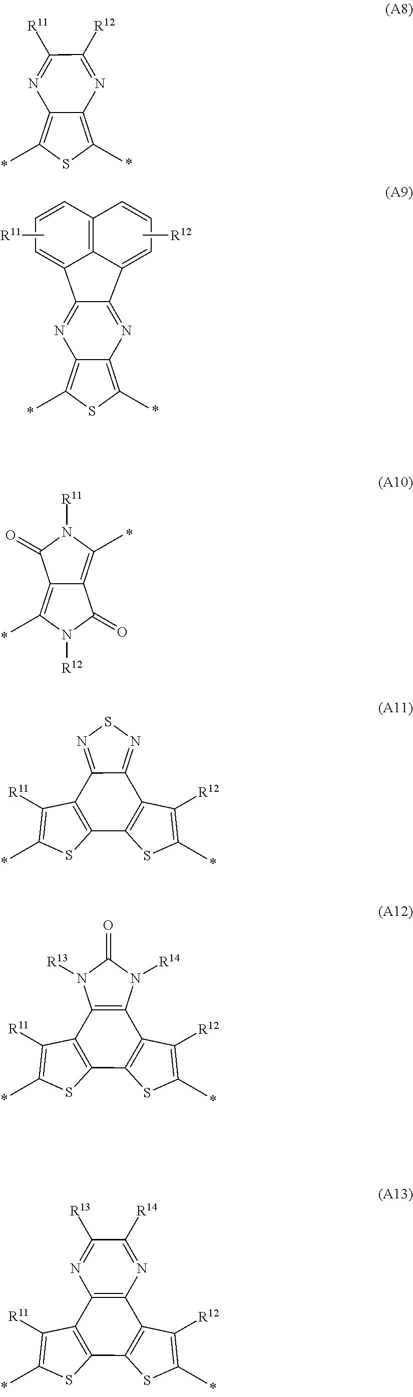 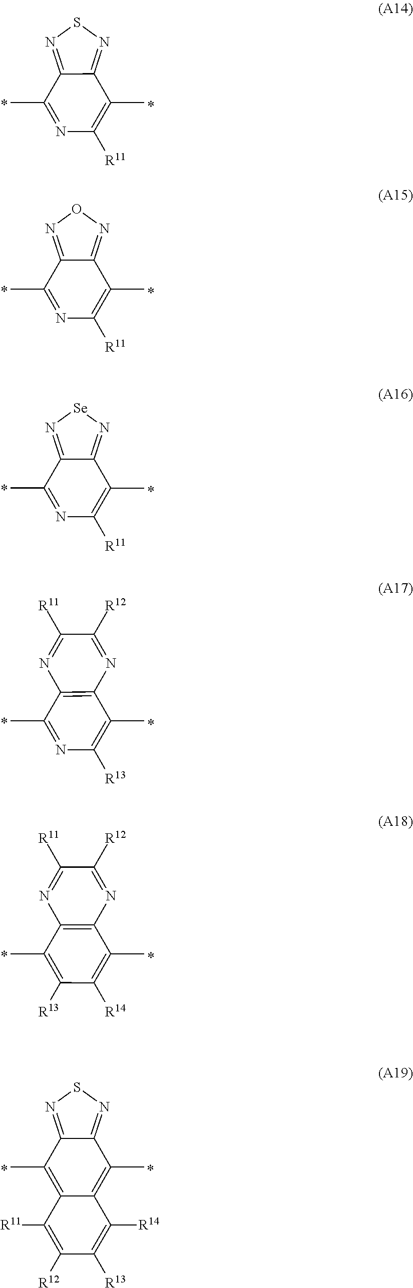 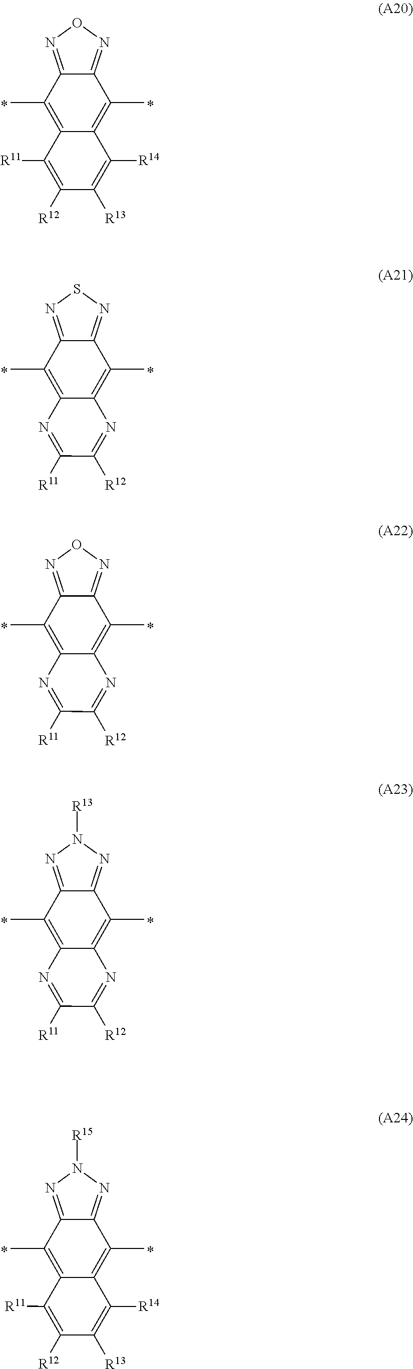 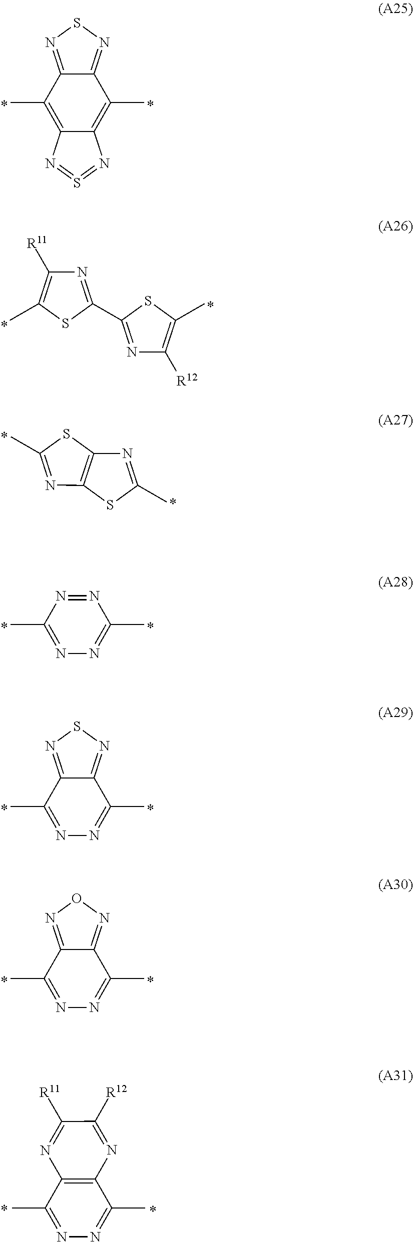 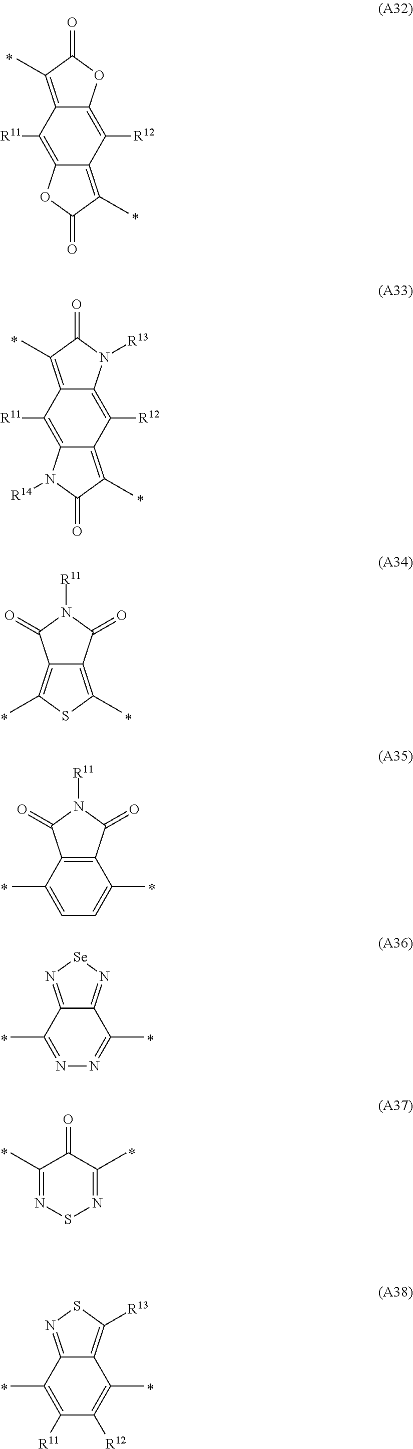 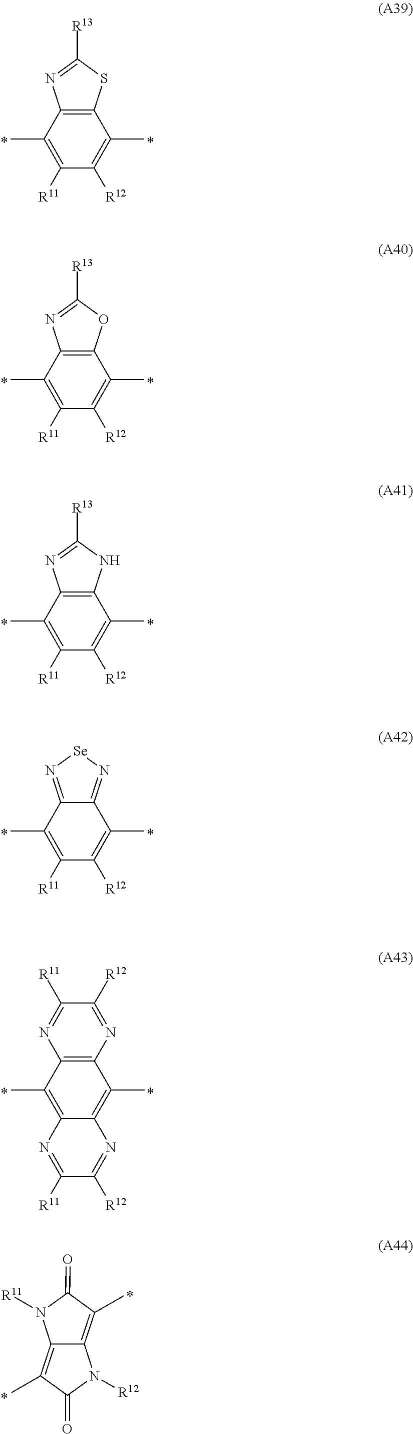
wherein one of X¹¹ and X¹² is S and the other is Se, and R¹¹, R¹², R¹³, R¹⁴ and R¹⁵ independently of each other denote H or have one of the meanings of R¹.

14. Polymer according to claim 6, characterized in that it is selected from the group consisting of the following formulae 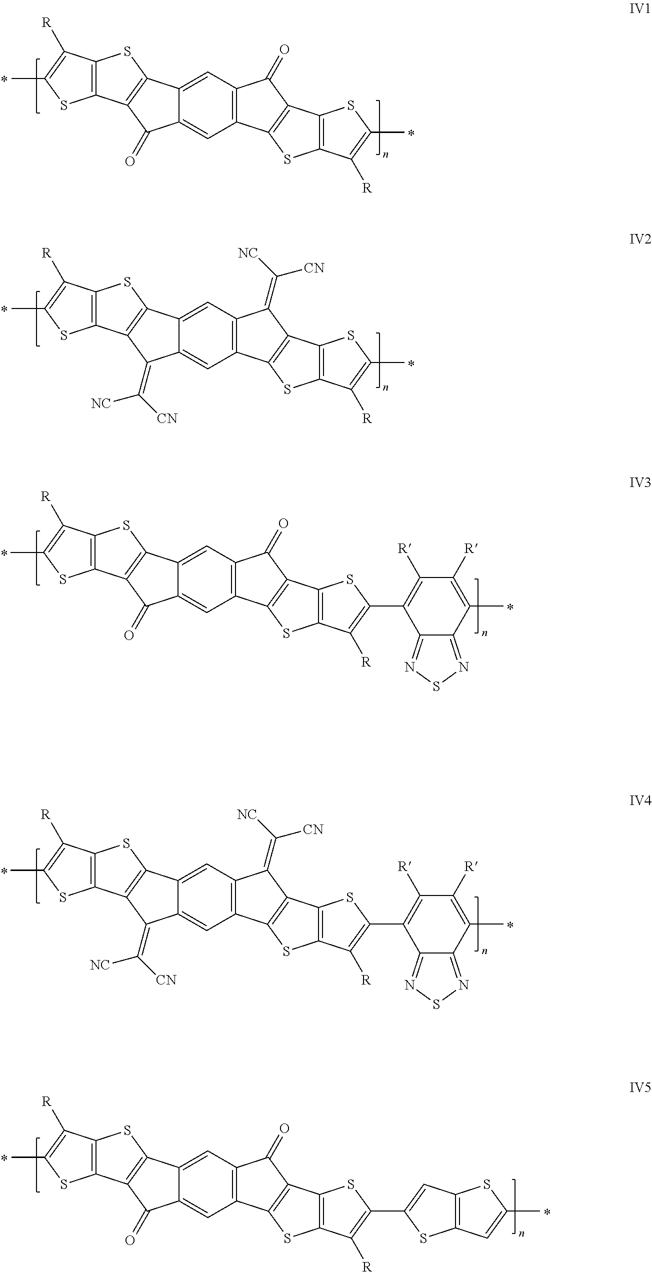 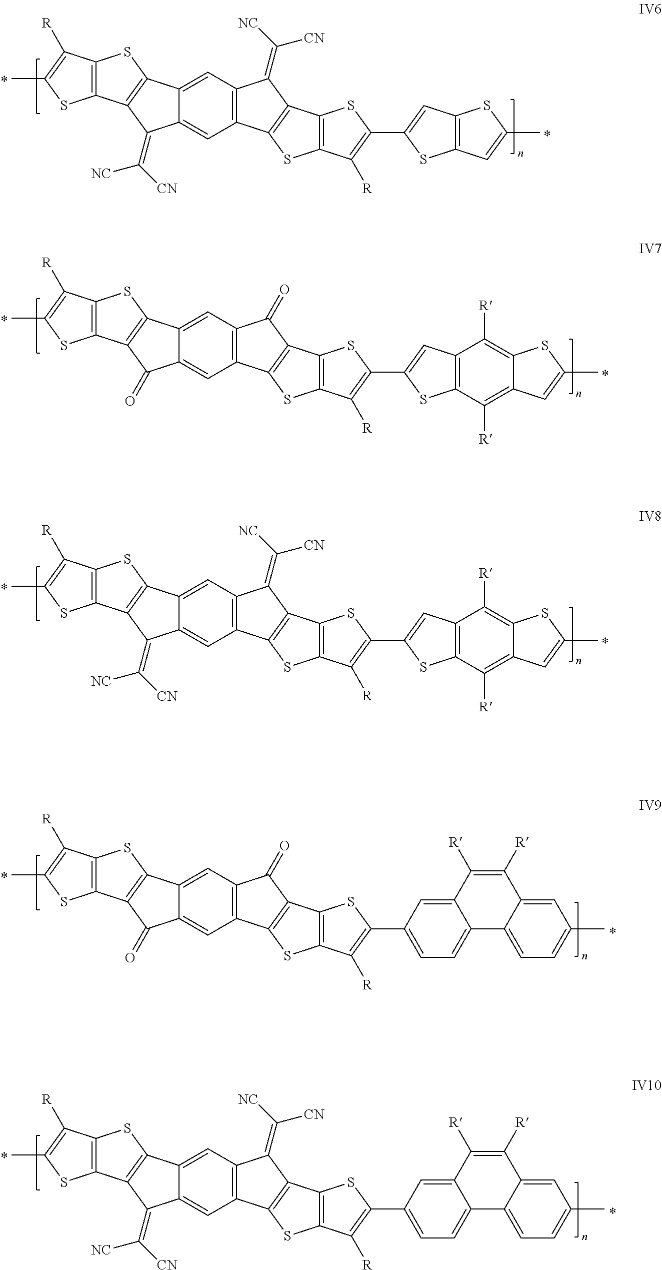
wherein R and R′ have independently of each other one of the meanings of R¹, and n is an integer >1.

15. Compound according to claim 1, which is selected of the following formulae 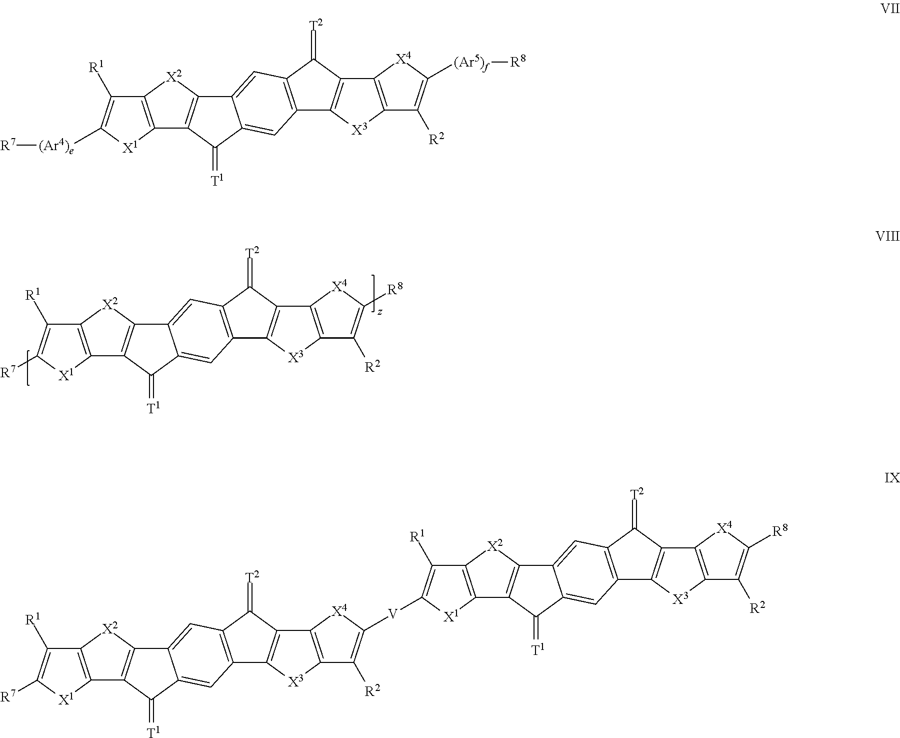
wherein R¹, R², T¹, T², X¹, X², X³ and X⁴ are as defined in claim 1,
Ar⁴, Ar⁵ independently of each other and on each occurrence identically or differently denote aryl or heteroaryl that is different from a unit of formula I, preferably having 5 to 30 ring atoms and is optionally being substituted, preferably by one or more groups R^{S}, and one or more of Ar⁴ and Ar⁵ may also denote a unit of formula I as defined in claim 1,
R⁷, R⁸ independently of each other denote H, F, Br, Cl, —CN, —NC, —NCO, —NCS, —OCN, —SCN, —C(O)NR⁰R⁰⁰, —C(O)X⁰, —C(O)R⁰, —C(O)OR⁰, —O—C(O)R⁰, —NH₂, —NR⁰R⁰⁰, —SH, —SR⁰, —SO₃H, —SO₂R⁰, —OH, —NO₂, —CF₃, —SF_{S}, P-Sp-, or optionally substituted silyl, carbyl or hydrocarbyl with 1 to 40 C atoms that is optionally substituted and optionally comprises one or more hetero atoms, and wherein one or more C atoms are optionally replaced by a hetero atom, R⁰ and R⁰⁰ are independently of each other H or optionally substituted C₁₋₄₀ carbyl or hydrocarbyl and X⁰ is halogen, preferably F, Cl or Br,
V is aryl or heteroaryl with 3 to 30 ring atoms which is optionally substituted, or denotes CY¹═CY² or C≡C,
Y¹, Y² are independently of each other H, F, Cl or CN,
e, f independently of each other denote 0, 1, 2 or 3, and
z is 2, 3 or 4.

16. Compound according to claim 15, which is selected from the following formulae 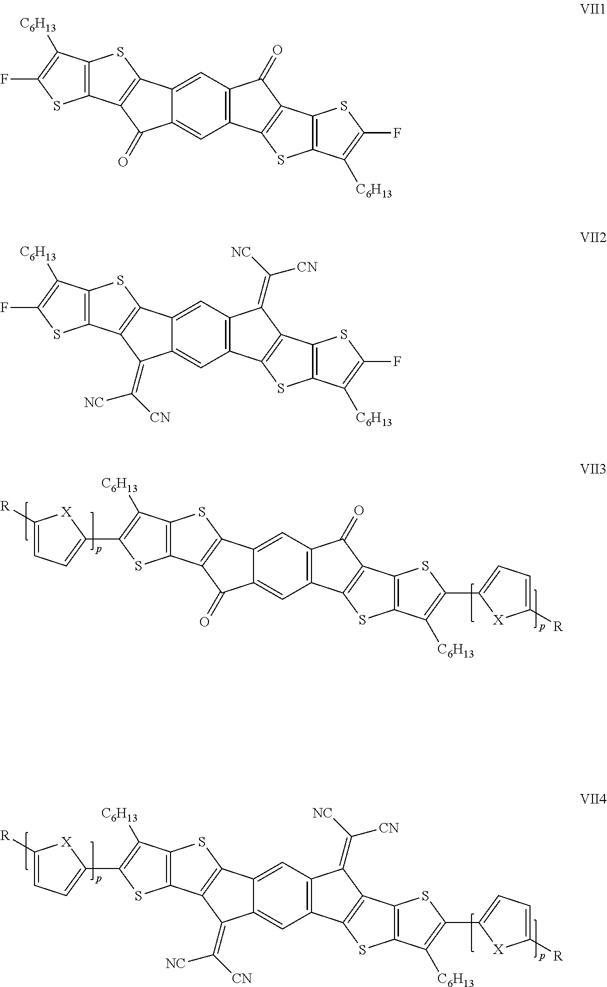
wherein p is 0, 1, 2, 3 or 4, X is O, S or Se, and R has one of the meanings of R⁷ as given in claim 15.

17. Mixture comprising one or more compounds according to claim 1 and one or more compounds or polymers having semiconducting, charge transport, hole/electron transport, hole/electron blocking, electrically conducting, photoconducting or light emitting properties.

18. Mixture according to claim 17, characterized in that it further comprises one or more n-type organic semiconductor compounds.

19. Mixture or polymer blend according to claim 18, characterized in that the n-type organic semiconductor compound is a fullerene or substituted fullerene.

20. Formulation comprising one or more polymers, according to claim 6, and one or more solvents, preferably selected from organic solvents.

21. Use of a compound, polymer, mixture, polymer blend or formulation according to claim 1 as charge transport, semiconducting, electrically conducting, photoconducting or light emitting material in an optical, electrooptical, electronic, electroluminescent or photoluminescent device, or in a component of such a device, or in an assembly comprising such a device or component.

22. Charge transport, semiconducting, electrically conducting, photoconducting or light emitting material comprising a compound, polymer, formulation, mixture or polymer blend according to claim 1.

23. Optical, electrooptical, electronic, electroluminescent or photoluminescent device, or a component thereof, or an assembly comprising it, which comprises a charge transport, semiconducting, electrically conducting, photoconducting or light emitting material, or comprises a compound, polymer, mixture, polymer blend or formulation, according to claim 1.

24. Device, component thereof, or assembly comprising it, according to claim 23, wherein the device is selected from organic field effect transistors (OFET), thin film transistors (TFT), organic light emitting diodes (OLED), organic light emitting transistors (OLET), organic photovoltaic devices (OPV), organic photodetectors (OPD), organic solar cells, laser diodes, Schottky diodes, photoconductors and photodetectors, the component is selected from charge injection layers, charge transport layers, interlayers, planarising layers, antistatic films, polymer electrolyte membranes (PEM), conducting substrates, conducting patterns, and the assembly is selected from integrated circuits (IC), radio frequency identification (RFID) tags or security markings or security devices containing them, flat panel displays or backlights thereof, electrophotographic devices, electrophotographic recording devices, organic memory devices, sensor devices, biosensors and biochips.

25. Device according to claim 24, which is an OFET, bulk heterojunction (BHJ) OPV device or inverted BHJ OPV device.

26. Monomer of formula VI
R⁵—Ar¹—U—Ar^{e}—R⁶ VI
wherein U is a unit of formula I according to claim 1, Ar¹, Ar² are, on each occurrence identically or differently, and independently of each other, aryl or heteroaryl that is different from U, preferably has 5 to 30 ring atoms and is optionally substituted, preferably by one or more groups R^{S}, R⁵ and R⁶ denote independently of each other H, F, Br, Cl, I, —CH₂Cl, —CHO, —CR′═CR″₂, —SiR′R″R′″, —SiR′X′X″, —SiR′R″X′, —SnR′R″R′″, BR′R″, —B(OR′)(OR″), —B(OH)₂, —O—SO₂—R′, —C≡CH, —C≡C—SiR′₃, —ZnX′, P-Sp- or and endcap group, wherein P is a polymerizable group or crosslinkable group and Sp is a spacer group or a single bond, X′ and X″ denote halogen, R′, R″ and R′″ have independently of each other H or optionally substituted C₁₋₄₀ carbyl or hydrocarbyl, and two of R′, R″ and R′″ may also from a ring together with the hetero atom to which they are attached, and at least one of R⁵ and R⁶ is different from H.

27. Process of preparing a polymer comprising coupling one or more monomers according to claim 26, wherein R⁵ and R⁶ are selected from halogen, stannyl and boronate groups, with each other and/or with one or more monomers selected from the following formulae
R⁵—Ar³—R⁶ C1
R⁵-D-R⁶ C2
wherein Ar³ is independently as defined for Ar¹ and Ar², D is an aryl or heteroaryl group that is different from U and Ar¹⁻³, has 5 to 30 ring atoms, is optionally substituted by one or more groups R^{S}, and is selected from aryl or heteroaryl groups having electron donor properties, R^{S} is on each occurrence identically or differently F, Br, Cl, —CN, —NC, —NCO, —NCS, —OCN, —SCN, —C(O)NR⁰R⁰⁰, —C(O)X⁰, —C(O)R⁰, —NH₂, —NR⁰R⁰⁰, —SH, —SR⁰, —SO₂R⁰, —OH, —NO₂, —CF₃, —SF₅, optionally substituted silyl, carbyl or hydrocarbyl with 1 to 40 C atoms that is optionally substituted and optionally comprises one or more hetero atoms, or P-Sp-, in an aryl-aryl coupling reaction.
